(19) United States
(12) Patent Application Publication
(10) Pub. No.: US 2026/0304822 A1
(43) Pub. Date: Oct. 1, 2026

(54) SEMICONDUCTOR DEVICE INCLUDING ADDITIONAL GATE INSULATION PATTERN

(71) Applicant: SAMSUNG ELECTRONICS CO., LTD., Suwon-si (KR)

(72) Inventors: Songjae LEE, Suwon-si (KR); MINHYUNG KANG, Suwon-si (KR); SEWOUNG OH, Suwon-si (KR); SANGHYUN WOO, Suwon-si (KR); HYUNYUL CHOI, Suwon-si (KR); SOOHUN HONG, Suwon-si (KR)

(73) Assignee: SAMSUNG ELECTRONICS CO., LTD., Suwon-si (KR)

(21) Appl. No.: 19/532,507

(22) Filed: Feb. 6, 2026

(30) Foreign Application Priority Data
Mar. 25, 2025 (KR) 10-2025-0037786

(51) Int. Cl. H10D 30/00; H10D 30/01; H10D 30/60

(52) U.S. Cl. CPC H10D 30/508; H10D 30/0195; H10D 30/603

(57) ABSTRACT

A semiconductor device includes: an active pattern on a substrate; a first source/drain pattern and a second source/drain pattern on the active pattern; a channel pattern between the first source/drain pattern and the second source/drain pattern; a gate electrode on at least a portion of side surfaces of the channel pattern and an upper surface of the channel pattern; a gate insulating layer between the channel pattern and the gate electrode; and a sloped insulation pattern between the second source/drain pattern and the gate electrode and inclined with respect to the channel pattern.

### CROSS-REFERENCE TO RELATED APPLICATIONS

This application claims priority under 35 U.S.C. § 119 of Korean Patent Application No. 10-2025-0037786, filed on Mar. 25, 2025, the disclosure of which in incorporated herein in its entirety by reference.

### BACKGROUND

Embodiments of the disclosure described herein relate to a semiconductor device, more particularly, relate to a semiconductor device including gate-all-around (GAA) type transistors.

A semiconductor device includes an integrated circuit including metal-oxide-semiconductor field-effect transistors (MOSFETs). As the size of semiconductor devices are continuously scaled down, the scaling down of MOSFETs is also being accelerated. For example, multi-channel transistors such as multi-bridge channel FETs (MBCFETs) are being developed to reduce the size of the MOSFETs. However, in recently developed transistors, spacing between channels is set to be very narrow, which in turn makes it difficult to form a sufficiently thick gate insulating layer. Accordingly, the transistors are highly vulnerable to malfunction at a high voltage.

### SUMMARY

Embodiments of the disclosure provide a semiconductor device in which three-dimensional transistors are reliably formed and a method for manufacturing the semiconductor device.

According to an embodiment, a semiconductor device may include: an active pattern on a substrate; a first source/drain pattern and a second source/drain pattern on the active pattern; a channel pattern between the first source/drain pattern and the second source/drain pattern; a gate electrode on at least a portion of side surfaces of the channel pattern and an upper surface of the channel pattern; a gate insulating layer between the channel pattern and the gate electrode; and a sloped insulation pattern between the second source/drain pattern and the gate electrode and inclined with respect to the channel pattern.

According to an embodiment, a semiconductor device may include: an active area in a substrate; a fin structure in the active area and comprising a channel pattern on the active area, a source region, and a drain region; a gate electrode on at least a portion of a side surface and an upper surface of the channel pattern of the fin structure; a gate insulating layer between the channel pattern and the gate electrode; and a sloped insulation pattern between the drain and the gate electrode and comprising a slope surface inclined with respect to the channel pattern.

According to an embodiment, a semiconductor device may include: a substrate; an active pattern extending along a first direction on the substrate; a first semiconductor pattern and a second semiconductor pattern vertically stacked on the active pattern and spaced apart from each other; a gate electrode on the active pattern, extending in a second direction, and surrounding the first semiconductor pattern and the second semiconductor pattern; a first source/drain pattern and a second source/drain pattern at least at opposite sides of the gate electrode; and a sloped insulation pattern between the gate electrode and one of the first source/drain pattern and the second source/drain pattern and inclined with respect to an upper surface of the second semiconductor pattern.

According to the above, an improved BVDSS (breakdown voltage drain-to-source) is realized, and a semiconductor device suitable for high-voltage operations may be provided. Accordingly, a reliable semiconductor device may be provided.

### BRIEF DESCRIPTION OF DRAWINGS

The above and other objects and features of the present disclosure will become apparent by describing in detail embodiments thereof with reference to the accompanying drawings.

FIG. 1A is a plan view schematically illustrating a semiconductor device according to one or more embodiments, and FIG. 1B is a perspective view illustrating a portion P1 of FIG. 1A.

FIGS. 2A to 2D are views illustrating a semiconductor device according to one or more embodiments, FIG. 2A is a cross-sectional perspective view taken along a line A-A′ of FIG. 1B, FIG. 2B is a cross-sectional view taken along a line A-A′ of FIG. 1B, FIG. 2C is a cross-sectional view taken along a line B-B′ of FIG. 1B, and FIG. 2D is a plan view taken along a line C-C′ of FIG. 1B.

FIGS. 3A to 17C are views sequentially illustrating a method of manufacturing a semiconductor device according to one or more embodiments, FIGS. 3A, 4A, . . . , and 17A are cross-sectional perspective views taken along a line A-A′ of FIG. 1B, FIGS. 3B, 4B, . . . , and 17B are cross-sectional views taken along a line B-B′ of FIG. 1B, and FIGS. 3C, 4C, 13C, 14C, . . . , and 17C are cross-sectional views taken along a line B-B′ of FIG. 1B.

FIGS. 18A to 18C are views illustrating a semiconductor device according to one or more embodiments, FIG. 18A is a cross-sectional perspective view taken along a line A-A′ of FIG. 1B, FIG. 18B is a cross-sectional view taken along a line A-A′ of FIG. 1B, and FIG. 18C is a cross-sectional view taken along a line B-B′ of FIG. 1B.

FIGS. 19A to 25B are views sequentially illustrating a method of manufacturing a semiconductor device according to one or more embodiments, FIGS. 19A, 20A, . . . , and 25A are cross-sectional perspective views taken along a line A-A′ of FIG. 1B, FIGS. 19B, 20B, . . . , and 25B are cross-sectional views taken along a line A-A′ of FIG. 1B, and FIG. 19C are cross-sectional views taken along a line B-B′ of FIG. 1B.

FIGS. 26A to 26C are views illustrating a semiconductor device according to one or more embodiments, FIG. 26A is a cross-sectional perspective view taken along a line A-A′ of FIG. 1B, FIG. 26B is a cross-sectional view taken along a line A-A′ of FIG. 1B, and FIG. 26C is a cross-sectional view taken along a line B-B′ of FIG. 1B.

FIGS. 27A to 27C are views illustrating a semiconductor device according to one or more embodiments manufactured in a different order from the embodiments described above, FIG. 27A is a cross-sectional perspective view taken along a line A-A′ of FIG. 1B, FIG. 27B is a cross-sectional view taken along a line A-A′ of FIG. 1B, and FIG. 27C is a cross-sectional view taken along a line B-B′ of FIG. 1B.

FIGS. 28A to 39B are views sequentially illustrating a method of manufacturing a semiconductor device according to one or more embodiments, FIGS. 28A, 29A, . . . , and 39A are cross-sectional perspective views taken along a line A-A′ of FIG. 1B, FIGS. 28B, 29B, . . . , and 39B are cross-sectional views taken along a line B-B′ of FIG. 1B, and FIGS. 28C, 29C, 36C, and 37C are cross-sectional views taken along a line B-B′ of FIG. 1B.

FIG. 40 is a perspective view illustrating a semiconductor device according to one or more embodiments.

FIGS. 41A to 41C are views illustrating a semiconductor device according to one or more embodiments, FIG. 41A is a cross-sectional perspective view taken along a line A-A′ of FIG. 40, FIG. 41B is a cross-sectional view taken along a line A-A′ of FIG. 40, and FIG. 41C is a cross-sectional view taken along a line B-B′ of FIG. 40.

FIGS. 42A to 46B are views sequentially illustrating a method of manufacturing a semiconductor device according to one or more embodiments, FIGS. 42A, 43A, . . . , and 46A are cross-sectional perspective views taken along a corresponding line to the line A-A′ of FIG. 1B, FIGS. 42B, 43B, . . . , and 46B are cross-sectional views taken along a corresponding line to the line B-B′ of FIG. 1B, and FIG. 42C is a cross-sectional view taken along a line B-B′ of FIG. 1B.

FIGS. 47A, 47B, and 47C are views illustrating a semiconductor device according to one or more embodiments, FIG. 47A is a cross-sectional perspective view taken along a line A-A′ of FIG. 1B, FIG. 47B is a cross-sectional view taken along a line A-A′ of FIG. 1B, and FIG. 47C is a cross-sectional view taken along a line B-B′ of FIG. 1B.

FIGS. 48A to 61C are views sequentially illustrating a method of manufacturing a semiconductor device according to one or more embodiments, FIGS. 48A, 49A, . . . , and 61A are cross-sectional perspective views taken along a line A-A′ of FIG. 1B, FIGS. 48B, 49B, . . . , and 61B are cross-sectional views taken along a line B-B′ of FIG. 1B, and FIGS. 48C, 49C, 54C, 55C, 57C, 58C, 60C, and 61C are cross-sectional views taken along a line B-B′ of FIG. 1B.

### DETAILED DESCRIPTION

Hereinafter, embodiments of the disclosure will be described with reference to accompanying drawings. All of the embodiments described herein are non-limiting example embodiments, and thus, the disclosure is not limited thereto and may be realized in various other forms. It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present. As used herein, an expression, “a and/or b” should be understood as including only a, only b and both a and b. As used herein, expressions “at least one of a, b, and c” and “at least one of a, b, or c” should be understood as including only a, only b, only c, both a and b, both a and c, both b and c, or all of a, b, and c.

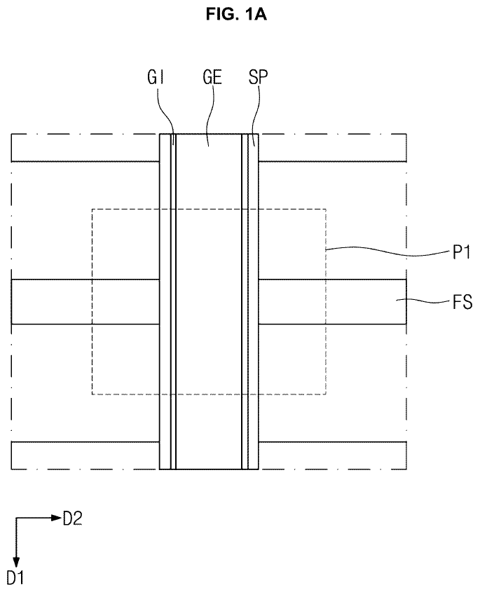

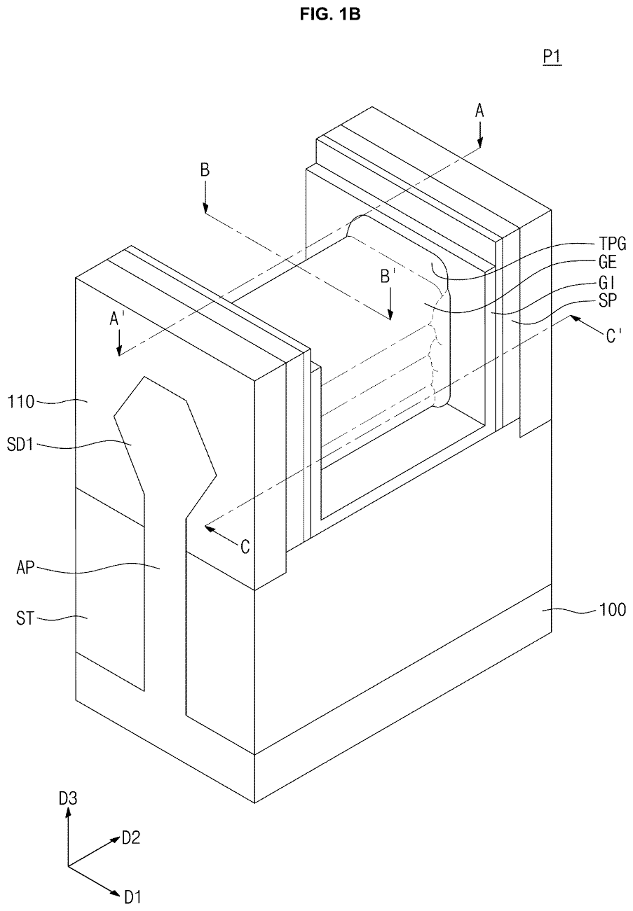

A semiconductor device according to embodiments may be applied to various types of devices, FIGS. 1A and 1B schematically illustrate a semiconductor device, FIG. 1A is a plan view schematically illustrating a semiconductor device according to one or more embodiments, and FIG. 1B is a perspective view illustrating a portion P1 of FIG. 1A according to one or more embodiments.

According to one or more embodiments, the semiconductor device may be applied to various types of semiconductor apparatuses. A single semiconductor device or multiple semiconductor devices may be included in various semiconductor apparatuses. When viewed in a plane, multiple semiconductor devices may be arranged in various patterns and may be connected to various wirings either directly or indirectly.

In one or more embodiments, the semiconductor device may include a P-type or P-channel metal-oxide-semiconductor (PMOS) transistor or an N-type or N-channel metal-oxide-semiconductor (NMOS) transistor. In the following embodiments, for convenience of explanation, the PMOS transistor will be described as a representative example of the semiconductor device, however, the disclosure should not be limited thereto or thereby, and it will be apparent to those skilled in the art that the semiconductor device may be equally applied to NMOS transistors. Further, in the following embodiments, an N-type dopant and a P-type dopant may be referred to as a first dopant and a second dopant, respectively, but are not limited thereto. For example, it should be understood that within the concept of the disclosure, even if a P-type dopant is used, it may be replaced with an N-type dopant.

In the following drawings, for convenience of explanation, a single semiconductor device is illustrated by way of example.

Referring to FIGS. 1A and 1B, the semiconductor device may include a fin structure FS disposed in an active area and a gate electrode GE formed to intersect the fin structure FS. As an example, the gate electrode GE may extend in a first direction D1, and the fin structure FS may extend in a second direction D2.

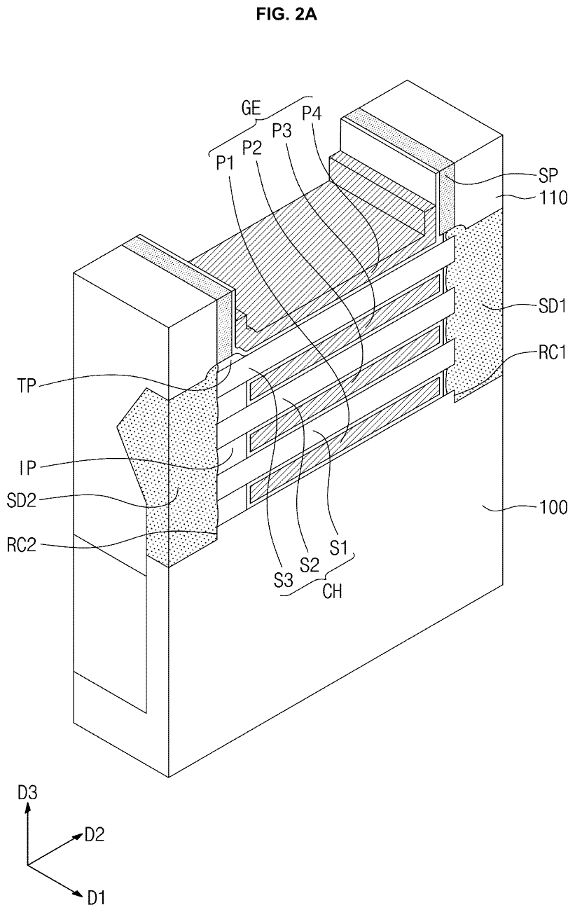

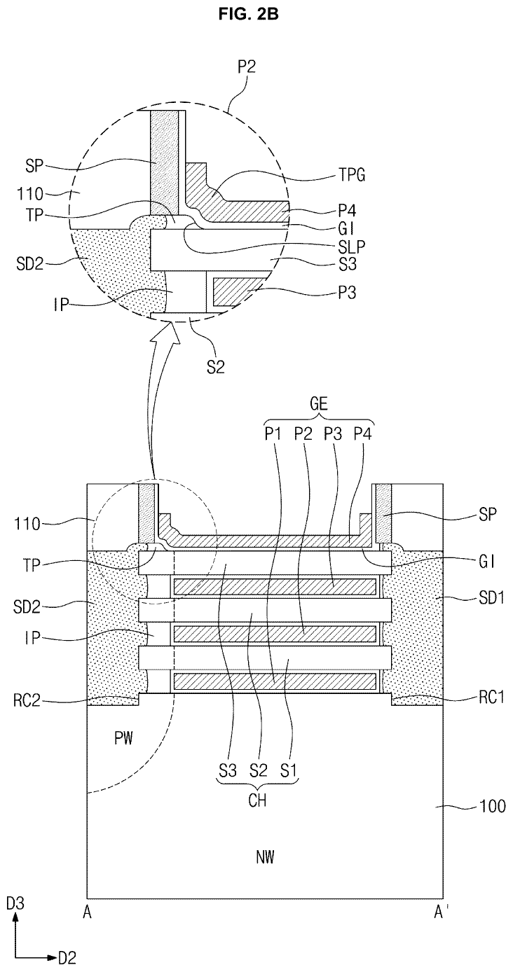

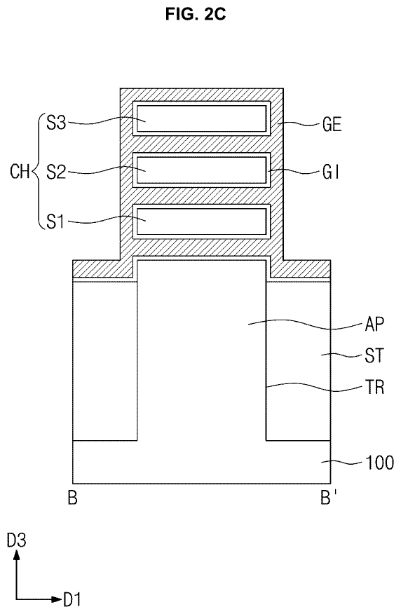

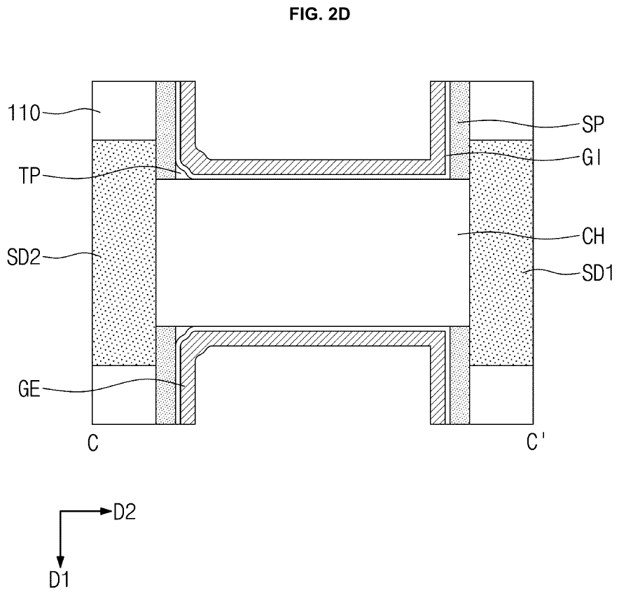

The fin structure FS may be formed in a direction, i.e., a third direction D3, perpendicular to an upper surface of a substrate 100 including a semiconductor material. The fin structure FS may include first and second source/drain patterns SD1 and SD2 (refer to FIG. 2A) doped with dopants and a channel pattern formed between the first and second source/drain patterns SD1 and SD2. The fin structure FS may include a plurality of channel patterns (not shown) stacked in the third direction D3 and spaced apart from each other. This will be described later.

The channel pattern may be buried by the gate electrode GE. In other words, the gate electrode GE may be formed to surround the channel pattern and to intersect a plurality of fin structures FS.

The gate electrode GE may be formed of a conductive material, such as metal, metal silicide, or polysilicon. The gate electrode GE may include a plurality of layers. When the gate electrode GE includes multiple layers, the gate electrode GE may include a work function metal layer to adjust a work function, a barrier metal layer, and a gate metal layer.

The gate electrode GE may have a sloped gate portion TPG on a side of or close to the second source/drain pattern. An upper surface of the sloped gate portion TPG may be sloped with respect to an upper surface of the substrate 100 and a side surface of a gate insulating layer GI.

The gate insulating layer GI and a gate spacer pattern SP may be disposed on a side surface of the gate electrode GE. Similar to the gate electrode GE, the gate insulating layer GI and the gate spacer pattern SP may be formed to surround a channel pattern and to intersect the fin structures FS. The gate electrode GE may extend in a direction (e.g., the third direction D3 of FIG. 1B) while having a shape that passes over the fin structure FS.

FIGS. 2A to 2D are views illustrating a semiconductor device according to one or more embodiments, FIG. 2A is a cross-sectional perspective view taken along a line A-A′ of FIG. 1B, FIG. 2B is a cross-sectional view taken along the line A-A′ of FIG. 1B, FIG. 2C is a cross-sectional view taken along a line B-B′ of FIG. 1B, and FIG. 2D is a plan view taken along a line B-B′ of FIG. 1B.

Referring to FIGS. 1A, 1B, and 2A to 2D, the semiconductor device may be disposed on the substrate 100.

The substrate 100 may be a semiconductor substrate or a compound semiconductor substrate, which includes silicon, germanium, silicon-germanium, or the like. The substrate 100 may include a single-crystalline semiconductor material such as Si, Ge, SiGe, GaAs, InSb, GaP, GaSb, InAlAs, InGaAs, GaSbP, GaAsSb, InP, etc., but the disclosure should not be limited thereto or thereby. As an example, the substrate 100 may be a silicon substrate.

An active pattern AP may be defined by a trench TR formed in the substrate 100. The active pattern AP may extend in the second direction D2. The active pattern AP may be a portion of the substrate 100, which protrudes vertically in the third direction D3. When the semiconductor device is provided in plural, multiple active patterns AP may be arranged in the first direction D1 while being spaced apart from each other.

The substrate 100 may be a P-type substrate 100 and may include an N-well NW doped with an N-type dopant and defined in an upper portion thereof. However, the type of the substrate 100 should not be limited thereto or thereby. Hereinafter, a case in which the P-type substrate is used will be described as a representative example.

A device isolation layer ST may fill the trench TR. The device isolation layer ST may include silicon oxide. Upper portions of the active pattern may protrude vertically over the device isolation layer ST. The device isolation layer ST may not cover the upper portions of the active pattern AP. The device isolation layer ST may cover at least portions of lower side surfaces of the active pattern AP.

A channel pattern CH may be disposed on the active pattern AP. The channel pattern CH may include first, second, and third semiconductor patterns S1, S2, and S3 that are sequentially stacked. The first, second, and third semiconductor patterns S1, S2, and S3 may be spaced apart from each other in a vertical direction, i.e., the third direction D3.

Each of the first, second, and third semiconductor patterns S1, S2, and S3 may include silicon (Si), germanium (Ge), or silicon-germanium (SiGe). As an example, each of the first, second, and third semiconductor patterns S1, S2, and S3 may include crystalline silicon.

Two recesses, for example, a first recess RC1 and a second recess RC2, may be formed in upper portions of the active pattern AP, respectively. A source/drain pattern may be provided in each recess. For instance, the first source/drain pattern SD1 may be provided in the first recess RC1, and the second source/drain pattern SD2 may be provided in the second recess RC2. The channel pattern CH may be interposed between the first source/drain pattern SD1 and the second source/drain pattern SD2. The channel pattern CH may include the stacked first, second, and third semiconductor patterns S1, S2, and S3. The channel pattern CH may connect the first source/drain pattern SD1 and the second source/drain pattern SD2 to each other.

The first source/drain pattern SD1 and the second source/drain pattern SD2 may be epitaxial patterns formed by a selective epitaxial growth (SEG) process. The first and second source/drain patterns SD1 and SD2 may include a high concentration of dopants. For example, the first and second source/drain patterns SD1 and SD2 may include a high concentration of P-type dopants. A region adjacent to the second source/dram pattern SD2 may be provided with a P-well PW implanted with a low concentration of the P-type dopants. In the disclosure, the P-well may be referred to as a lightly doped drain (LDD) region implanted with the P-type dopants.

As an example, an upper surface of each of the first source/drain pattern SD1 and the second source/drain pattern SD2 may be at least partially at the same level as an upper surface of an uppermost semiconductor pattern, for example, the third semiconductor pattern S3. As another example, the upper surface of each of the first source/drain pattern SD1 and the second source/drain pattern SD2 may be higher than the upper surface of the uppermost semiconductor pattern.

The first source/drain pattern SD1 and the second source/drain pattern SD2 may include a semiconductor element that is the same as or different from that of the substrate 100. The first and second source/drain patterns SD1 and SD2 may include a semiconductor element, for example, SiGe, having a lattice constant lager than that of the semiconductor element of the substrate 100. Accordingly, the first and second source/drain patterns SD1 and SD2 may apply compressive stress to the channel pattern CH disposed between them. Alternatively, the first and second source/drain patterns SD1 and SD2 may include the same semiconductor element, for example, Si, as that of the substrate 100. As an example, the first and second source/drain patterns SD1 and SD2 may include single crystal silicon.

Although not shown, the first source/drain pattern SD1 may include a buffer layer on an inner side surface of the first recess RC1 and a main layer filling the remaining region of the first recess RC1. Likewise, the second source/drain pattern SD2 may include a buffer layer on an inner side surface of the second recess RC2 and a main layer filling the remaining region of the second recess RC2.

The gate electrode GE may extend in the first direction D1 while crossing the active pattern AP. The gate electrode GE may vertically and horizontally overlap the channel pattern CH.

The gate electrode GE may include at least one of a conductive metal nitride, for example, titanium nitride or tantalum nitride, and a metal material, for example, titanium, tantalum, tungsten, copper, or aluminum.

Each gate electrode GE may include a first portion P1 disposed between the substrate 100 and the first semiconductor pattern S1, a second portion P2 disposed between the first semiconductor pattern S1 and the second semiconductor pattern S2, a third portion P3 disposed between the second semiconductor pattern S2 and the third semiconductor pattern S3, and a fourth portion P4 disposed on the third semiconductor pattern S3. Here, the gate electrode GE may be provided on an upper surface, a lower surface, and both side surfaces of each of the first, second, and third semiconductor patterns S1, S2, and S3. In other words, the semiconductor device according to the present embodiment may be a three-dimensional field-effect transistor, for example, an MBCFET, in which each gate electrode GE surrounds the channel three dimensionally.

A pair of gate spacer patterns SP may be disposed on both side surfaces of the fourth portion P4 of the gate electrode GE. The gate spacer patterns SP may extend in the first direction D1 along each gate electrode GE. The gate spacer patterns SP may include at least one of SiCN, SiCON, and SiN. As another example, the gate spacer patterns SP may include a multi-layer structure of at least two of SiCN, SiCON, and SiN.

The gate insulating layer GI may be disposed between each gate electrode GE and each channel pattern CH. The gate insulating layer GI may be disposed on the upper surface, the lower surface, and the both side surfaces of each of the first, second, and third semiconductor patterns S1, S2, and S3.

The gate insulating layer GI may be formed as a single layer, but may also be formed as a multi-layer structure. For example, the gate insulating layer GI may include an interfacial layer that is disposed on a surface of the channel pattern CH and a high-k dielectric layer on the interfacial layer. In an embodiment, the high-k dielectric layer may be thicker than the interfacial layer. The interfacial layer may include silicon oxide or silicon oxynitride.

Inner spacers IP may be provided between the first source/drain pattern SD1 and the gate electrode GE. The inner spacers IP may be disposed between the first, second, and third portions P1, P2, and P3 of the gate electrode GE and the first source/drain pattern SD1 and between the first, second, and third portions P1, P2, and P3 of the gate electrode GE and the second source/drain pattern SD2. The inner spacers IP may be in direct contact with the first source/drain pattern SD1. Each of the first, second, and third portions P1, P2, and P3 of the gate electrode GE may be spaced apart from each of the first source/drain pattern SD1 by the inner spacers IP. The inner spacers IP may include one of SiOx, SiN, SiCN, or SiOCN, for example, the inner spacers IP may include SiOx.

A sloped insulation pattern TP may be disposed between the gate electrode GE and the channel pattern CH. As an example, the sloped insulation pattern TP may be on an uppermost portion of the channel pattern CH, i.e., on the third semiconductor pattern S3. In addition, the sloped insulation pattern TP may be disposed on an outer side surface of the channel pattern CH and an outer side surface of the inner spacers IP. For example, the sloped insulation pattern TP may be disposed on an outer side surface of each of the first, second, and third semiconductor patterns S1, S2, and S3. The sloped insulation pattern TP may protrude outwardly along a direction parallel to a surface of the substrate 100. The sloped insulation pattern TP on the outer side surface may be formed integrally with the inner spacers IP without being separated.

The sloped insulation pattern TP on the uppermost portion of the channel pattern CH may be in contact with the second source/drain pattern SD2 and may have a slope surface inclined with respect to one surface of the channel pattern CH. For example, the sloped insulation pattern TP may have a slope surface SLP that is inclined with respect to an uppermost surface of the channel pattern CH. An end portion of the gate electrode GE at the side of the second source/drain pattern SD2 may vertically overlap the sloped insulation pattern TP. The sloped insulation pattern TP provided on the outer side surface of the channel pattern CH may have the slope surface SLP inclined with respect to the outer side surface of the channel pattern CH.

The gate insulating layer GI and the gate electrode GE may be sequentially stacked on the slope surface SLP of the sloped insulation pattern TP. Due to the sloped insulation pattern TP, the gate electrode GE may have the sloped gate portion TPG which is inclined with regard to the upper surface of the third semiconductor pattern S3 extending in the second direction D2 and the side surface of the gate spacer SP extending in the third direction D3.

The sloped insulation pattern TP may function as an insulating layer that insulates the gate electrode GE from the second source/drain pattern SD2 along with the gate insulating layer GI, and simultaneously, may function as a field plate of a laterally diffused metal oxide semiconductor (LDMOS) device. This will be described in detail below.

In an embodiment, the gate insulating layer GI may include the same material as the sloped insulation pattern TP. As an example, the sloped insulation pattern TP and the gate insulating layer GI may include SiOx. In a case where the gate insulating layer GI includes the same material as the sloped insulation pattern TP, the gate insulating layer GI and the sloped insulation pattern TP may be provided integrally with each other without being separated from each other. Even when the gate insulating layer GI and the sloped insulation pattern TP are provided as separate structures, the gate insulating layer GI and the sloped insulation pattern TP may function as an insulating field plate.

In an embodiment, the sloped insulation pattern TP, the inner spacer IP, and the gate insulating layer GI may include the same material. For example, the sloped insulation pattern TP, the inner spacer IP, and the gate insulating layer GI may include SiOx. When the inner spacer IP, the sloped insulation pattern TP, and the gate insulating layer GI include the same material, the inner spacer IP, the sloped insulation pattern TP, and the gate insulating layer GI may be provided integrally with each other without being separated from each other. In this case, a boundary, an interface or a junction may not be formed between the inner spacer IP including the sloped insulation pattern TP and the gate insulating layer GI.

However, the disclosure should not be limited thereto or thereby, and according to an embodiment, each of the sloped insulation pattern TP, the inner spacer IP, and the gate insulating layer GI may include various other insulating materials.

A cover layer 110 may be disposed above the substrate 100. The cover layer 110 may be disposed on the device isolation layer ST and may cover at least a portion of the first source/drain pattern SD1 and the second source/drain pattern SD2.

In the semiconductor device of the disclosure having the above-described structure, the N-well NW, the source, the drain, and the P-well PW in the substrate 100 may form a structure similar to that of the LDMOS device, and in particular, the P-well PW may correspond to a P-drift region. In addition, the sloped insulation pattern TP, which is inclined with respect to the upper surface of the channel pattern CH adjacent to the drain SD2, may correspond to the field plate. The field plate may be disposed on the P-well which is the P-drift region and may modulate an electric field generated by the gate electrode GE, for example, reducing a peak electric field, and thus, performance of the semiconductor device may be improved. Accordingly, the semiconductor device may achieve a higher breakdown voltage.

As described above, the semiconductor device according to the embodiment may exhibit behavior similar to that of the LDMOS device. However, there is a difference in that while a conventional LDMOS device is formed as a planar type, the semiconductor device according to the embodiment is formed as a fin-type or gate-all-around (GAA) type. When an LDD doping process is not performed and is omitted, the P-well may not be formed near the drain or may be formed in a narrow region. However, even when the P-well is not formed and the N-well extends to the vicinity of the drain, the semiconductor device according to the embodiment may still operate similarly to the LDMOS device due to the field plate.

As a result, the semiconductor device according to the embodiment may have the same or similar effects as the LDMOS device, for example, a high drain-source breakdown voltage (BVDSS).

In a case of a conventional MBCFET semiconductor device, since a gap between channel patterns is narrow, it is difficult to grow a thick gate insulating layer. When the semiconductor device is operated under a high voltage, a strong electric field from the drain may cause breakdown of the gate insulating layer, resulting in a short circuit between the drain and the gate electrode. However, the semiconductor device according to the embodiment has a high BVDSS and thus may be applied to various high-voltage devices.

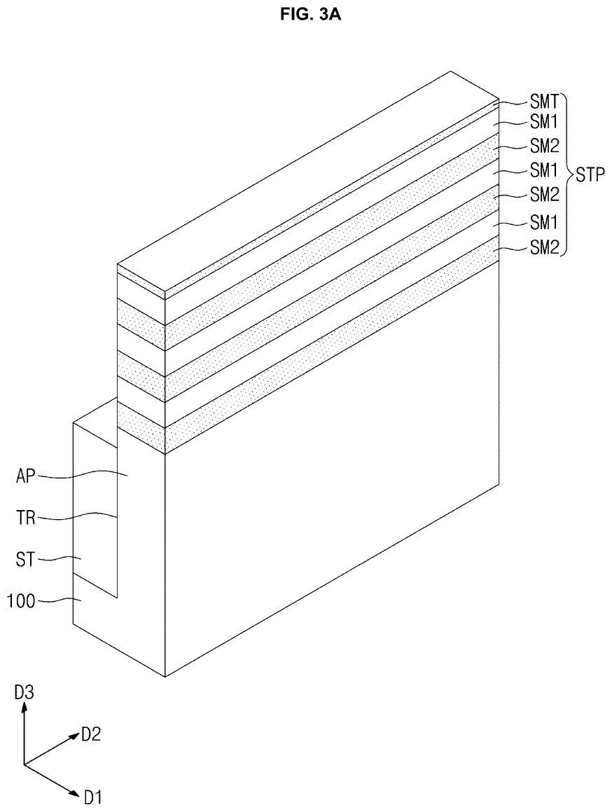

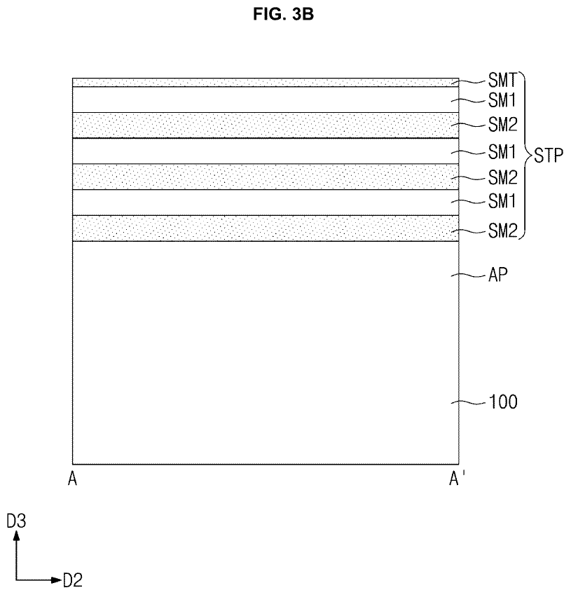

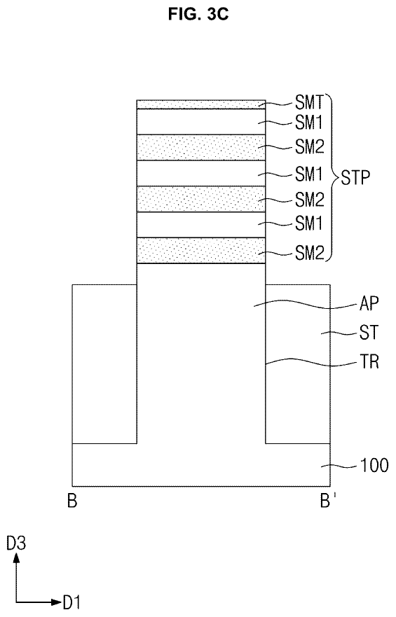

FIGS. 3A-3C to 17A-17C are views sequentially illustrating a method of manufacturing a semiconductor device according to one or more embodiments, FIGS. 3A, 4A, 5A, 6A, 7A, 8A, 9A, 10A, 11A, 12A, 13A, 14A, 15A, 16A, and 17A are cross-sectional perspective views taken along the line A-A′ of FIG. 1B, FIGS. 3B, 4B, 5B, 6B, 7B, 8B, 9B, 10B, 11B, 12B, 13B, 14B, 15B, 16B, and 17B are cross-sectional views taken along the line A-A′ of FIG. 1B, and FIGS. 3C, 4C, 13C, 14C, 15C, 16C, and 17C are cross-sectional views taken along the line B-B′ of FIG. 1B. The semiconductor device manufactured in the present embodiments may be the same as or similar to the semiconductor device described above in reference to FIGS. 1A, 1B and 2A-2D, and thus, the same reference numerals and characters may be used in the descriptions of the present embodiments.

Referring to FIGS. 3A, 3B, and 3C, a stack pattern STP may be formed on the substrate 100. The stack pattern STP may include layers including different materials and alternately stacked to facilitate formation of the channel pattern CH. In an embodiment, the stack pattern STP may include first semiconductor layers SM1, second semiconductor layers SM2 alternately stacked with the first semiconductor layers SM1, and an uppermost semiconductor layer SMT disposed above the alternately stacked first and second semiconductor layers SM1 and SM2. The uppermost semiconductor layer SMT may have the same composition as the second semiconductor layers SM2 and may have a thickness smaller than the second semiconductor layers SM2.

The first semiconductor layers SM1 and the second semiconductor layers SM2 may have material compositions different from each other. The first semiconductor layers SM1 and the second semiconductor layers SM2 may provide different etch selectivities and/or different oxidation rates. Since the uppermost semiconductor layer SMT may have the same material composition as the second semiconductor layers SM2, the uppermost semiconductor layer SMT may also have an etch selectivity and/or an oxidation rate different from the first semiconductor layers SM1.

In an embodiment, the number of each of the first and second semiconductor layers SM1 and SM2 may be three, and the uppermost semiconductor layer SMT may be disposed on the first semiconductor layer SM1. However, the number of the first and second semiconductor layers SM1 and SM2 should not be limited thereto or thereby. In other embodiments, more or fewer semiconductor layers may be included in the stack pattern STP depending on a desired number of the channel patterns CH in the semiconductor device to be formed. For example, in some embodiments, the number of the first and second semiconductor layers SM1 and SM2 may be within a range from 1 to 10.

The first semiconductor layers SM1 may include a compound semiconductor such as Si, Ge, SiC, GeAs, GaP, InP, InAs, and/or InSb, an alloy semiconductor such as SiGe, GaAsP, AlInAs, AlGaAs, InGaAs, GaInP, and/or GaInAsP, or a combination thereof. The second semiconductor layers SM2 may include silicon-germanium (SiGe).

For example, the first semiconductor layers SM1 may include silicon (Si), and the second semiconductor layers SM2 may include silicon-germanium (SiGe). Each of the second semiconductor layers SM2 may have a germanium concentration in a range from about 10 atomic percent (at %) to about 30 atomic percent (at %).

The first and second semiconductor layers SM1 and SM2 may be formed by a molecular beam epitaxy (MBE) process, a metal-organic chemical vapor deposition (MOCVD) process, and/or another suitable epitaxial growth process. portions of the first and second semiconductor layers SM1 and SM2 may be removed in subsequent processes and may serve to define a vertical distance between the channel patterns CH adjacent to each other in a final semiconductor device. In an embodiment, the thickness of each of the first and second semiconductor layers SM1 and SM2 may be variously modified depending on embodiments.

A mask pattern may be formed on the stack pattern STP. The mask pattern may have a line or bar shape extending in the second direction D2. When a patterning process is performed on the stack pattern STP and the substrate 100 using the mask pattern as an etch mask, the trench TR that defines the active area may be formed. The trench TR may be formed on both sides of the active pattern AP. The active pattern AP may have a bar shape extending in a direction parallel to the second direction D2.

The device isolation layer ST may fill the trench TR. In detail, an insulating layer may be formed on the surface of the substrate 100 to cover at least a portion of the active pattern AP and a portion of the stack pattern STP. The insulating layer may be recessed until the stack pattern STP is exposed, and thus, the device isolation layer ST may be formed. The device isolation layer ST may be formed by a high density plasma chemical vapor deposition (HDP-CVD) process, a flowable chemical vapor deposition (FCVD) process, or another suitable deposition process.

The device isolation layer ST may include silicon oxide, silicon nitride, silicon oxynitride, fluorine-doped silicate glass (FSG), low-k dielectric materials, or combinations thereof. In an embodiment, the device isolation layer ST may include silicon oxide. The stack pattern STP may be exposed above the device isolation layer ST. For example, the stack pattern STP may protrude upward from the device isolation layer ST.

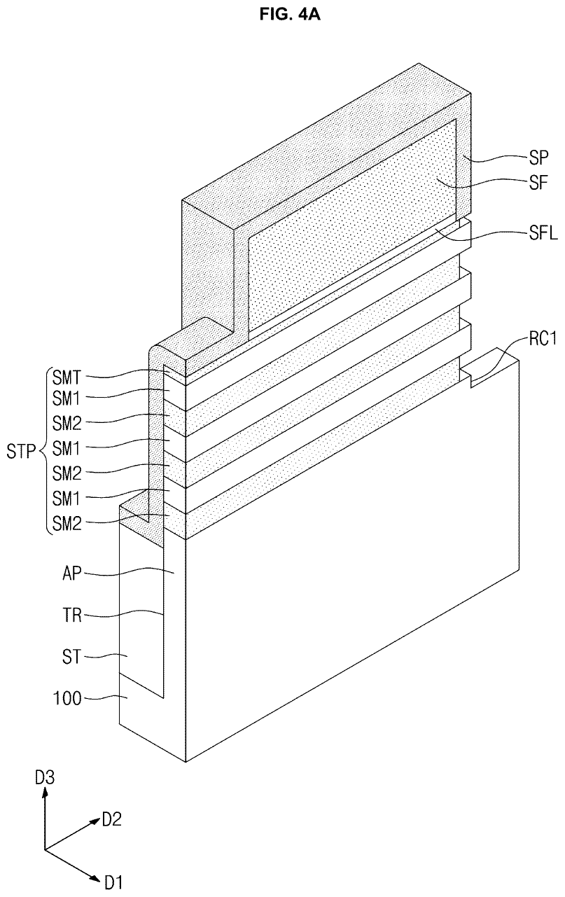

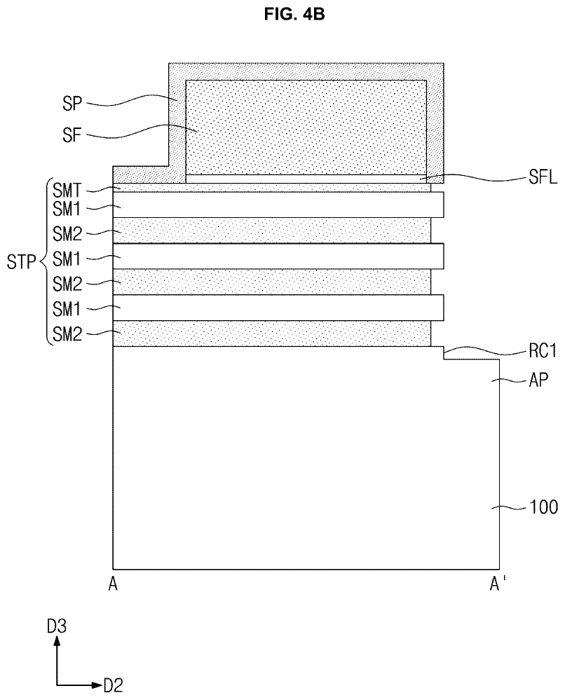

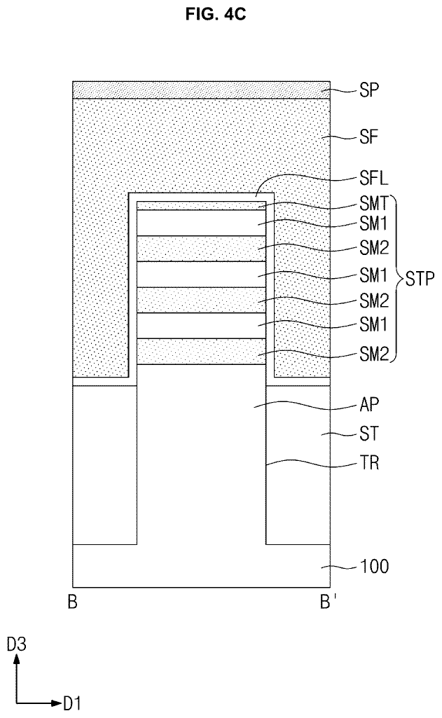

Referring to FIGS. 4A, 4B, and 4C, a sacrificial pattern SF and a sub-sacrificial pattern SFL, which cross the active pattern AP, may be formed on the substrate 100. In detail, the sub-sacrificial pattern SFL may be formed on the uppermost semiconductor layer SMT of the stack pattern STP, and the sacrificial pattern SF may be formed on the sub-sacrificial pattern SFL.

The sacrificial pattern SF may include various materials, and for example, may include polysilicon. The sub-sacrificial pattern SFL may include various insulating materials different from the stack pattern STP and/or the sacrificial pattern SF. For example, the sub-sacrificial pattern SFL may include SiOx, SiON, SiCN, SiCON, SiN, and the like.

The sacrificial pattern SF may be replaced by the gate electrode GE of the semiconductor device in a subsequent process. Accordingly, the sacrificial pattern SF may have substantially the same width as a width of the gate electrode GE.

The sacrificial pattern SF and the sub-sacrificial pattern SFL may have a line shape or bar shape extending in the first direction D1.

The formation of the sub-sacrificial pattern SFL and the sacrificial pattern SF may include sequentially forming a sub-sacrificial layer and a sacrificial layer on the surface of the substrate 100, forming a mask pattern on the sacrificial layer, and patterning a portion of the sacrificial layer and a portion of the sub-sacrificial layer simultaneously or sequentially using the mask pattern as an etch mask.

The sacrificial layer and the sub-sacrificial layer may be deposited using a chemical vapor deposition (CVD) including a low pressure CVD (LPCVD) and a plasma-enhanced CVD (PECVD), a physical vapor deposition (PVD), an atomic layer deposition (ALD), or other appropriate processes. The portions of the sacrificial layer and the sub-sacrificial layer may be removed using a plasma dry etching and/or wet etching. In some embodiments, when the sacrificial layer includes polysilicon, the wet etching may be performed to selectively remove the portion of the sacrificial layer, and various etching solutions, such as a tetramethylammonium hydroxide (TMAH) solution, may be used.

The gate spacer pattern SP may be formed on the sacrificial pattern SF. The gate spacer pattern SP may be conformally formed on the surface of the substrate 100. The gate spacer pattern SP may include materials such as SiOx, SiCN, SiCON, SiN, or SiON. As another example, the gate spacer pattern SP may have a multi-layer structure including at least two of SiCN, SiCON, and SiN.

The gate spacer pattern SP may be deposited using a chemical vapor deposition (CVD) including a low pressure CVD (LPCVD) and a plasma-enhanced CVD (PECVD), a physical vapor deposition (PVD), an atomic layer deposition (ALD), or other appropriate processes.

Then, a portion of the gate spacer pattern SP and a portion of the stack pattern STP on the active pattern AP may be removed, and thus, the first recess RC1 may be formed in one side of the stack pattern STP. The first recess RC1 may correspond to an area in which the first source/drain pattern SD1 is to be formed. In an embodiment, the first source/drain pattern SD1 may be used as a source of the semiconductor device.

The removal of a portion of the stack pattern STP may be performed by a dry etching and/or wet etching process suitable to perform the removal of a portion the gate spacer pattern SP together or separately. The etching process may be performed until an upper portion of the active pattern AP is exposed through the stack pattern STP. The etching process may also be performed anisotropically using the sacrificial pattern SF and the gate spacer pattern SP, which are provided on the stack pattern STP, as a mask. Accordingly, a side surface of the stack pattern STP, an upper surface of the active pattern AP, and an upper surface of the device isolation layer ST may be partially exposed by the first recess RC1. According to embodiments, the first recess RC1 may be formed deeper than the upper surfaces of the active pattern AP and/or the device isolation layer ST.

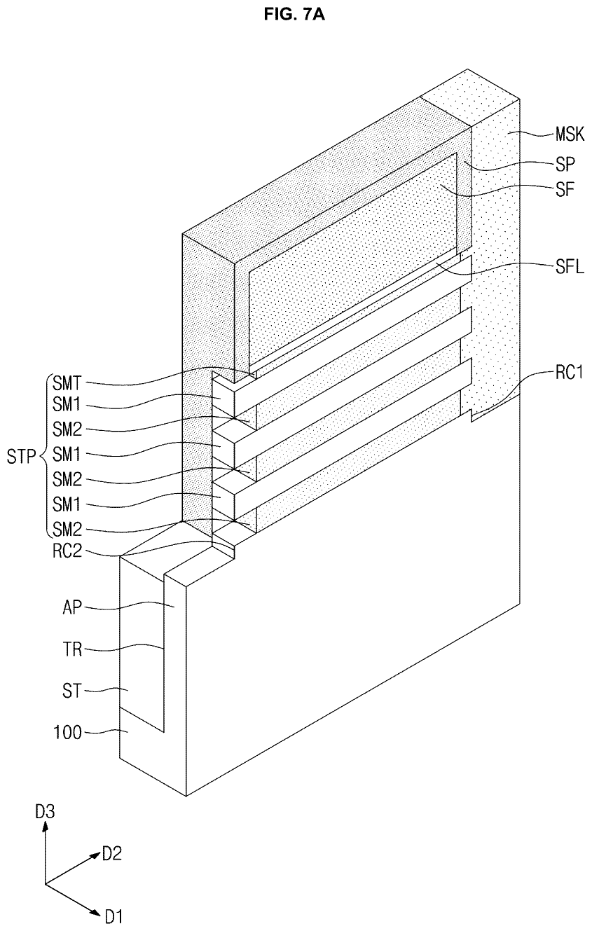

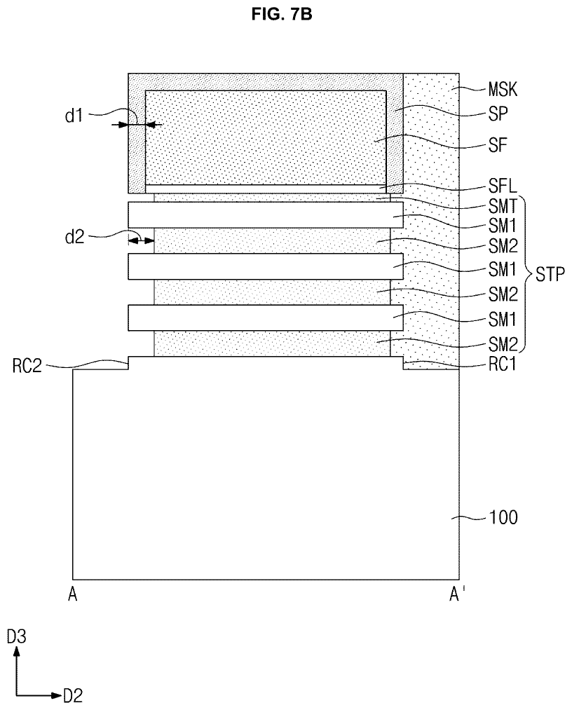

The remaining portion of the stack pattern STP exposed by the first recess RC1 may be selectively etched. For instance, the uppermost semiconductor layer SMT and the second semiconductor layers SM2 may be selectively etched. Since the uppermost semiconductor layer SMT and the second semiconductor layers SM2 are selectively etched, the side surfaces of the uppermost semiconductor layer SMT and the second semiconductor layers SM2 may have recessed portions that are recessed inward in a horizontal direction, for example, along the second direction D2, more than the side surfaces of the first semiconductor layers SM1. The uppermost semiconductor layer SMT and the second semiconductor layers SM2 may be recessed inward by a first distance d1 or about the first distance d1 (refer to FIG. 7B) from the side surfaces thereof before etching, or from the side surfaces of the first semiconductor layers SM1.

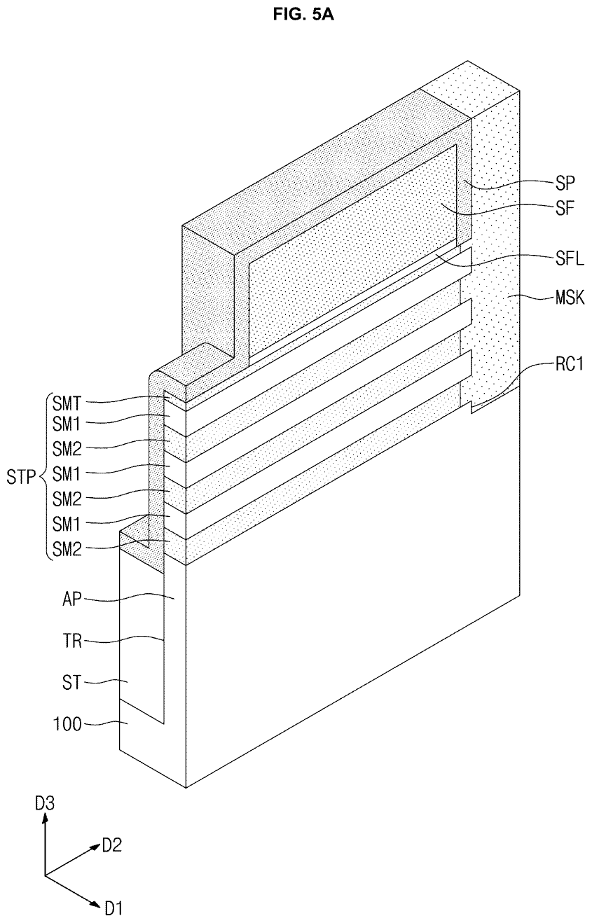

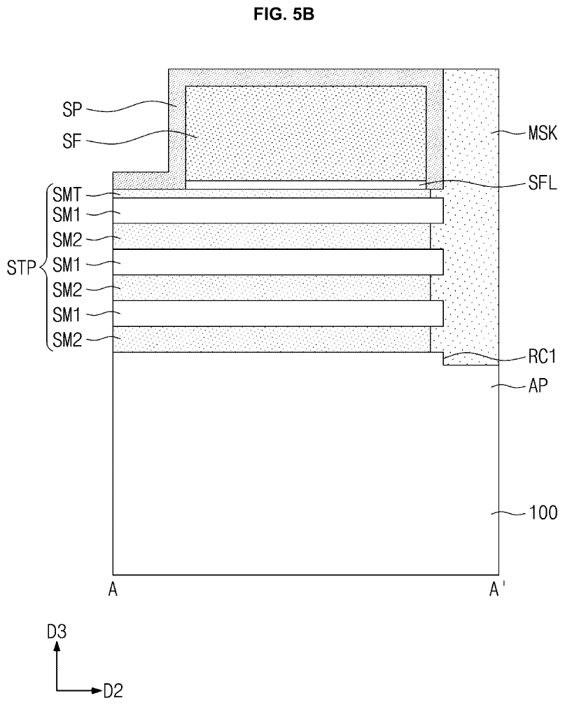

Referring to FIGS. 5A and 5B, a protective mask MSK may be formed in the first recess RC1.

For the following drawings, if there are no substantial changes, the description will refer to the drawings of the previous processes.

The protective mask MSK may be formed on the side surfaces of the stack pattern STP exposed by the first recess RC1 to block effects from subsequent processes. The protective mask MSK may be formed of a photosensitive material such as photoresist. The protective mask MSK may be formed by forming a photoresist layer on a front surface of the substrate 100 and patterning the photoresist layer.

In an embodiment, the protective mask MSK may be formed only in the first recess RC1 and may not be formed in other areas. An upper surface of the protective mask MSK may be coplanar with an upper surface of the gate spacer pattern SP.

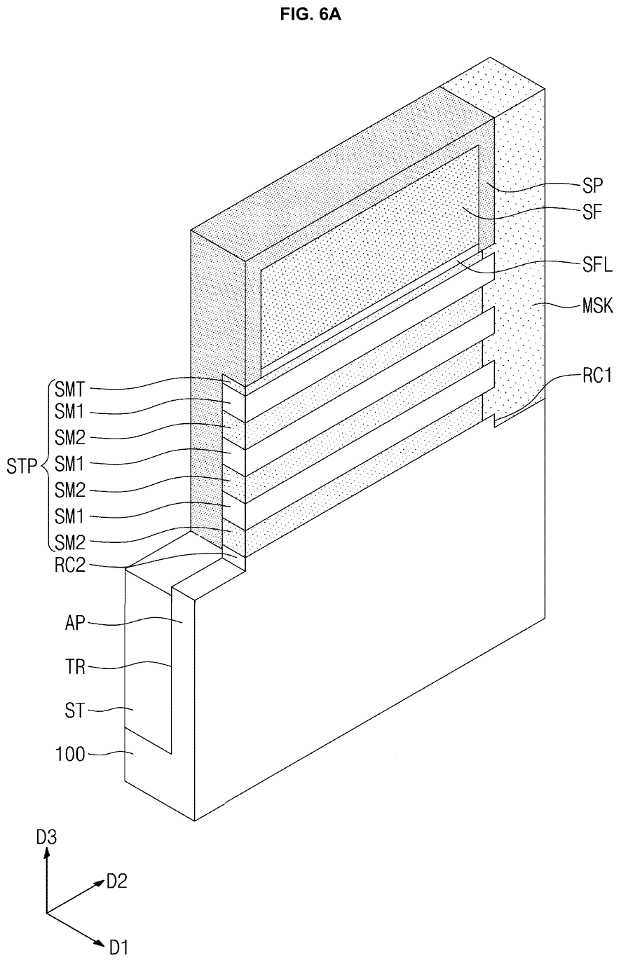

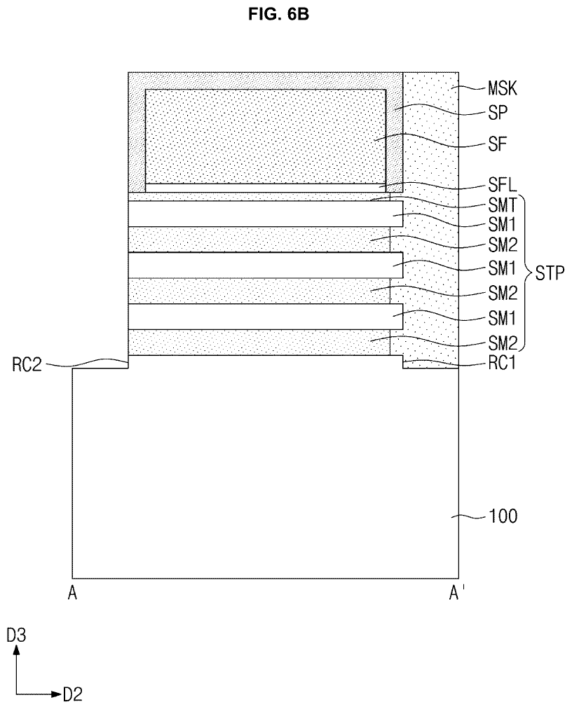

Referring to FIGS. 6A, 6B, and 4C, the second recess RC2 may be formed on the other side of the stack pattern STP by removing a portion of the gate spacer pattern SP and a portion of the stack pattern STP on the active pattern AP. The first recess RC1 may be formed on the one side of the stack pattern STP extending in the second direction D2, and the second recess RC2 may be formed on the other side of the stack pattern STP. The second recess RC2 may correspond to an area in which the second source/drain pattern SD2 is to be formed. In an embodiment, the second source/drain pattern SD2 may be used as a drain of the semiconductor device.

The removal of a portion of the gate spacer pattern SP and a portion of the stack pattern STP in this step may also be performed together or separately by a suitable dry etching and/or wet etching process. The etching process may be performed until the upper portion of the active pattern AP is exposed through the stack pattern STP. The etching process may also be performed anisotropically using the sacrificial pattern SF and the gate spacer pattern SP, which are provided above the stack pattern STP, as a mask. Accordingly, the side surface of the stack pattern STP, the upper surface of the active pattern AP, and the upper surface of the device isolation layer ST may be partially exposed through the second recess RC2. In an embodiment, the side surface of the stack pattern STP exposed through the second recess RC2 may be substantially coplanar or aligned with the side surface of the gate spacer pattern SP, and the second recess RC2 may include a recessed portion downwardly recessed with respect to the upper surfaces of the active pattern AP and/or the device isolation layer ST.

An additional dopant implantation for forming the lightly doped drain (LDD) region may be performed on the front surface of the substrate 100 in which the second recess RC2 is formed. Since the area where the first recess RC1 is formed is protected by the protective mask MSK, the stack pattern STP and the active area may not be exposed, and thus the effect of the dopant implantation may be less than in the area where the second recess RC2 is formed. For example, an amount of dopants implanted into the area where the second recess RC2 is formed and its adjacent areas may be greater than an amount of dopants implanted into the area where the first recess RC1 is formed and its adjacent areas. Accordingly, a dopant concentration profile along the second direction D2 of the subsequently fabricated semiconductor device may have an asymmetric shape with respect to the source and the drain.

Referring to FIGS. 7A, 7B, and 4C, a portion of the stack pattern STP exposed through the second recess RC2 may be selectively etched. For example, the exposed side surfaces of the uppermost semiconductor layer SMT and the second semiconductor layers SM2 may be selectively etched.

As the uppermost semiconductor layer SMT and the second semiconductor layers SM2 are selectively etched, the side surfaces of the uppermost semiconductor layer SMT and the second semiconductor layers SM2 may have recessed portions that are recessed inward along the horizontal direction more than the side surfaces of the first semiconductor layers SM1.

According to the present embodiment, a degree of recess described above in reference to FIGS. 4A-4C and 7A-7B may be controlled by varying etching conditions for the uppermost semiconductor layer SMT and the second semiconductor layers SM2. In an embodiment, the uppermost semiconductor layer SMT may be etched until a lower surface of a portion of the sub-sacrificial pattern SFL is exposed. The uppermost semiconductor layer SMT and the second semiconductor layers SM2 may be recessed inward by a second distance d2 from the side surfaces thereof before etching.

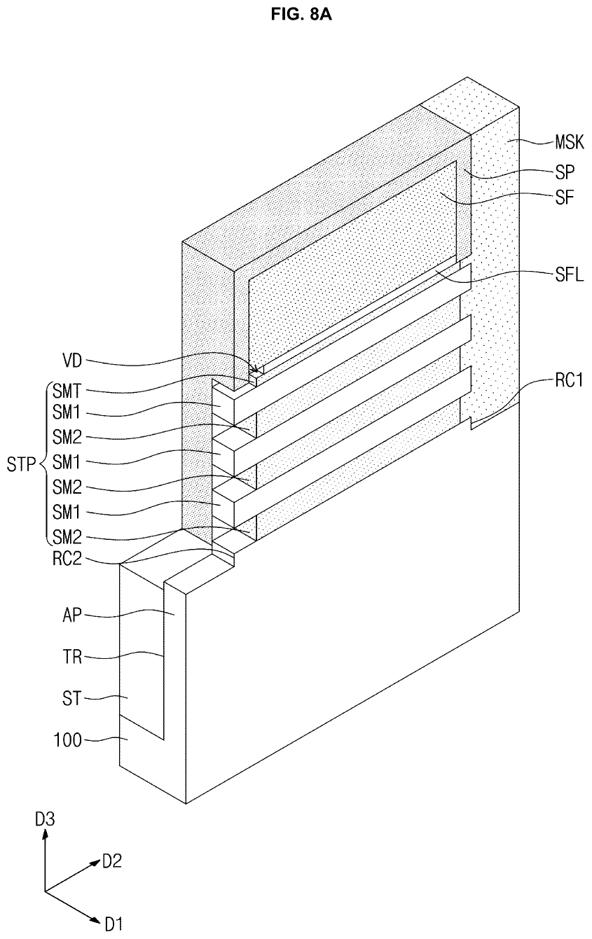

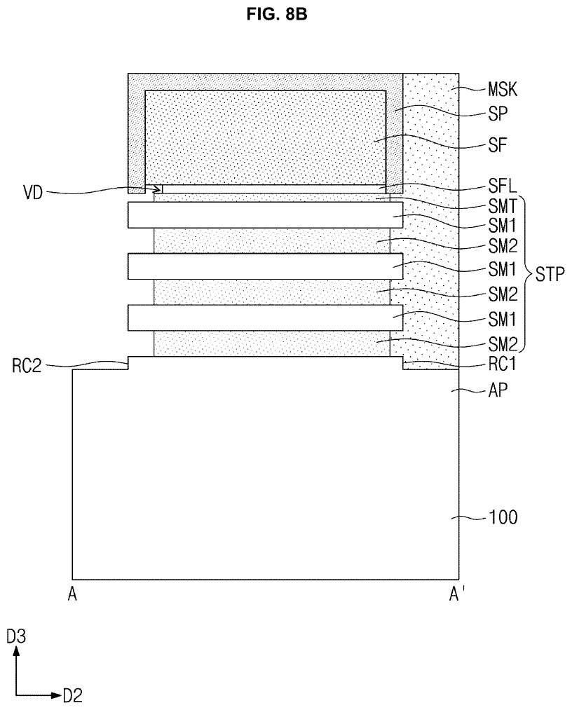

Referring to FIGS. 8A, 8B, and 4C, the portion of the sub-sacrificial pattern SFL exposed through the etching operation described above in reference to FIGS. 7A, 7B and 4C may be etched. The sub-sacrificial pattern SFL may be partially etched inwardly from its exposed lower surface, and the etching process for the sub-sacrificial pattern SFL may be performed until a lower surface of a portion of the sacrificial pattern SF is exposed. As a result, a void VD may be formed, which is surrounded by an inner side surface of the gate spacer pattern SP, the lower surface of the sacrificial pattern SF, a side surface of the sub-sacrificial pattern SFL, and an upper surface of the uppermost semiconductor layer SMT.

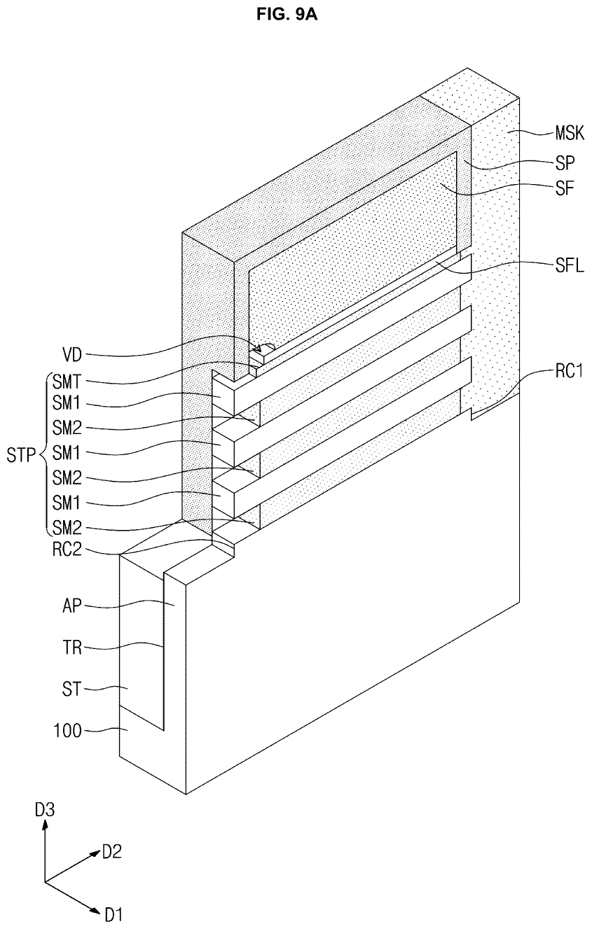

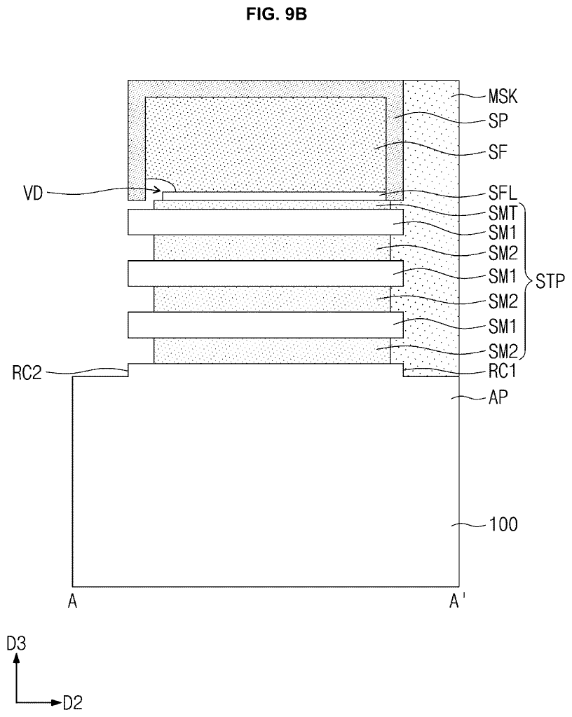

Referring to FIGS. 9A, 9B, and 4C, the portion of the sacrificial pattern SF exposed through the etching operation described above in reference to FIGS. 8A, 8B and 4C may be etched. The sacrificial pattern SF may include a material, for example, polysilicon, having etch selectivity with respect to the materials constituting the sub-sacrificial pattern SFL and the stack pattern STP.

The sacrificial pattern SF may be etched sequentially inward from its exposed lower surface. Through the inward etching, the sacrificial pattern SF may have a recess inward. As the sacrificial pattern SF is partially etched, the void VD that becomes larger than that in the previous process may be formed. Accordingly, the void VD may be surrounded by the inner side surface of the gate spacer pattern SP, the side surface of the recess in the sacrificial pattern SF, the side surface of the sub-sacrificial pattern SFL, and the upper surface of the uppermost semiconductor layer SMT.

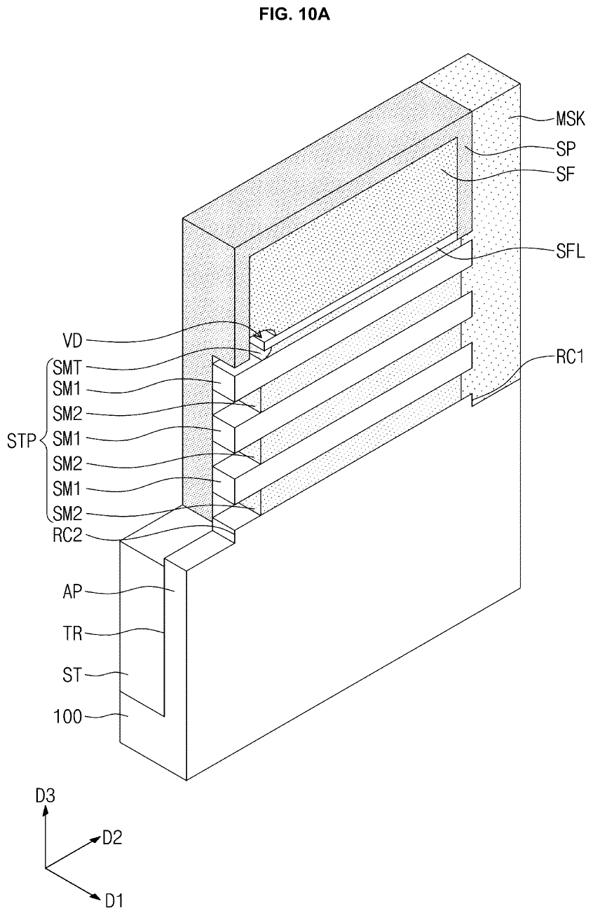

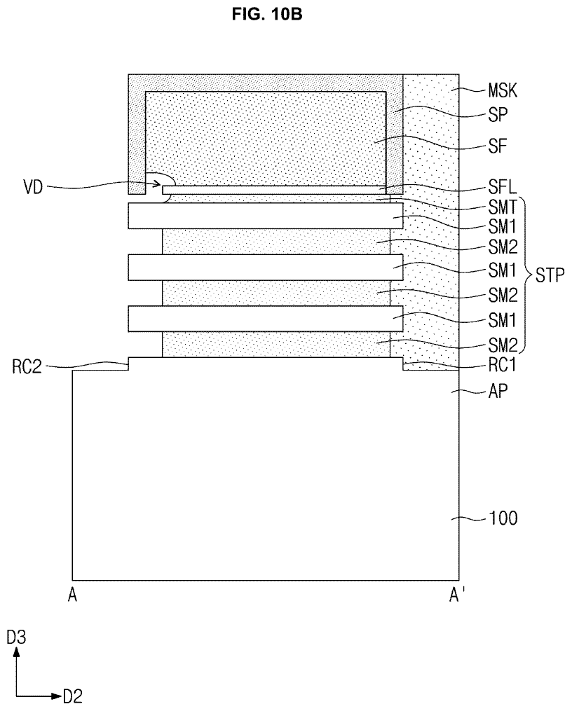

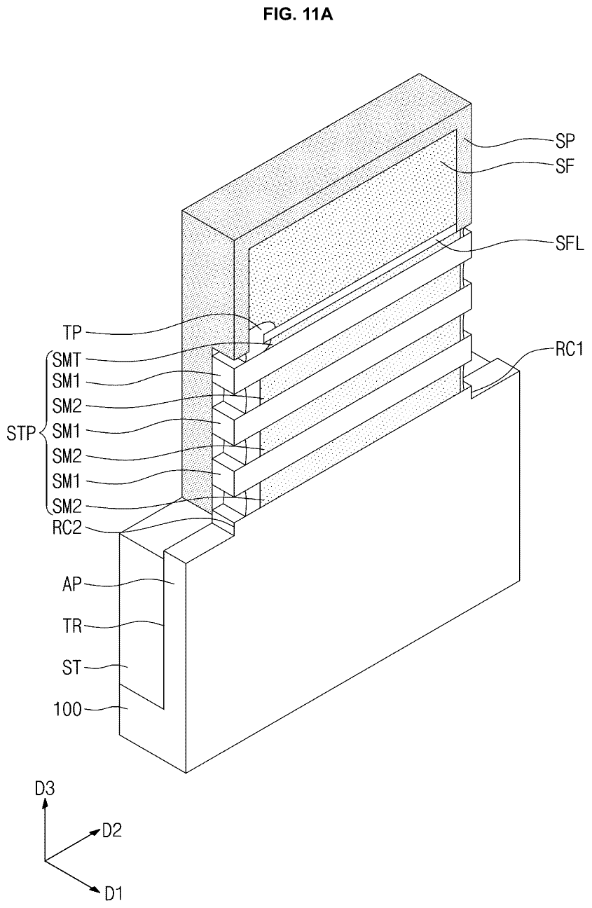

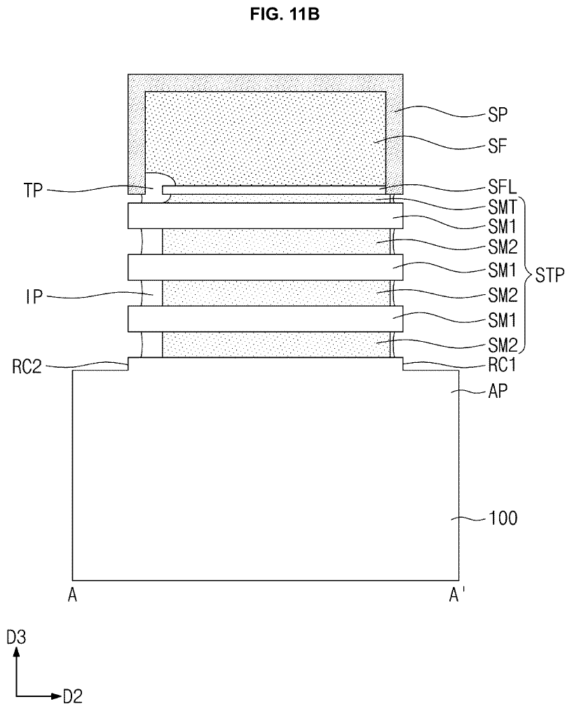

Referring to FIGS. 10A, 10B, and 4C, an additional etching process may be performed to expand the void VD. The additional etching process may be to etch the uppermost semiconductor layer SMT and the second semiconductor layers SM2.

Since the uppermost semiconductor layer SMT and the second semiconductor layers SM2 are selectively etched, the side surfaces of the uppermost semiconductor layer SMT and the second semiconductor layers SM2 may be recessed further inward along the horizontal direction than the side surface of the sub-sacrificial pattern SFL. For example, the uppermost semiconductor layer SMT may be etched until a lower surface of a portion of the sub-sacrificial pattern SFL is exposed. The recess may have a third distance inward from the side surfaces of the first semiconductor layers SM1. In the present embodiment, the third distance may be greater than the first distance d1, and this means that a shape of the stack pattern STP is asymmetric in the horizontal direction with respect to a center of the semiconductor device. As a result, the void VD may be formed to be larger than in the previous etching process.

Referring to FIGS. 11A, 11B, and 4C, since the protective mask MSK formed in the first recess RC1 is removed, the side surface of the stack pattern STP corresponding to the first recess RC1 may be exposed to the outside. That is, the side surfaces of the uppermost semiconductor layer SMT, the first semiconductor layers SM1, and the second semiconductor layers SM2 may be exposed to the outside.

Then, the inner spacer IP and the sloped insulation pattern TP may be formed on the exposed side surface of the stack pattern STP. The inner spacer IP and the sloped insulation pattern TP may be formed by conformally forming an inner spacer insulating layer on the substrate 100 and anisotropically patterning a portion of the inner spacer insulating layer.

The inner spacer IP and the sloped insulation pattern TP may include at least one of SiO₂, SiN, SiC, SiOC, SiON, and AlOx.

The inner spacer insulating layer may be formed on the front surface of the substrate 100 including the void VD and recesses in the uppermost semiconductor layer SMT and the second semiconductor layers SM2. Then, portions of the inner spacer insulating layer, except for the remaining portion thereof in the void VD and the recesses may be removed. As a result, the inner spacer IP may be formed between the first semiconductor layers SM1 adjacent to the first recess RC1 and between the second semiconductor layers SM2 adjacent to the second recess RC2. In addition, the sloped insulation pattern TP may be formed in the void VD adjacent to the second recess RC2.

Since the inner spacer insulating layer is patterned, the side surfaces of the sloped insulation pattern TP and the inner spacer IP, which are exposed outwardly, may be recessed inward more than the side surfaces of the first semiconductor layers SM1. In the present embodiment, since the uppermost semiconductor layer SMT and the second semiconductor layers SM2 include the side surfaces asymmetrically recessed with respect to both sides of the first semiconductor layers SM1 along the second direction D2, the finally formed inner spacer IP may be asymmetrical. For instance, a width of the inner spacer IP adjacent to the second recess RC2 may be greater than a width of the inner spacer IP adjacent to the first recess RC1 in the second direction D2.

In an embodiment, the gate spacer pattern SP may be formed of the same material as the sub-sacrificial pattern SFL. In this case, the sloped insulation pattern TP remaining after etching of the gate spacer pattern SP may be integrally provided with the sub-sacrificial pattern SFL without being separated from the sub-sacrificial pattern SFL.

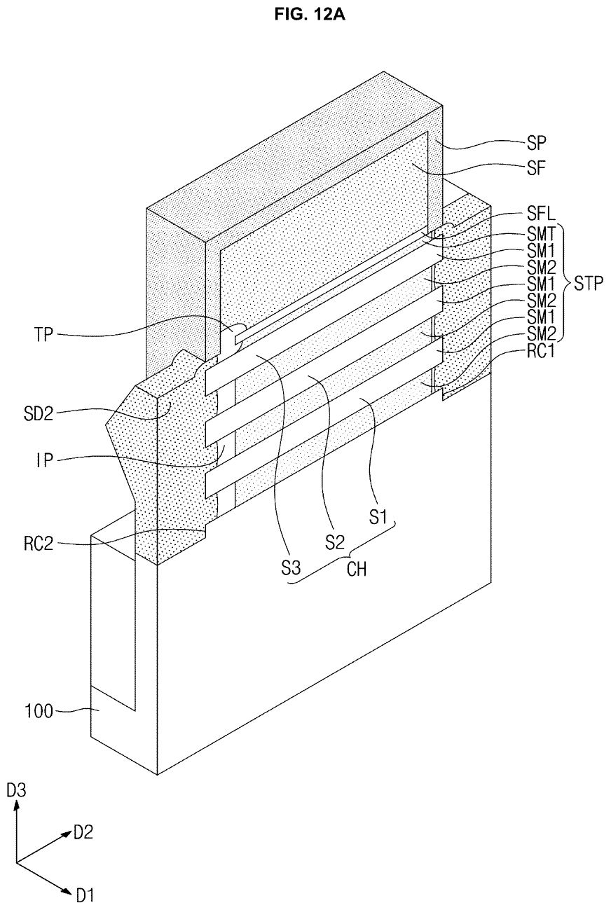

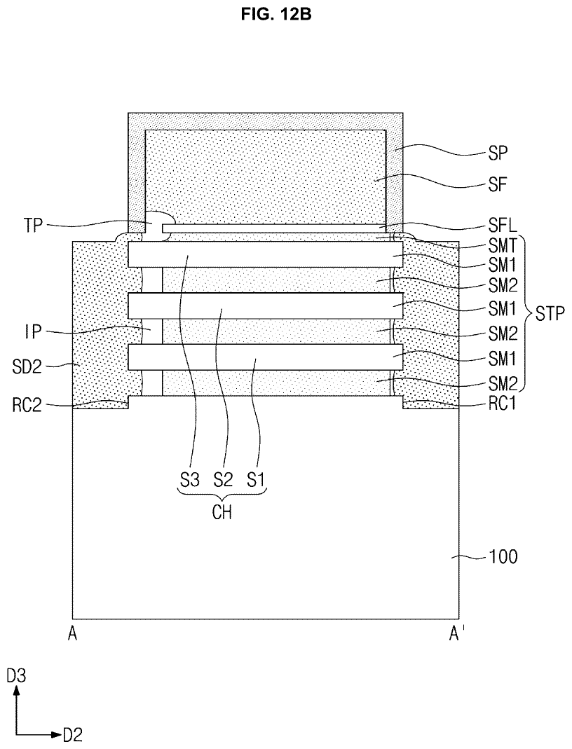

Referring to FIGS. 12A, 12B, and 4C, the first source/drain pattern SD1 may be formed in the first recess RC1, and the second source/drain pattern SD2 may be formed in the second recess RC2. The first and second source/drain patterns SD1 and SD2 may be formed on opposite sides of the stack pattern STP.

A lower portion of each of the first and second source/drain patterns SD1 and SD2 may include a semiconductor material doped with a predetermined dopant. A height of the first source/drain pattern SD1 may be modified in various way. In FIGS. 12A and 12B, the upper surfaces of the first and second source/drain patterns SD1 and SD2 are illustrated as being formed at substantially the same height as the upper surface of the uppermost first semiconductor layer SM1, however, the present disclosure should not be limited thereto or thereby. For example, the upper surfaces of the first and second source/drain patterns SD1 and SD2 may be higher than the upper surface of the uppermost first semiconductor layer SM1.

To form the first and second source/drain patterns SD1 and SD2, a first selective epitaxial growth (SEG) process may be performed using inner walls of the first and second recesses RC1 and RC2 as seed layers, and thus, a buffer layer may be formed. The buffer layer may be grown using the first, second, and third semiconductor patterns S1, S2, and S3 and the substrate 100, which are exposed through the first and second recesses RC1 and RC2, as seeds. For example, the first SEG process may include a chemical vapor deposition (CVD) process or a molecular beam epitaxy (MBE) process.

The buffer layer may include a semiconductor element, such as SiGe, having a lattice constant larger than that of the semiconductor element of the substrate 100. The buffer layer may include a relatively low concentration of germanium. As another embodiment, the buffer layer may include only silicon (Si) without germanium. The concentration of germanium in the buffer layer may be in a range from about 0 at % to about 10 at %.

A second selective epitaxial growth (SEG) process may be performed on the buffer layer to form a main layer. The main layer may be formed to completely or nearly fill the first recess RC1. The main layer may include a relatively high concentration of germanium. For example, the concentration of germanium in the main layer may be in a range from about 30 at % to about 70 at %.

During the formation of the buffer layer and the main layer, the first and second source/drain patterns SD1 and SD2 may be in-situ doped with dopants such as a P-type dopant (e.g., boron, gallium, or indium) or an N-type dopant (e.g., phosphorus, arsenic, or antimony). As another example, dopants may be implanted into the first and second source/drain patterns SD1 and SD2 after the formation of the first and second source/drain patterns SD1 and SD2.

In one or more embodiments, the P-type dopant may be implanted into the first and second source/drain patterns SD1 and SD2 at high concentration.

As the first and second source/drain patterns SD1 and SD2 are formed, the channel pattern CH may be formed between the first source/drain pattern SD1 and the second source/drain pattern SD2. The channel pattern CH may include the first, second, and third semiconductor patterns S1, S2, and S3 that are sequentially stacked. The first and second source/drain patterns SD1 and SD2 shown in FIG. 12A may have a hexagonal shape when viewed from one direction. However, the shape of the first and second source/drain patterns SD1 and SD2 may vary depending on design. For example, the first and second source/drain patterns SD1 and SD2 for P-type devices may have different shapes from those of the first and second source/drain patterns SD1 and SD2 for N-type devices.

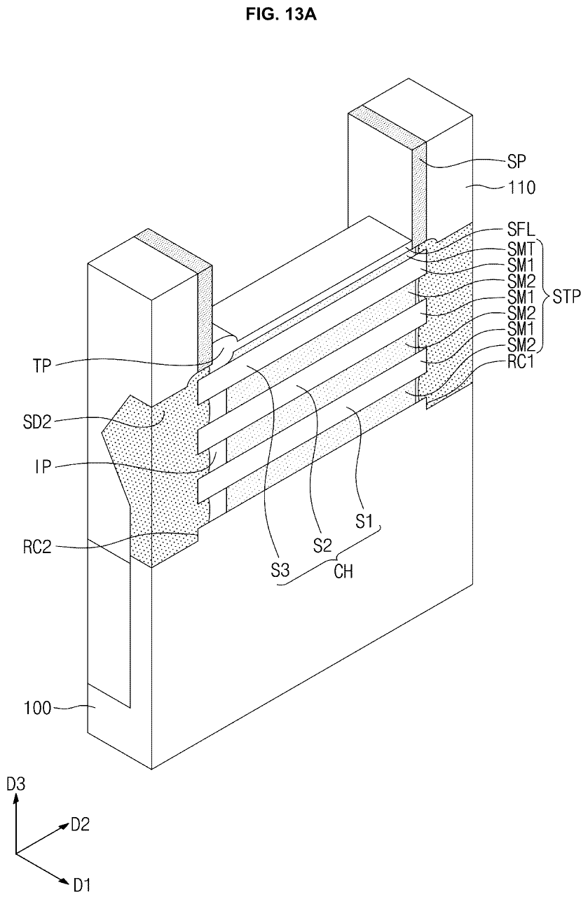

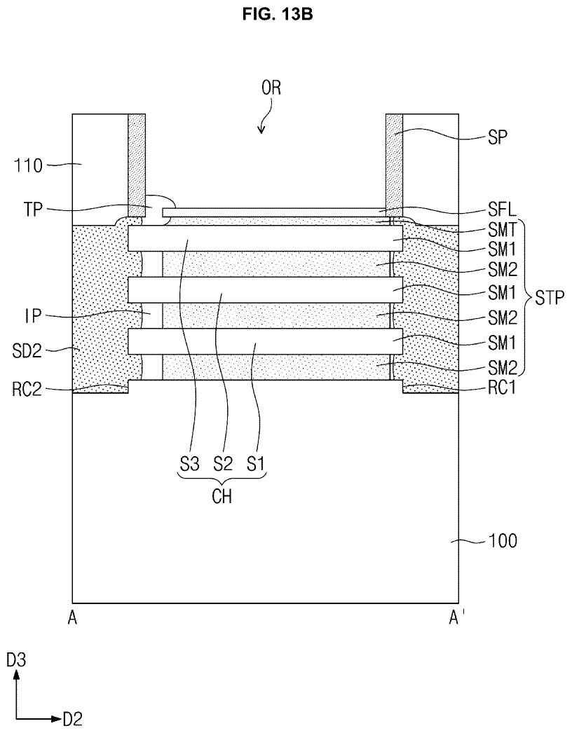

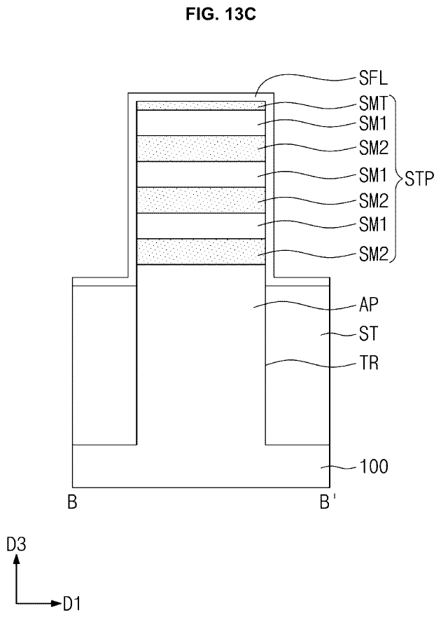

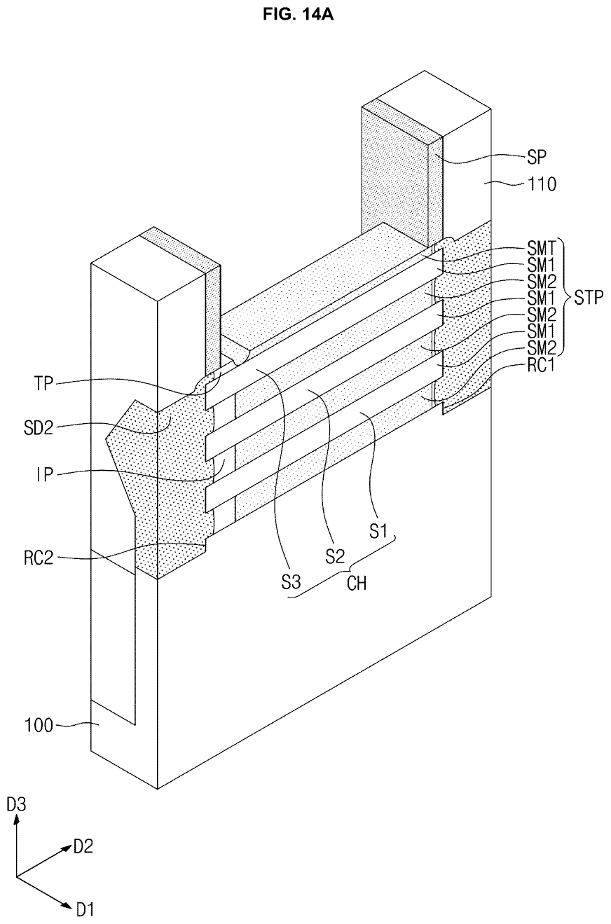

Referring to FIGS. 13A to 13C, the cover layer 110 may be formed to cover the first source/drain pattern SD1, the second source/drain pattern SD2, and the gate spacer pattern SP. The cover layer 110 may include a compound including Si, O, C, and/or H, such as SiCOH or SiOC. For example, the cover layer 110 may include silicon oxide.

The cover layer 110 may be planarized until the upper surfaces of the sacrificial pattern SF are exposed. The planarization of the cover layer 110 may be performed by an etch-back process or a chemical mechanical polishing (CMP) process. The gate spacer patterns SP disposed on the sacrificial pattern SF may be entirely removed during the planarization process. As a result, the upper surface of the cover layer 110 may be coplanar with the upper surfaces of the sacrificial pattern SF and the upper surfaces of the gate spacer patterns SP.

Then, the sacrificial pattern SF may be selectively removed using photolithography to form an outer region OR. The sacrificial pattern SF may be removed by a wet etching process. In the wet etching process, for example, an etchant capable of selectively etching polysilicon may be used.

As the sacrificial pattern SF is removed, the upper surface of the sub-sacrificial pattern SF, the upper surface of the sloped insulation pattern TP, and the side surfaces of the gate spacer pattern SP may be exposed. The sloped insulation pattern TP may be provided on the upper surface of the first semiconductor layer SM1, but only on the side adjacent to the second source/drain pattern SD2. The sloped insulation pattern TP may be formed to be thicker than the sub-sacrificial pattern SFL. One side of the upper surface of the sloped insulation pattern TP, i.e., one side of the slope surface, may be in contact with the gate spacer pattern SP, and the other side of the upper surface of the sloped insulation pattern TP, i.e., the other side of the slope surface, may be in contact with the sub-sacrificial pattern SFL. When viewed in a cross-section, the sloped insulation pattern TP may have a slope shape extending from the portion in contact with the gate spacer pattern SP to the portion in contact with the sacrificial pattern SF.

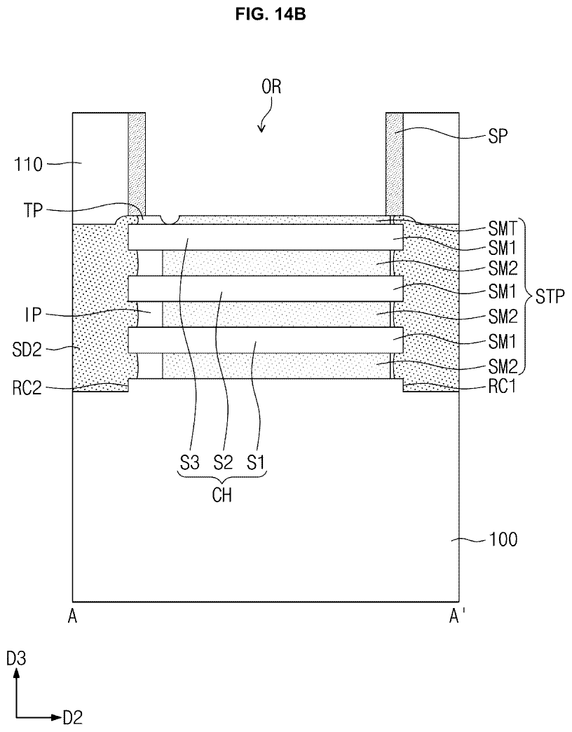

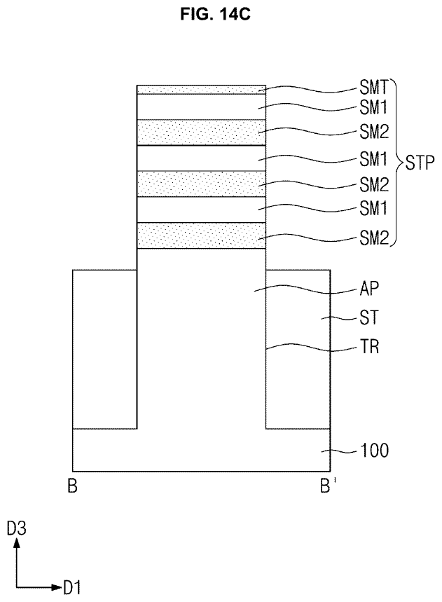

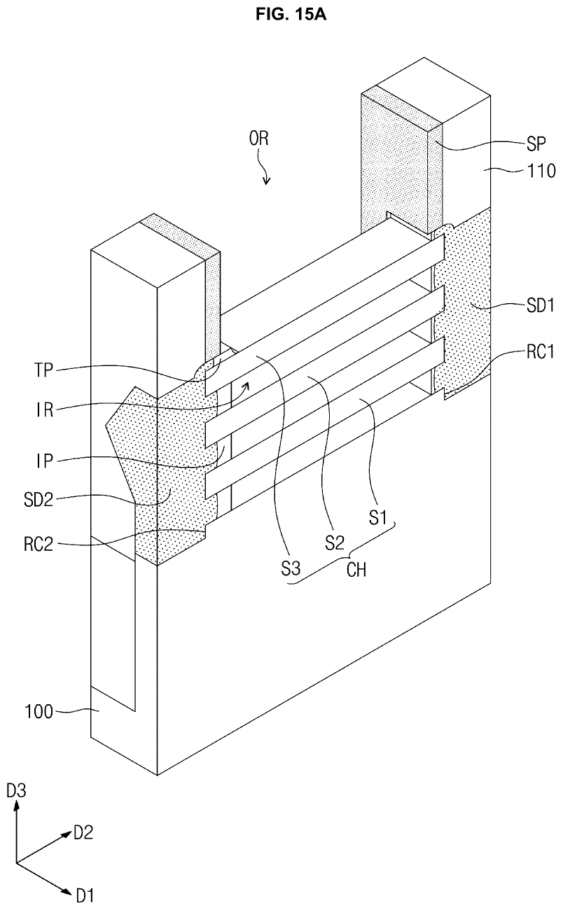

Referring to FIGS. 14A to 14C, a portion of the sloped insulation pattern TP and the lower sacrificial pattern SFL, which are exposed to the outside, may be etched and removed. In this process, only the portion of the sloped insulation pattern TP may be removed, while the lower sacrificial pattern SFL may be entirely removed. As a result, a portion of the uppermost semiconductor layer SMT and the sloped insulation pattern TP may remain on the upper surface of the first semiconductor layer SM1. The height of the sloped insulation pattern TP may be further reduced due to the etching. One side of the slope surface of the sloped insulation pattern TP with reduced height may be in contact with the gate spacer pattern SP, and the other side of the slope surface of the sloped insulation pattern TP may be in contact with the upper surface of the uppermost first semiconductor layer SM1.

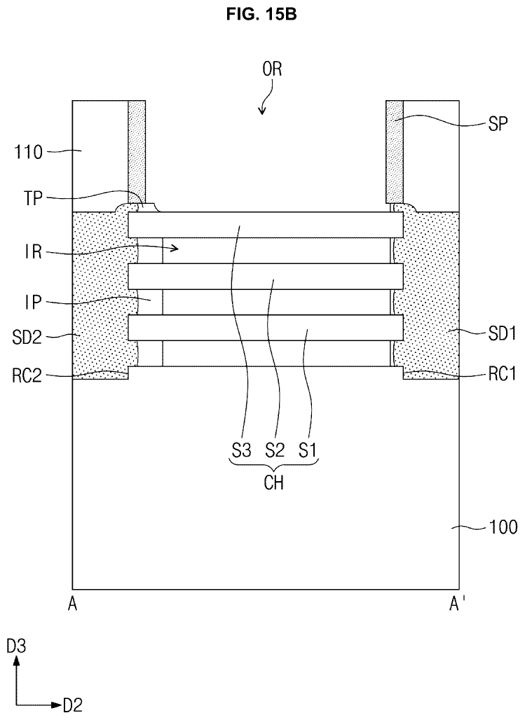

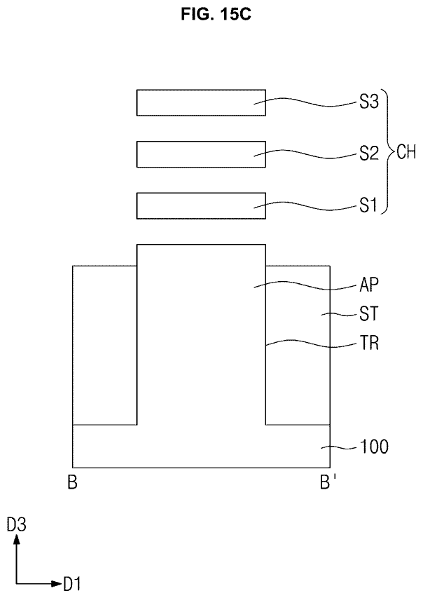

Referring to FIGS. 15A to 15C, the uppermost semiconductor layer SMT exposed through the outer region OR and the second semiconductor layers SM2 may be selectively removed. Due to the removal of the second semiconductor layers SM2, inner regions IR may be formed between the first semiconductor layers SM1 adjacent to each other. The outer region OR may be a region that contacts an upper region of a uppermost semiconductor layer SMT as well as the side surfaces of the first, second, and third semiconductor patterns S1, S2, and S3. The inner regions IR may be regions located between the substrate 100 and the first semiconductor pattern S1 and between first, second, and third semiconductor patterns S1, S2, and S3 adjacent to each other.

In detail, an etching process for selectively etching the second semiconductor layers SM2 may be performed to remove only the second semiconductor layers SM2 while the first, second, and third semiconductor patterns S1, S2, and S3 remain intact. The etching process may utilize the etch selectivity between the first semiconductor layers SM1 and the second semiconductor layers SM2. For instance, silicon-germanium with a relatively high germanium concentration may have a higher etch rate than silicon-germanium with a relatively low germanium concentration. The first source/drain pattern SD1 may be protected during the etching process due to its material with a low etch selectivity, for example, a material with a relatively low germanium concentration. In an embodiment, the second semiconductor layers SM2 may be selectively etched using a wet etching solution, including but not limited to hydrogen peroxide, hydrofluoric acid, acetic acid, ammonium hydroxide (NH₄OH), tetramethylammonium hydroxide (TMAH), ethylenediamine pyrocatechol (EDP), and/or potassium hydroxide (KOH).

As the second semiconductor layers SM2 are selectively removed, the stacked first, second, and third semiconductor patterns S1, S2, and S3, the sloped insulation pattern TP, and the inner spacer IP may remain on each active pattern AP.

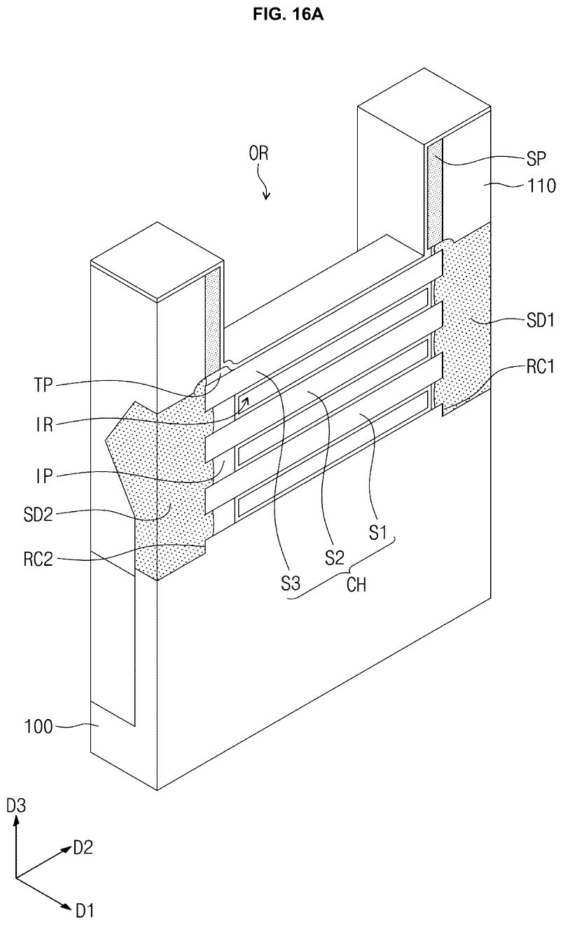

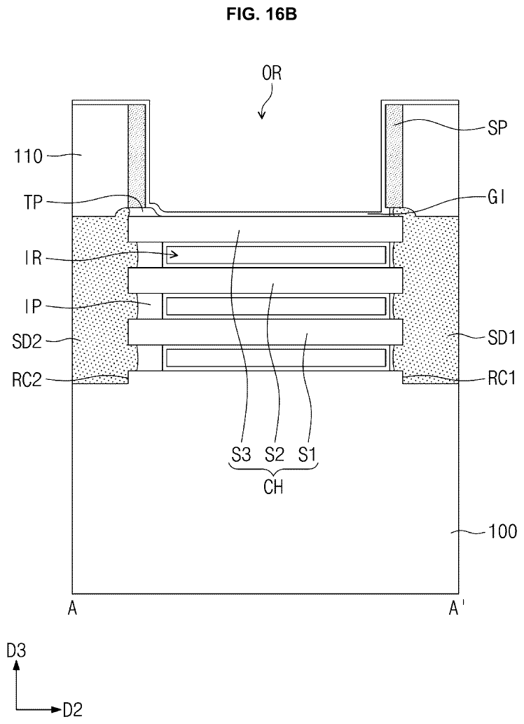

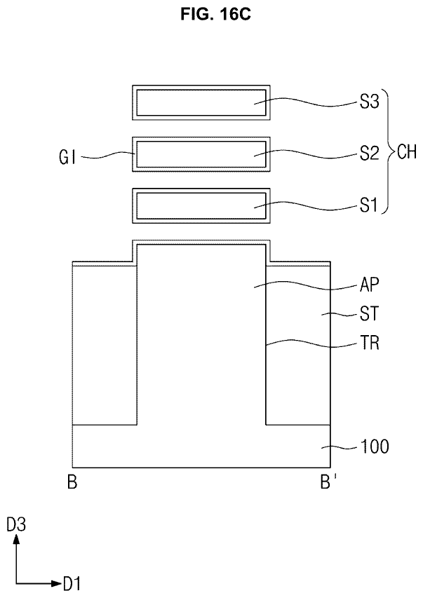

Referring to FIGS. 16A to 16C, the gate insulating layer GI may be conformally formed in the inner region IR and the outer region OR that are exposed to the outside on the active pattern AP.

The gate insulating layer GI may include the interfacial layer and the high-k dielectric layer disposed on the interfacial layer. In an embodiment, the high-k dielectric layer may have a thickness thicker than the interfacial layer. The interfacial layer may include silicon oxide or silicon oxynitride. The high-k dielectric layer may include a high dielectric constant material having a dielectric constant higher than silicon oxide. As an example, the high dielectric constant material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanate oxide, barium titanate oxide, strontium titanate oxide, lithium oxide, aluminum oxide, lead scandium tantalate oxide, and lead zinc niobate.

The gate insulating layer GI may be formed by chemical vapor deposition (CVD), atomic layer deposition (ALD), or other appropriate processes.

In an embodiment, the gate insulating layer GI may include the same material as the sloped insulation pattern TP. When the gate insulating layer GI includes the same material as the sloped insulation pattern TP, the gate insulating layer GI and the sloped insulation pattern TP may be integrally formed as a single structure. Even when the gate insulating layer GI and the sloped insulation pattern TP are provided as separate structures, the gate insulating layer GI and the sloped insulation pattern TP may function as the insulating field plate.

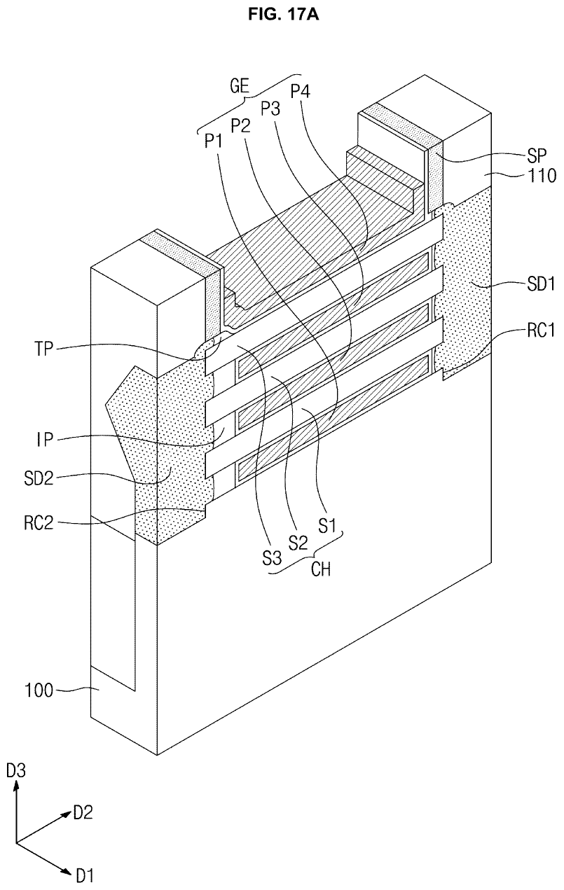

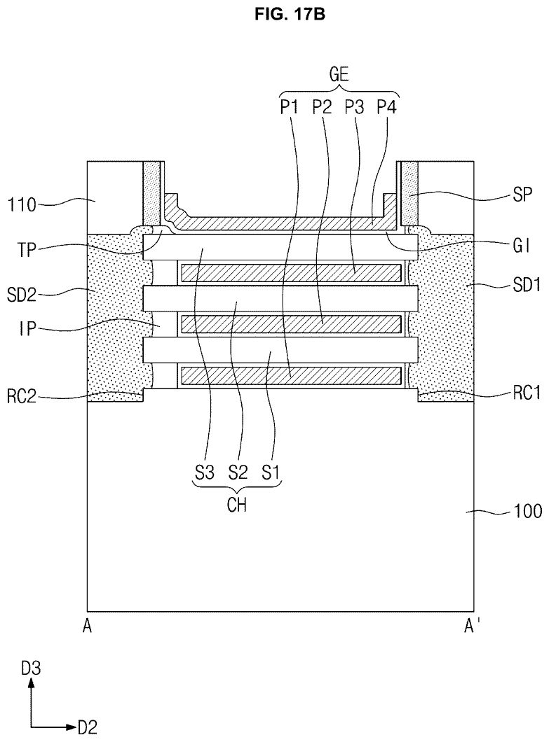

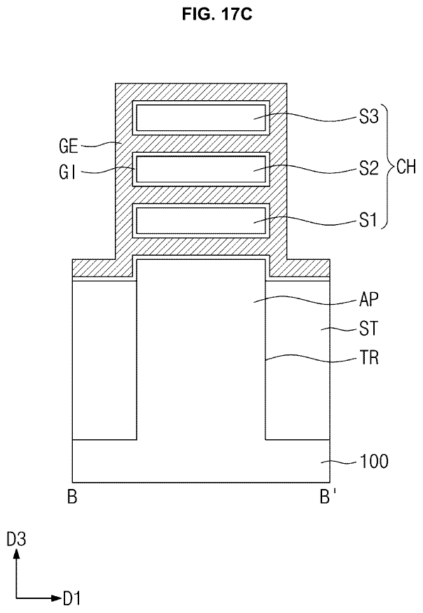

Referring to FIGS. 17A to 17C, the gate electrode GE may be formed on the gate insulating layer GI. The gate electrode GE may be formed to fill a portion of the outer region OR and the inner region IR. The gate electrode GE may include the first, second, and third portions P1, P2, and P3 respectively formed in the inner regions IR and the fourth portion P4 formed in the outer region OR.

A portion of the fourth portion P4 of the gate electrode GE, for example, a portion adjacent to the second source/drain pattern SD2, may be provided on the sloped insulation pattern TP. As a result, the portion of the fourth portion P4 of the gate electrode GE may have a shape, that is, a slope shape, corresponding to the shape of the sloped insulation pattern TP.

The gate electrode GE may include one or more layers of a conductive material such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. In some embodiments, the gate electrode GE may be formed by chemical vapor deposition (CVD), atomic layer deposition (ALD), electroplating, or other appropriate processes.

A semiconductor device according to one or more embodiments may have a structure different from the above-described structure or may be manufactured by different methods. For example, a method of manufacturing the semiconductor device according to the embodiments of the disclosure may include forming a stacked structure in which the first semiconductor layers are alternately stacked with the second semiconductor layers, and the stack pattern may not include the uppermost semiconductor layer as in the embodiment described above.

Hereinafter, a semiconductor device and/or a method of manufacturing the semiconductor device according to one or more embodiments will be described, focusing on different features from the above-described embodiment. Descriptions of the parts that are the same as or similar to those in the above-described embodiment will be minimized or simplified.

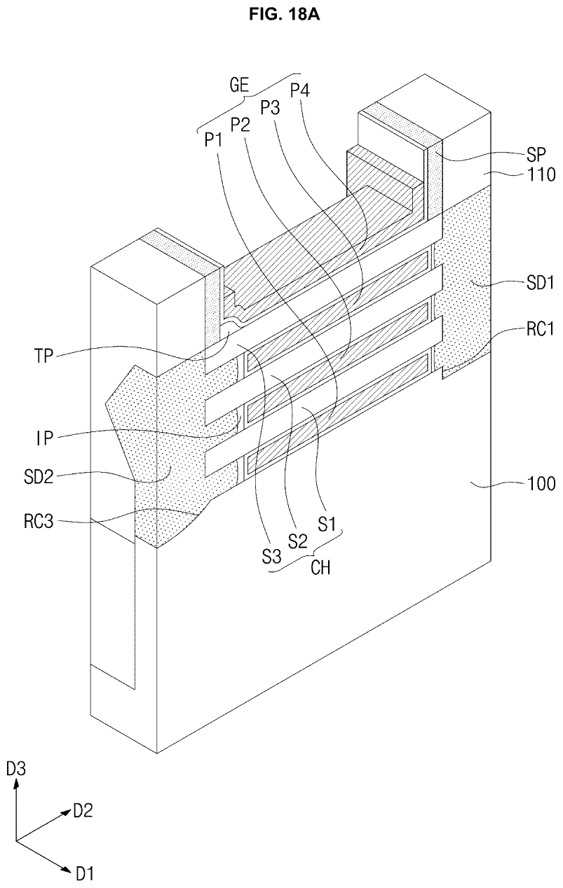

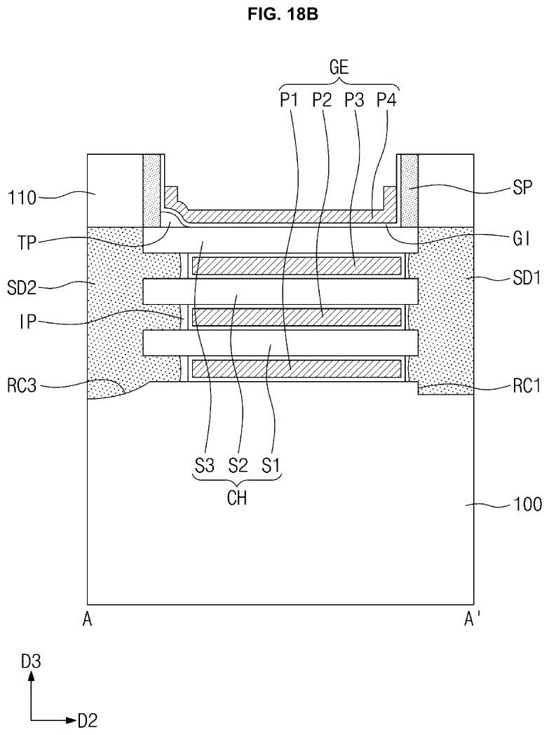

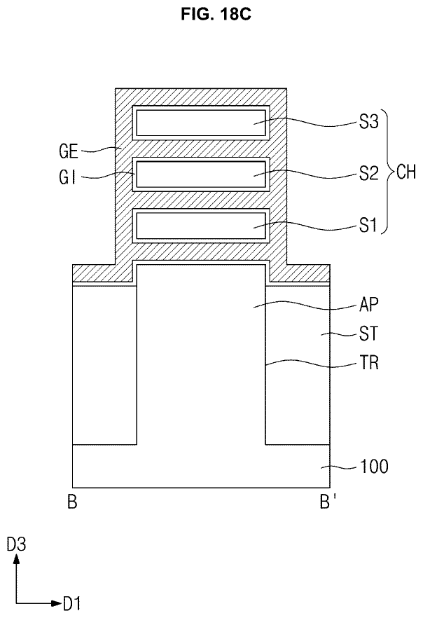

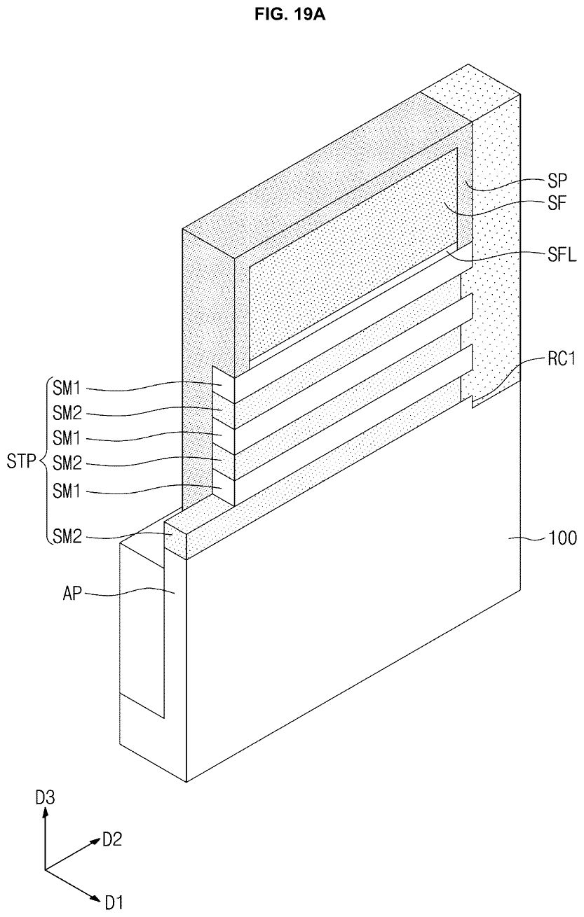

FIGS. 18A to 18C are views illustrating a semiconductor device according to one or more embodiments, FIG. 18A is a cross-sectional perspective view taken along the line A-A′ of FIG. 1B, FIG. 18B is a cross-sectional view taken along the line A-A′ of FIG. 1B, and FIG. 18C is a cross-sectional view taken along the line B-B′ of FIG. 1B.

The semiconductor device according to the present embodiments is substantially the same as the semiconductor device illustrated in FIGS. 2A to 2D, except for some components. Therefore, the following description will focus on different features.

Referring to FIGS. 18A to 18C, the semiconductor device includes a first recess RC1 and a third recess RC3, which have different shapes from each other. A lower surface of the third recess RC3 may be curved compared to the first recess RC1. Accordingly, a second source/drain pattern SD2 formed in the third recess RC3 may also have a shape different from that of a first source/drain pattern SD1 formed in the first recess RC1. The difference in the shapes of the first and second recesses RC1 and RC2 results from differences in the manufacturing method. The method of manufacturing the semiconductor device having the above-described structure is as follows.

First, as illustrated in FIGS. 3A, 3B, and 3C, a stack pattern STP may be formed on a substrate 100. To facilitate the formation of a channel pattern CH, the stack pattern STP may include alternating layers of different materials. In an embodiment, the stack pattern STP may include first semiconductor layers SM1 and second semiconductor layers SM2 alternately stacked with the first semiconductor layers SM1. In the present embodiment, the relatively thin uppermost semiconductor layer SMT is not provided on an uppermost first semiconductor layer SM1. A patterning process may be performed on the stack pattern STP and the substrate 100 to form a trench TR that defines an active area. The trench TR may be formed on both sides of the active pattern AP. A device isolation layer ST may fill the trench TR.

Then, as illustrated in FIGS. 4A, 4B, and 4C, a sacrificial pattern SF and a sub-sacrificial pattern SFL crossing the active pattern AP may be formed on the substrate 100. In detail, the sub-sacrificial pattern SFL may be formed on the uppermost first semiconductor layer SM1 of the stack pattern STP, and the sacrificial pattern SF may be formed on the sub-sacrificial pattern SFL. A gate spacer pattern SP may be formed on the sacrificial pattern SF. The gate spacer pattern SP may be conformally formed over the surface of the substrate 100.

Since a portion of the gate spacer pattern SP and a portion of the stack pattern STP on the active pattern AP are removed, the first recess RC1 may be formed at one side of the stack pattern STP. The first recess RC1 may correspond to an area in which the first source/drain pattern SD1 is to be formed. According to the embodiment, the first recess RC1 may be formed deeper than upper surfaces of the active pattern AP and/or the device isolation layer ST. A portion of the stack pattern STP exposed through the first recess RC1 may be selectively etched. For instance, the second semiconductor layers SM2 may be selectively etched without etching other components. Since the second semiconductor layers SM2 are selectively etched, side surfaces of the second semiconductor layers SM2 may include inwardly recessed portions relative to side surfaces of the first semiconductor layers SM1 in the horizontal direction. These recessed portions may be recessed inward by a first distance d1 from the side surfaces of the second semiconductor layers SM2 before etching or from the side surfaces of the first semiconductor layers SM1.

Then, as illustrated in FIGS. 5A, 5B, and 4C, a protective mask MSK may be formed in the first recess RC1. In an embodiment, the protective mask MSK may be formed only in the first recess RC1 and may not be formed in other areas. An upper surface of the protective mask MSK may be coplanar with an upper surface of the gate spacer pattern SP.

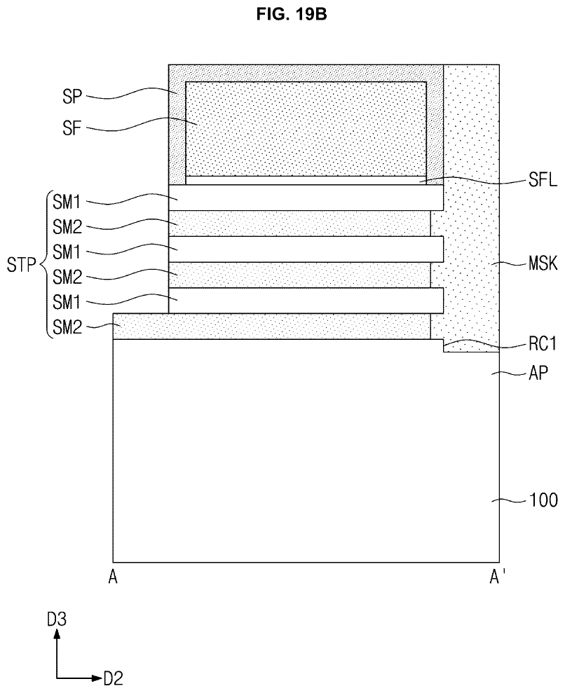

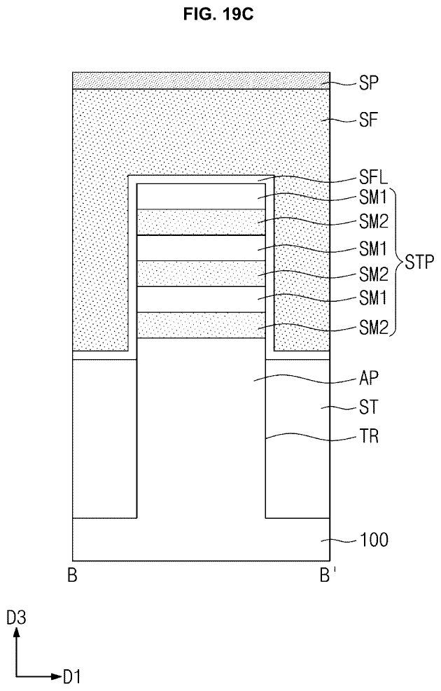

Referring to FIGS. 19A to 19C, the third recess RC3 may be formed by removing a portion of the gate spacer pattern SP and a portion of the stack pattern STP on the active pattern AP through a first etching process. One side of the stack pattern STP may be etched through the first etching process. For example, the gate spacer pattern SP, first semiconductor layers SM1, and second semiconductor layers SM2 may be etched through the first etching process except a lowermost second semiconductor layer SM2. The first etching process may correspond to an anisotropic etching in the vertical direction.

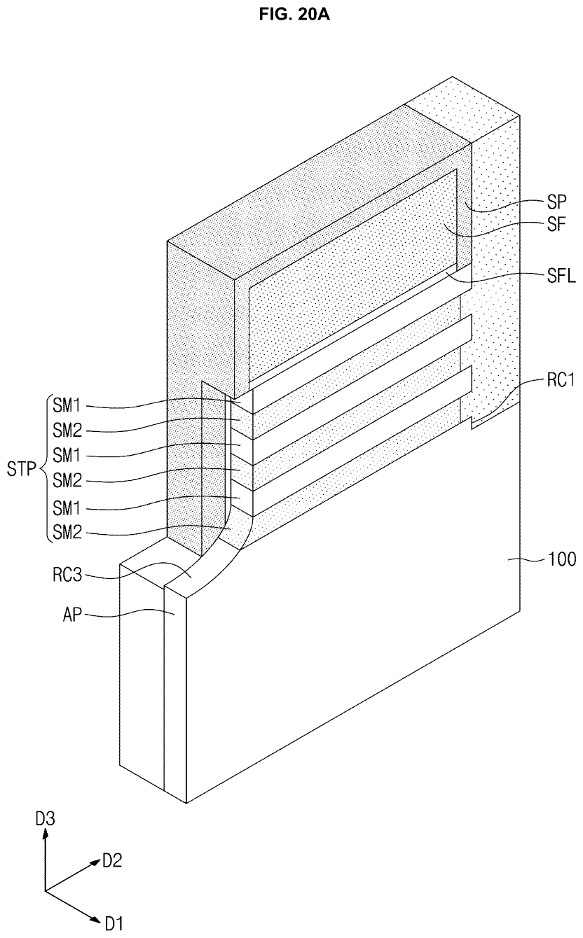

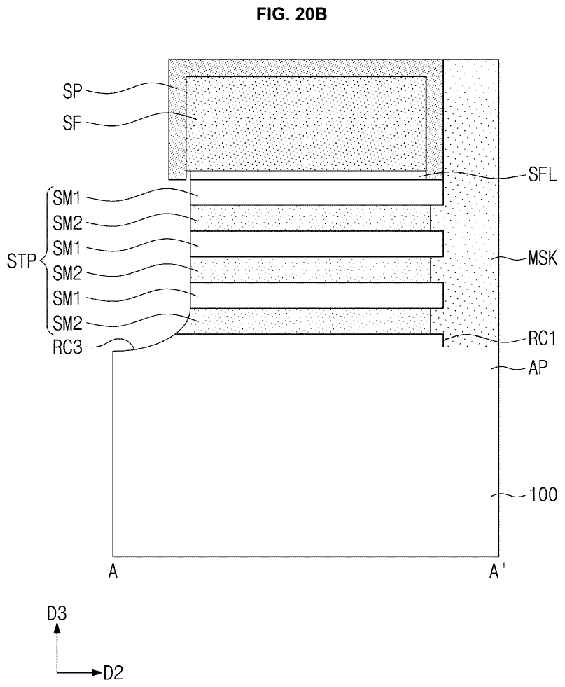

Referring to FIGS. 20A, 20B, and 19C, one sides of the first semiconductor layers SM1 and the second semiconductor layers SM2 a remaining after the first etching process may be removed through a second etching process, thereby forming the third recess RC3. The second etching process may be a process that isotropically etches a lowermost first semiconductor layer SM1 remaining at the other side and lower side of the stack pattern STP. As the second etching process proceeds, the substrate 100 beneath the lowermost first semiconductor layer SM1 may also be isotropically etched. The second etching process may be performed until a portion of a lower surface of the sub-sacrificial pattern SFL is exposed.

As a result, side surfaces of the substrate 100 and the stack pattern STP may have a curved shape in the third recess RC3 when viewed in the cross-section. Since the third recess RC3 is formed through a two-step etching process, the third recess RC3 may have a shape different from that of the first recess RC1.

The third recess RC3 may correspond to an area in which the second source/drain pattern SD2 is to be formed. In an embodiment, the second source/drain pattern SD2 may be used as a drain of the semiconductor device later.

A dopant implantation for forming a lightly doped drain (LDD) may additionally be performed on the surface of the substrate 100 where the third recess RC3 is formed.

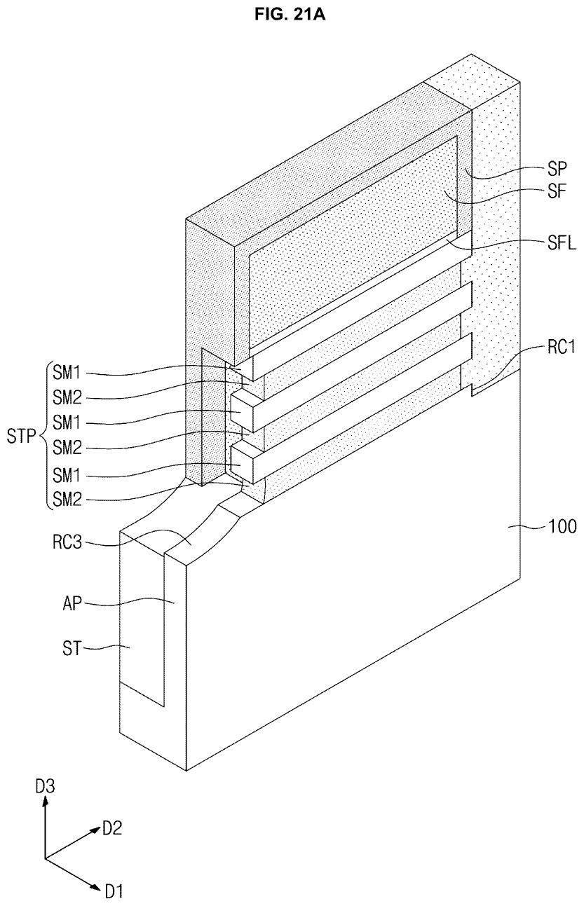

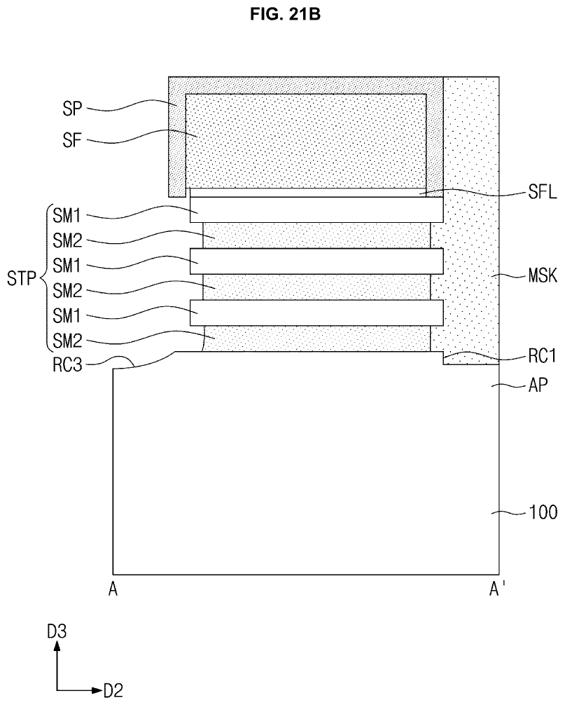

Referring to FIGS. 21A, 21B, and 19C, a portion of the stack pattern STP exposed through the third recess RC3 may be selectively etched. For example, the exposed side surfaces of the second semiconductor layers SM2 may be selectively etched. Since the second semiconductor layers SM2 are selectively etched, the second semiconductor layers SM2 may be recessed inward along the horizontal direction more than the side surfaces of the first semiconductor layers SM1.

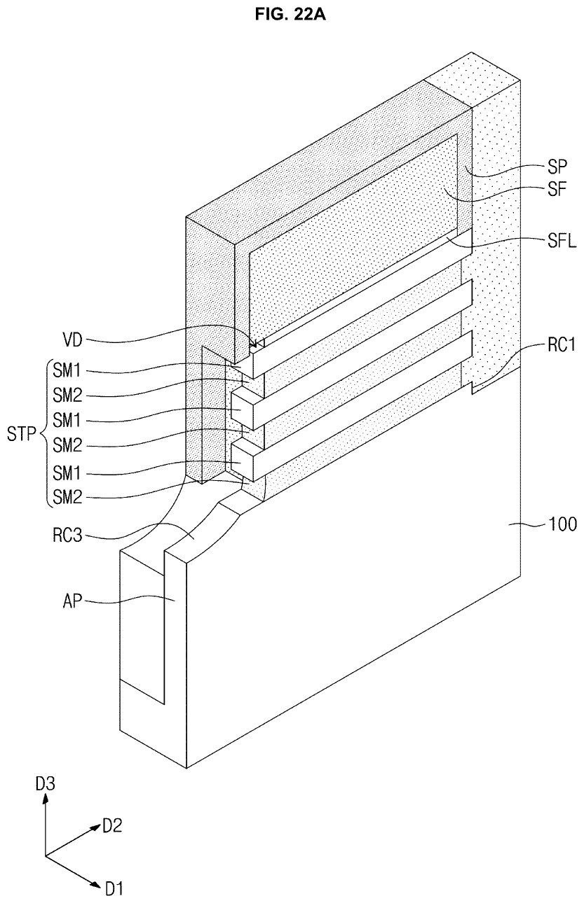

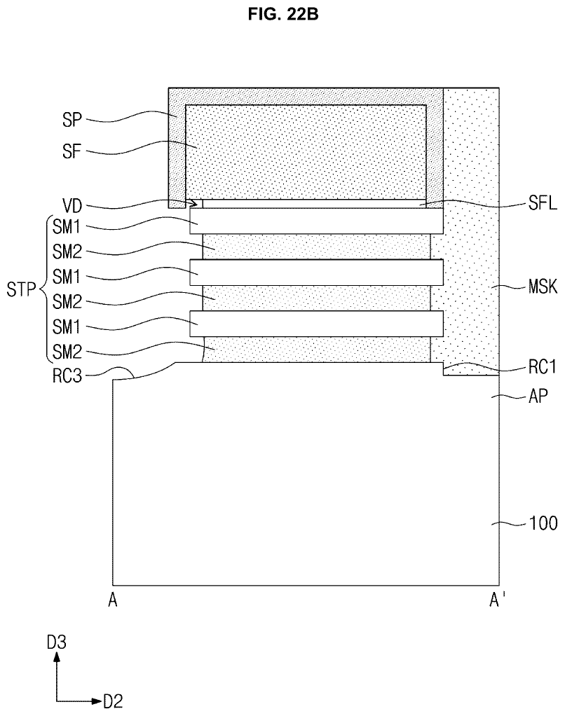

Referring to FIGS. 22A, 22B, and 19C, a portion of the exposed sub-sacrificial pattern SFL may be etched. The sub-sacrificial pattern SFL may be partially etched sequentially in an inward direction from its lower surface exposed to the outside. The etching of the sub-sacrificial pattern SFL may be performed until a portion of the lower surface of the sacrificial pattern SF is exposed. As a result, a void VD may be formed, which is surrounded by an inner side surface of the gate spacer pattern SP, the lower surface of the sacrificial pattern SF, a side surface of the sub-sacrificial pattern SFL, and an upper surface of the uppermost first semiconductor layer SM1.

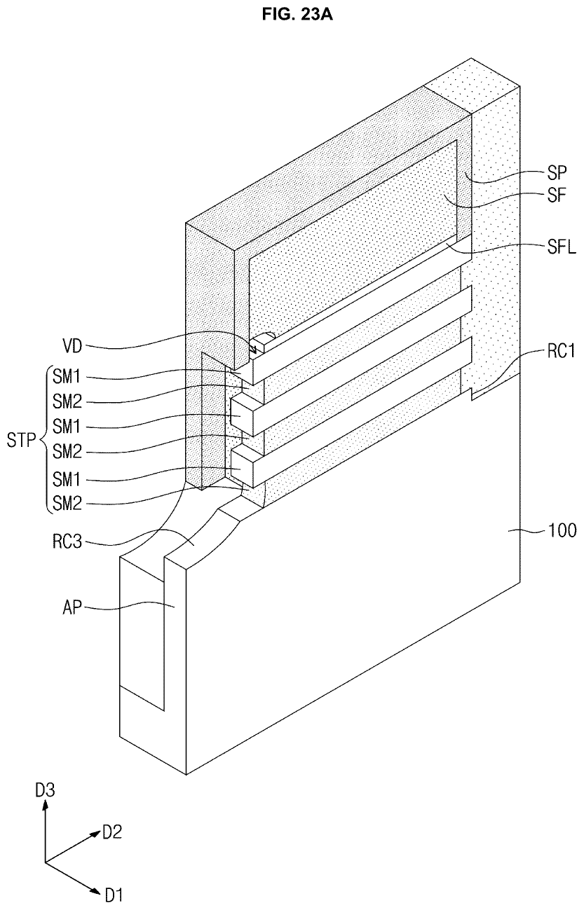

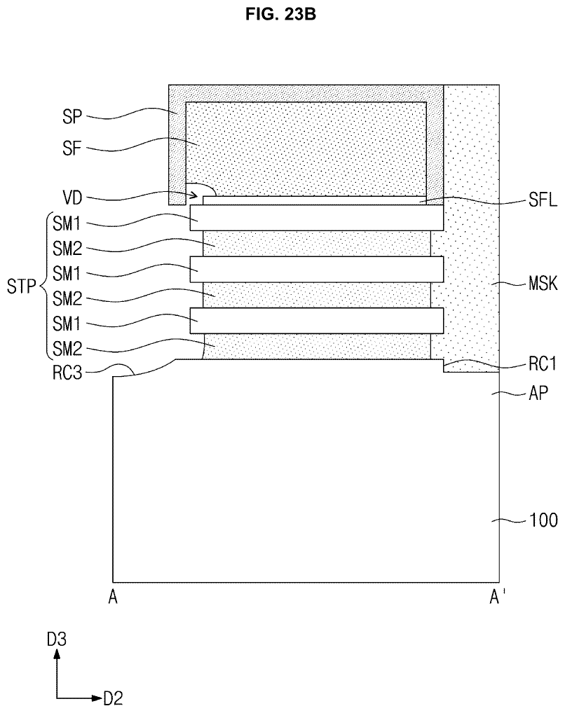

Referring to FIGS. 23A, 23B, and 19C, a portion of the exposed sacrificial pattern SF may be etched. The sacrificial pattern SF may be partially etched sequentially in the inward direction from its lower surface exposed to the outside. Due to the inward etching, the sacrificial pattern SF may also be recessed inward. Since the sacrificial pattern SF is partially etched, the void VD that becomes larger than that in the previous process may be formed. Accordingly, the void VD may be surrounded by the inner side surface of the gate spacer pattern SP, the side surface defining the recess formed in the sacrificial pattern SF, the side surface of the sub-sacrificial pattern SFL, and the upper surface of the uppermost first semiconductor layer SM1.

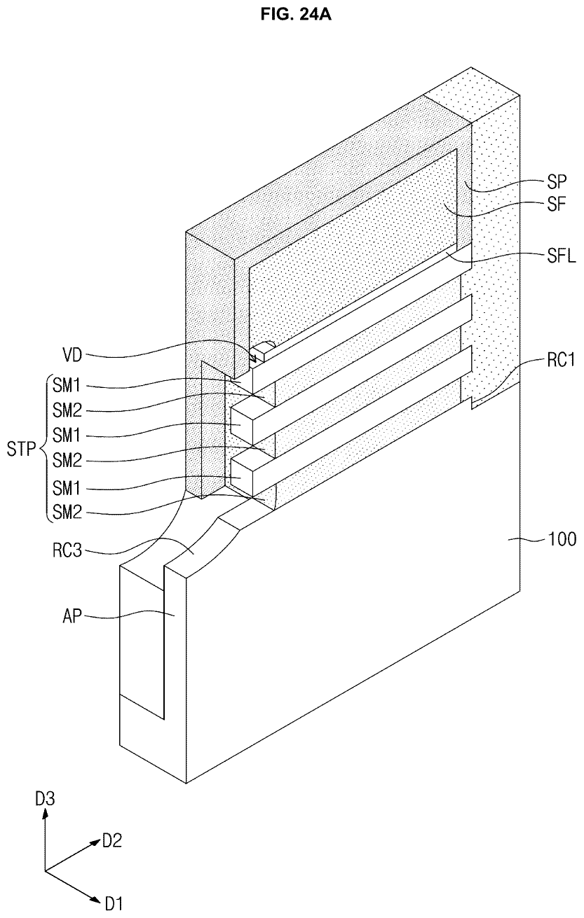

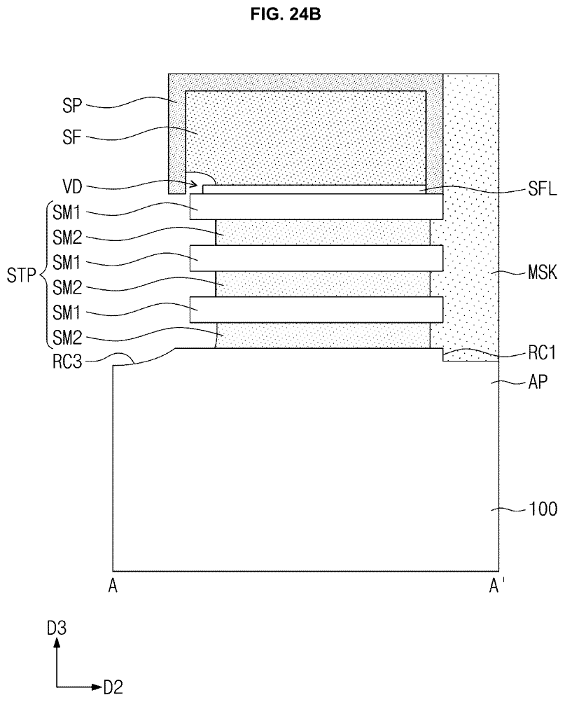

Referring to FIGS. 24A, 24B, and 19C, an additional etching process may be performed to etch the second semiconductor layers SM2. Since the second semiconductor layers SM2 are selectively etched, the side surfaces of the second semiconductor layers SM2 may be recessed further inward along the horizontal direction than the side surfaces of the sub-sacrificial pattern SFL.

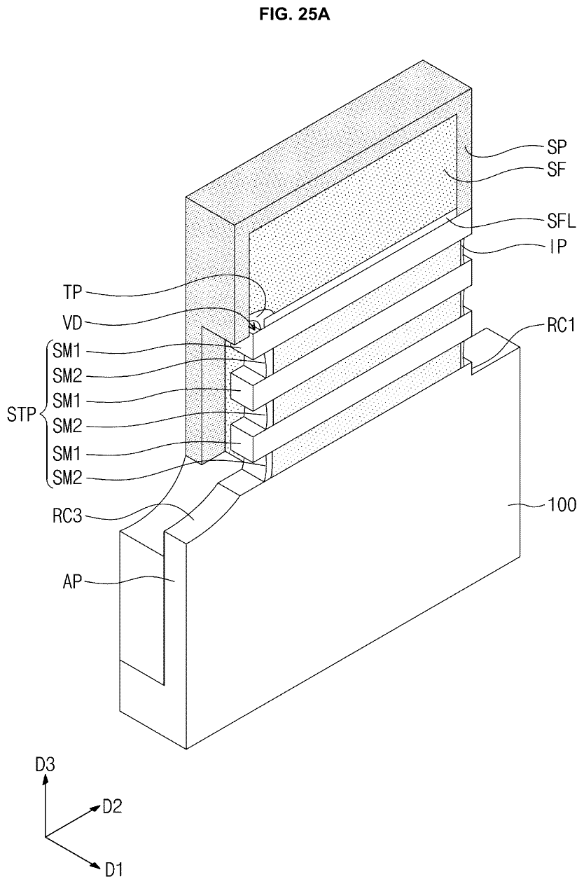

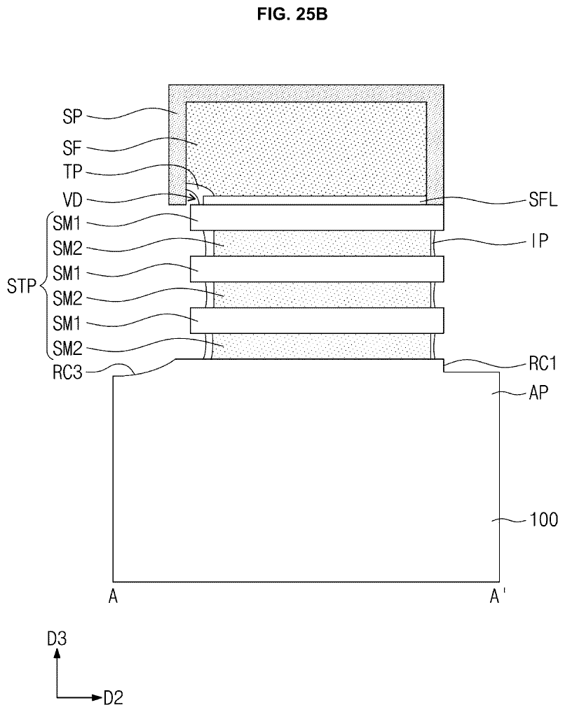

Referring to FIGS. 25A, 25B, and 19C, as the protective mask MSK formed in the first recess RC1 is removed, the side surface of the stack pattern STP, which corresponds to the first recess RC1, may be exposed to the outside.

An inner spacer IP and a sloped insulation pattern TP may be formed on the exposed side surfaces of the stack pattern STP. The inner spacer IP and the sloped insulation pattern TP may be formed by conformally forming an inner spacer insulating layer on the substrate 100 and anisotropically patterning a portion of the inner spacer insulating layer.

As a result, the inner spacer IP may be formed between the first semiconductor layers SM1 adjacent to the first recess RC1 and between the first semiconductor layers SM1 adjacent to the third recess RC3. In addition, the sloped insulation pattern TP may be formed in the void VD adjacent to the third recess RC3.

When the inner spacer insulating layer is patterned, the side surfaces of the sloped insulation pattern TP and the inner spacer IP, which are exposed to the outside, may be recessed inward more than the side surfaces of the first semiconductor layers SM1. In the present embodiment, since the second semiconductor layers SM2 have the side surfaces that are asymmetrically recessed with respect to both sides of the first semiconductor layers SM1, the finally formed inner spacer IP may also have an asymmetric shape. For instance, the inner spacer IP adjacent to the third recess RC3 may have a width greater than a width of the inner spacer IP adjacent to the first recess RC1.

Then, the semiconductor device may be formed by performing the processes illustrated in FIGS. 12A to 18C in substantially the same manner.

According to one or more embodiments, each component of the semiconductor device may be manufactured using different materials, and thus, semiconductor devices having different structures may be manufactured. For example, the method of manufacturing the semiconductor device according to one or more embodiments may include forming the gate spacer pattern SP, the sloped insulation pattern TP, and the inner spacer IP using the same material.

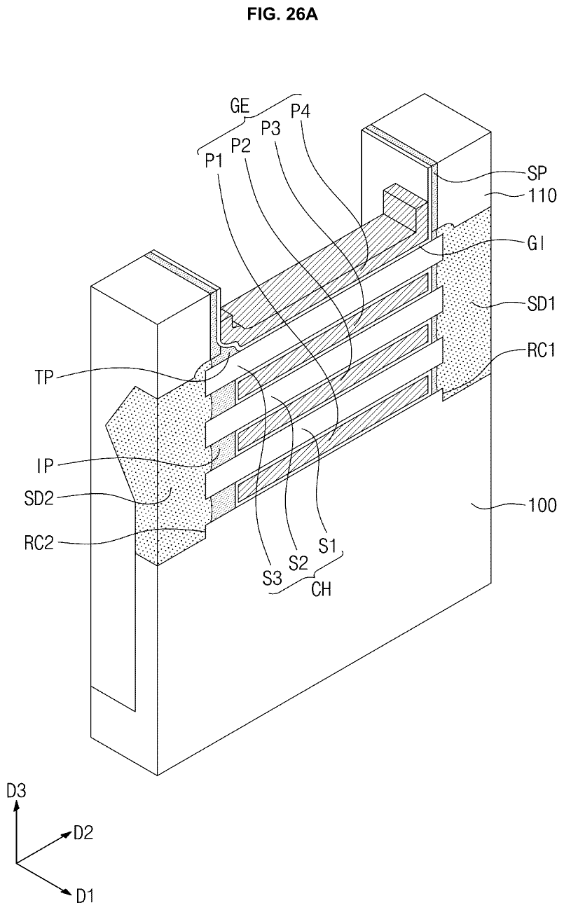

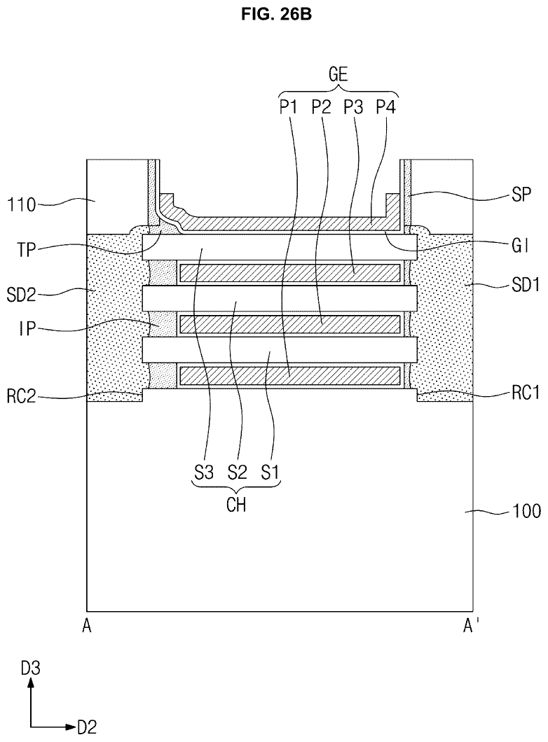

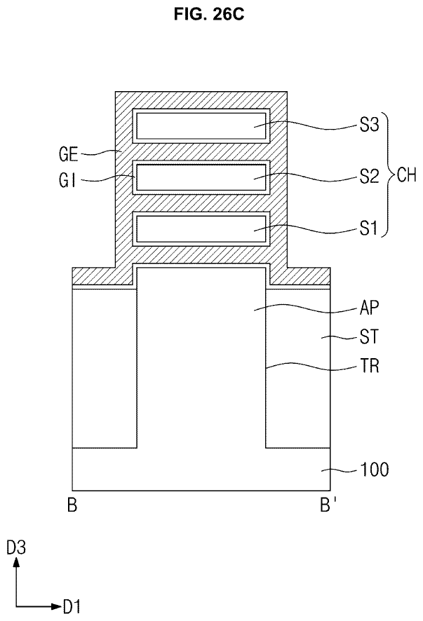

FIGS. 26A to 26C are views illustrating a semiconductor device according to one or more embodiments, FIG. 26A is a cross-sectional perspective view taken along the line A-A′ of FIG. 1B, FIG. 26B is a cross-sectional view taken along the line A-A′ of FIG. 1B, and FIG. 26C is a cross-sectional view taken along the line B-B′ of FIG. 1B.

The semiconductor device according to the present embodiments is substantially the same as the semiconductor device illustrated in FIGS. 2A to 2D, except for some components. Therefore, the following description will focus on different features.

Referring to FIGS. 26A to 26C, a gate spacer pattern SP may include the same material as a sloped insulation pattern TP. Although a boundary between the gate spacer pattern SP and the sloped insulation pattern TP is illustrated in FIGS. 26A to 26C, the gate spacer pattern SP and the sloped insulation pattern TP may be integrally formed with each other and may not have a boundary, an interface or a junction therebetween. In addition, the gate spacer pattern SP may include the same material as an inner spacer IP.

In an embodiment, the gate spacer pattern SP, the sloped insulation pattern TP, and the inner spacer IP may include at least one of SiCN, SiCON, and SiN. In an embodiment, the gate spacer pattern SP, the sloped insulation pattern TP, and the inner spacer IP may include silicon nitride (SiN).

The semiconductor device illustrated in FIGS. 26A to 26C may be manufactured using substantially the same manufacturing method as the manufacturing method disclosed in FIGS. 3A to 18C. However, the gate spacer pattern SP in FIGS. 4A to 4C may be formed of at least one of SiCN, SiCON, and SiN, for example, SiN. In addition, the inner spacer IP and the sloped insulation pattern TP in FIGS. 11A and 11B may also be formed of at least one of SiCN, SiCON, and SiN, for example, SiN. Further, in the aforementioned embodiment of FIGS. 14A and 14B, only the sloped insulation pattern TP may be etched without etching the gate spacer pattern SP, however, according to the present embodiment, the sloped insulation pattern TP and the gate spacer pattern SP may be etched simultaneously.

As describe above, since the gate spacer pattern SP includes the same material as the sloped insulation pattern TP, the gate spacer pattern SP may also be partially etched during the etching of the sloped insulation pattern TP in the manufacturing process of the semiconductor device, and thus, the gate spacer pattern SP may have a relatively thinner thickness than the gate spacer pattern SP of the above-described embodiments.

In one or more embodiments, the process sequence of the manufacturing of the semiconductor device may be modified in various ways. For example, the forming of the first and second recesses RC2 may be carried out differently from the above-described embodiments.

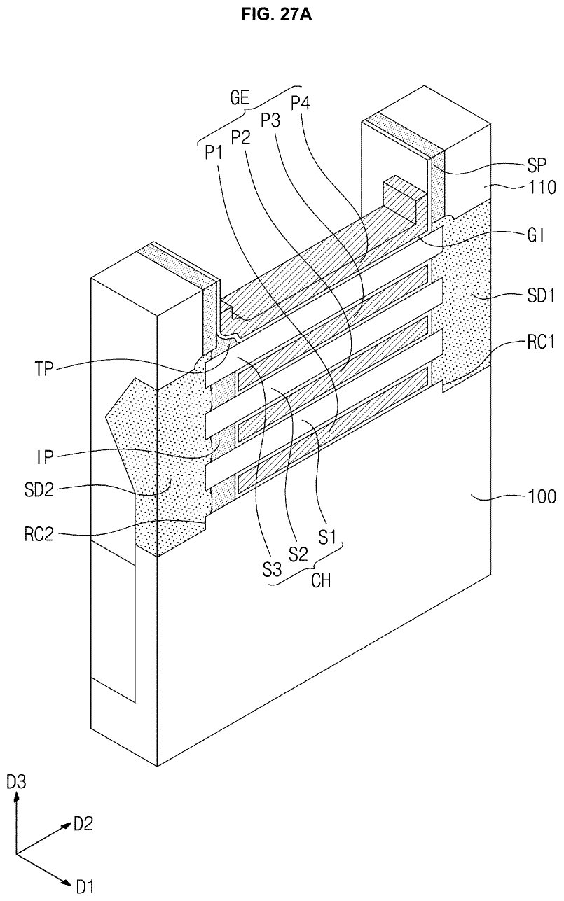

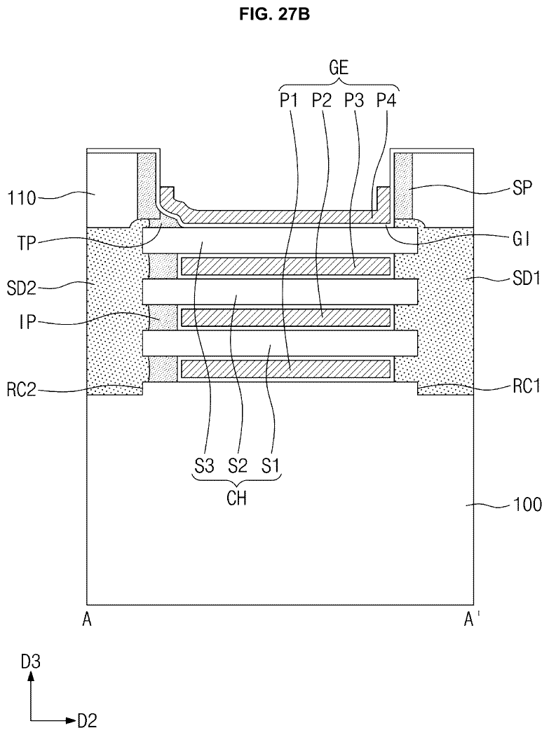

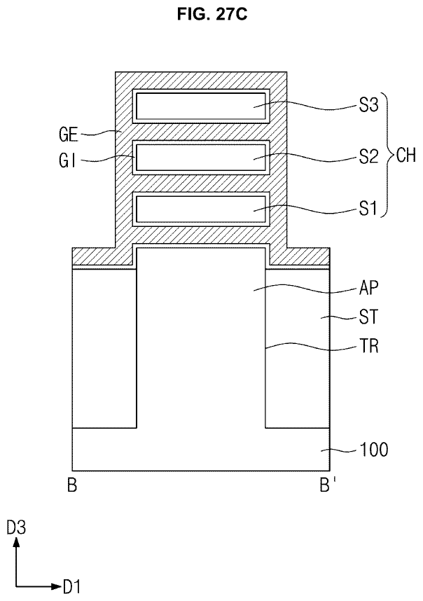

FIGS. 27A to 27C are views illustrating a semiconductor device according to one or more embodiments manufactured in a different order from the embodiments described above, FIG. 27A is a cross-sectional perspective view taken along the line A-A′ of FIG. 1B, FIG. 27B is a cross-sectional view taken along the line A-A′ of FIG. 1B, and FIG. 27C is a cross-sectional view taken along the line B-B′ of FIG. 1B.

The semiconductor device according to the present embodiments is substantially the same as the semiconductor device illustrated in FIGS. 2A to 2D, except for some components. Therefore, the following description will focus on different features.

Referring to FIGS. 27A to 27C, unlike in the above-described embodiments, an inner spacer IP is not provided in an area adjacent to a first source/drain pattern SD1. That is, according to the previous embodiments, the inner spacers IP may be provided between the first source/drain pattern SD1 and a gate electrode GE and between a second source/drain pattern SD2 and the gate electrode GE. However, according to the present embodiment, the inner spacers IP may be provided only between first, second, and third portions P1, P2, and P3 of the gate electrode GE and the second source/drain pattern SD2. The inner spacers IP may be in direct contact with the second source/drain pattern SD2. Each of the first, second, and third portions P1, P2, and P3 of the gate electrode GE may be spaced apart from each of the first and second source/drain patterns SD1 and SD2 by the inner spacer IP. The inner spacers IP may include one of SiOx, SiN, SiCN, SiON, or SiOCN, and, for example, the inner spacers IP may include SiN.

The difference in the inner spacers IP of the semiconductor device is due to the difference in the manufacturing method, and the manufacturing method of the semiconductor device having the above-described structure is as follows.

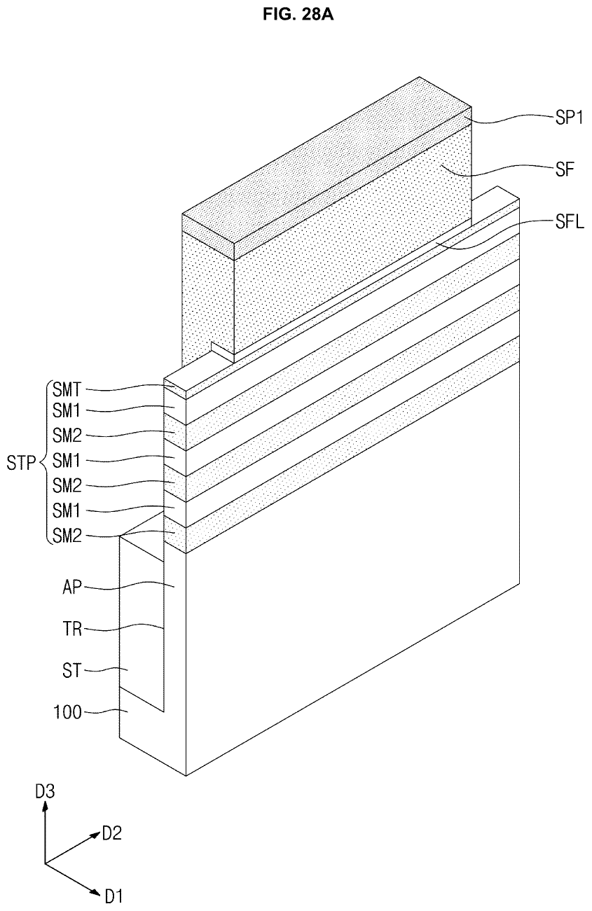

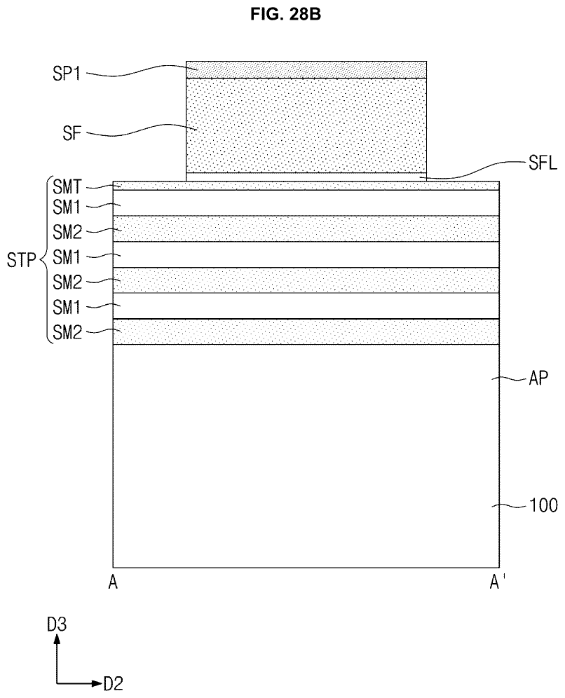

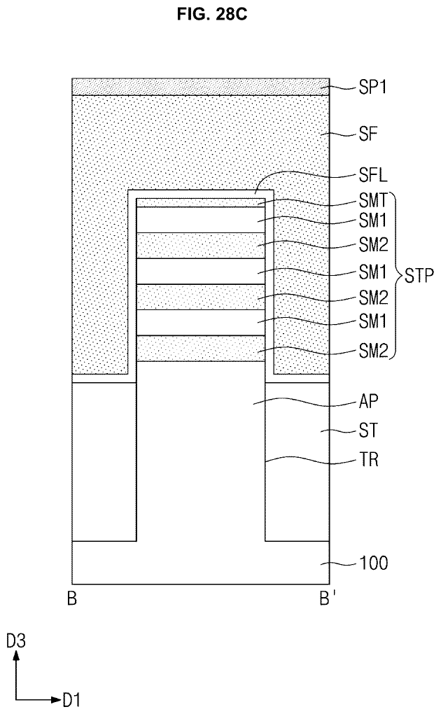

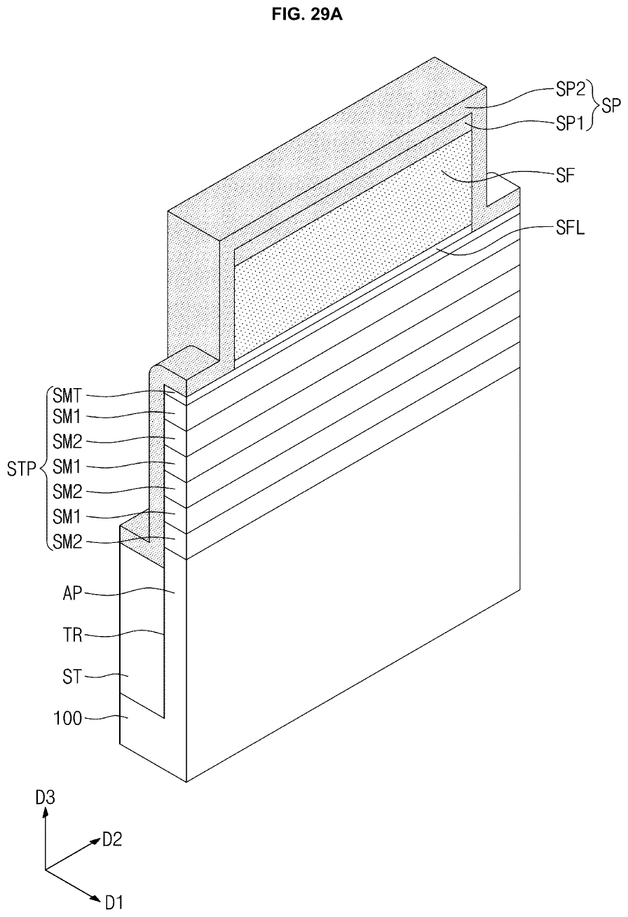

Referring to FIGS. 28A, 28B, and 28C, a stack pattern STP may be formed on a substrate 100. The stack pattern STP may include layers of different materials stacked alternately to facilitate the formation of a channel pattern CH. In an embodiment, the stack pattern STP may include first semiconductor layers SM1, second semiconductor layers SM2 alternately stacked with the first semiconductor layers SM1, and an uppermost semiconductor layer SMT disposed on the alternately stacked first and second semiconductor layers SM1 and SM2. The uppermost semiconductor layer SMT may have the same composition as the second semiconductor layers SM2 and may have a thickness smaller than the second semiconductor layers SM2.

A patterning process may be performed on the stack pattern STP and the substrate 100 to form a trench TR that defines an active area. The trench TR may be formed at opposite sides of an active pattern AP. The active pattern AP may have a bar shape extending in a direction parallel to the second direction D2. A device isolation layer ST may fill the trench TR.

A sacrificial pattern SF and a sub-sacrificial pattern SFL crossing the active pattern AP may be formed on the substrate 100. In detail, the sub-sacrificial pattern SFL may be formed on the uppermost semiconductor layer SMT of the stack pattern STP, and the sacrificial pattern SF may be formed on the sub-sacrificial pattern SFL.

The formation of the sub-sacrificial pattern SFL and the sacrificial pattern SF may include sequentially forming a sub-sacrificial layer and a sacrificial layer on the surface of the substrate 100, forming a mask pattern SP1 on the sacrificial layer, and simultaneously or sequentially patterning a portion of the sacrificial layer and a portion of the sub-sacrificial layer using the mask pattern SP1 as an etch mask. The mask pattern SP1 may include at least One of SiCN, SiCON, and SiN.

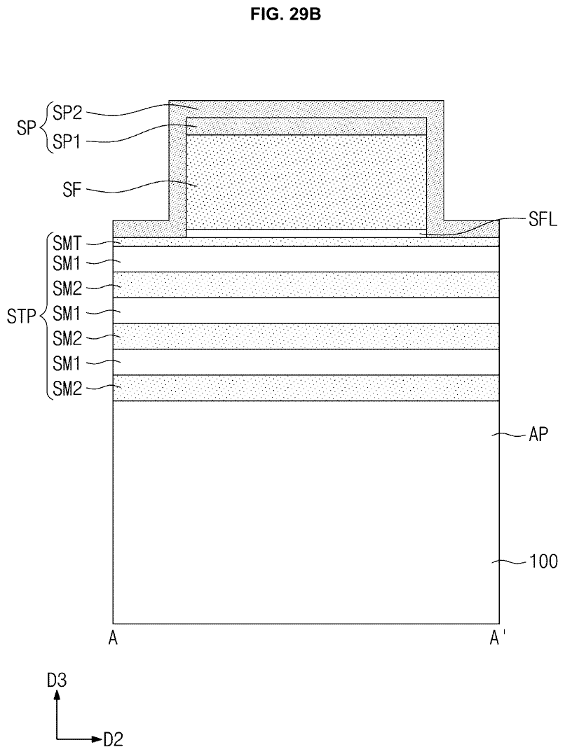

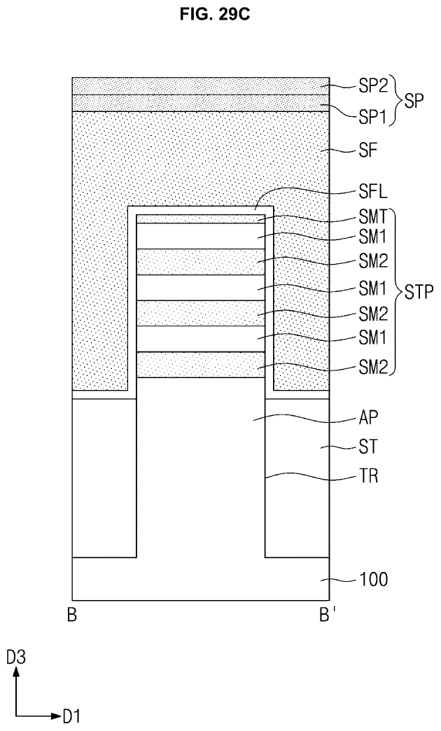

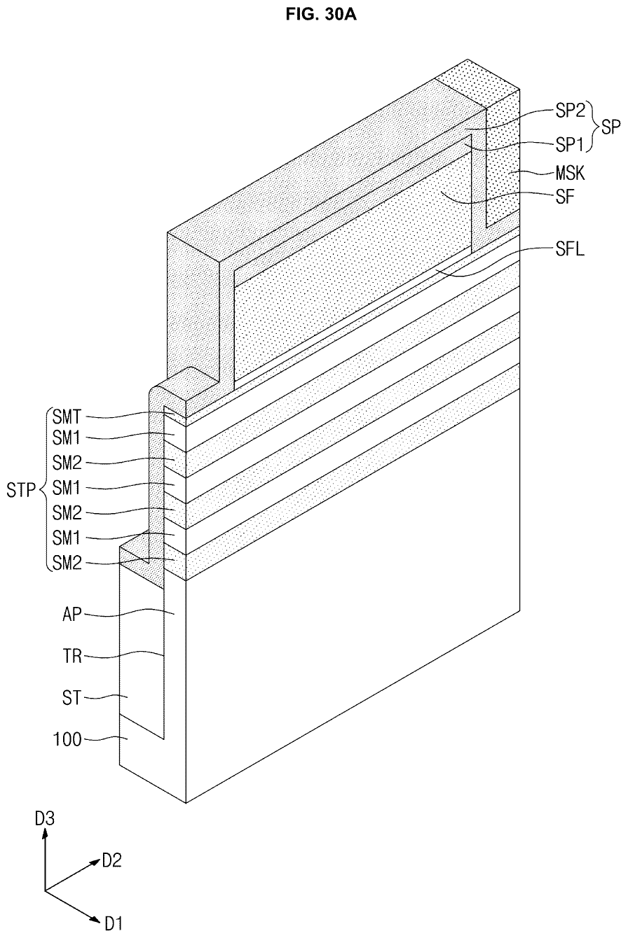

Referring to FIGS. 29A, 29B, and 29C, a gate spacer pattern SP2 may be formed on the sacrificial pattern SF. The gate spacer pattern SP2 may be conformally formed on the surface of the substrate 100. The gate spacer pattern SP2 may include at least one of SiCN, SiCON, and SiN. As another example, the gate spacer pattern SP2 may have a multi-layer structure of at least two of SiCN, SiCON, and SiN. In an embodiment, the mask pattern SP1 and the gate spacer pattern SP2 may include substantially the same material, and in this case, the mask pattern SP1 and the gate spacer pattern SP2 may be integrally formed without being separated from each other.

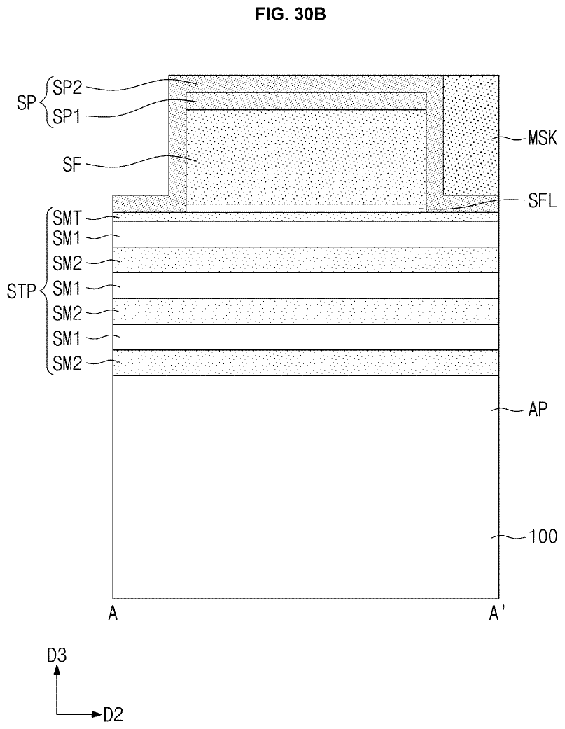

Referring to FIGS. 30A, 30B, and 29C, a protective mask MSK may be formed at one side of the sacrificial pattern SF. The area in which the protective mask MSK is formed may correspond to an upper portion of an area where the first source/drain pattern SD1 is to be formed.

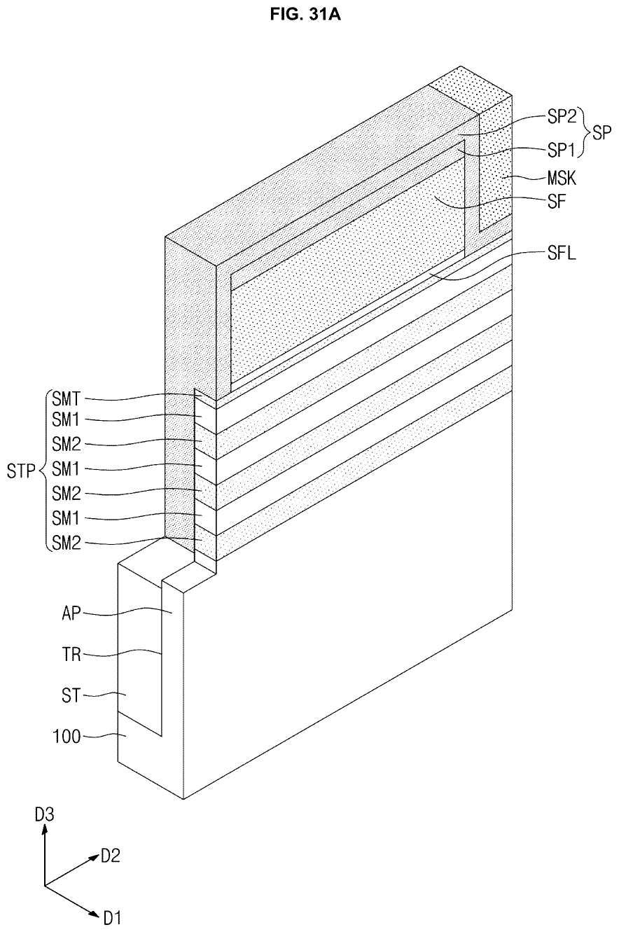

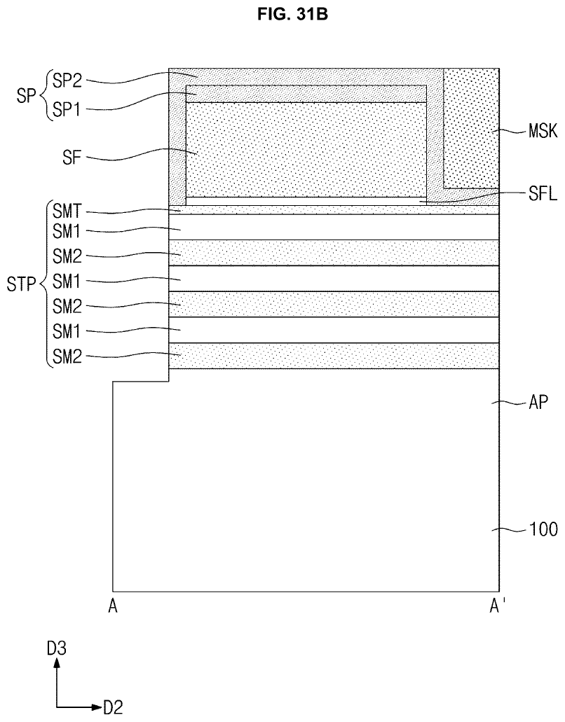

Referring to FIGS. 31A, 31B, and 29C, since a portion of the gate spacer pattern SP and a portion of the stack pattern STP are removed, a second recess RC2 may be formed at the other side of the stack pattern STP.

The second recess RC2 may correspond to an area in which the second source/drain pattern SD2 is to be formed. In an embodiment, the second source/drain pattern SD2 may later be used as the drain of the semiconductor device. In an embodiment, a side surface of the stack pattern STP exposed through the second recess RC2 may be substantially coplanar with a side surface of the gate spacer pattern SP, and the second recess RC2 may be recessed downward with respect to upper surfaces of the active pattern AP and the device isolation layer ST.

In the previous embodiments, a first recess RC1 is first formed at one side of the stack pattern STP, and then the second recess RC2 is formed at the other side of the stack pattern STP. However, the present embodiment is different in that the second recess RC2 is formed first.

A dopant implantation for forming a lightly doped drain (LDD) may be additionally performed on the surface of the substrate 100 in which the second recess RC2 is formed.

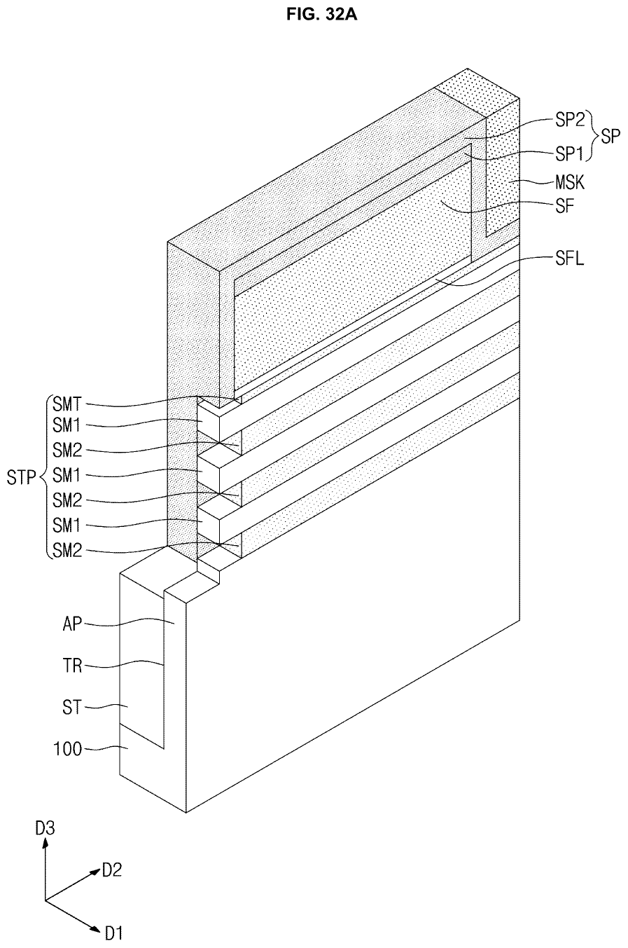

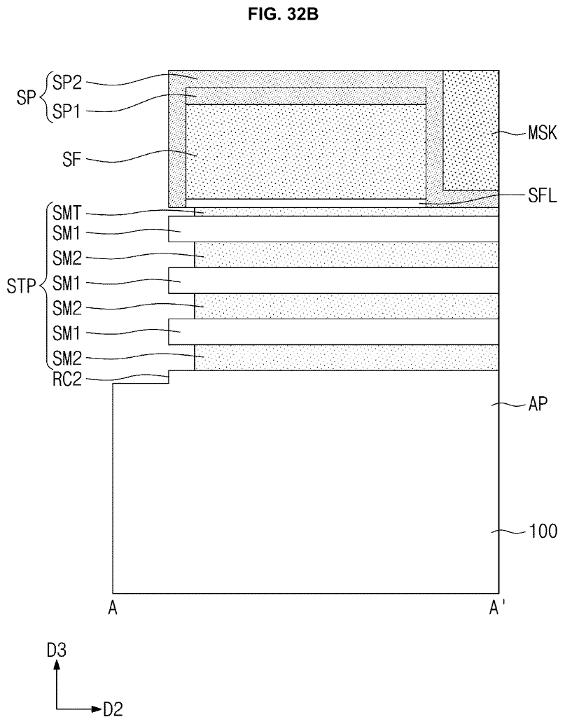

Referring to FIGS. 32A, 32B, and 29C, a portion of the stack pattern STP exposed through the second recess RC2 may be selectively etched. For example, the exposed side surfaces of the uppermost semiconductor layer SMT and the second semiconductor layers SM2 may be selectively etched.

Since the uppermost semiconductor layer SMT and the second semiconductor layers SM2 are selectively etched, the side surfaces of the uppermost semiconductor layer SMT and the second semiconductor layers SM2 may be recessed inward along the horizontal direction more than side surfaces of the first semiconductor layers SM1. In this case, a degree of the recess may be controlled by varying etching conditions for the uppermost semiconductor layer SMT and the second semiconductor layers SM2. In an embodiment, the uppermost semiconductor layer SMT may be etched until a portion of the lower surface of the sub-sacrificial pattern SFL is exposed.

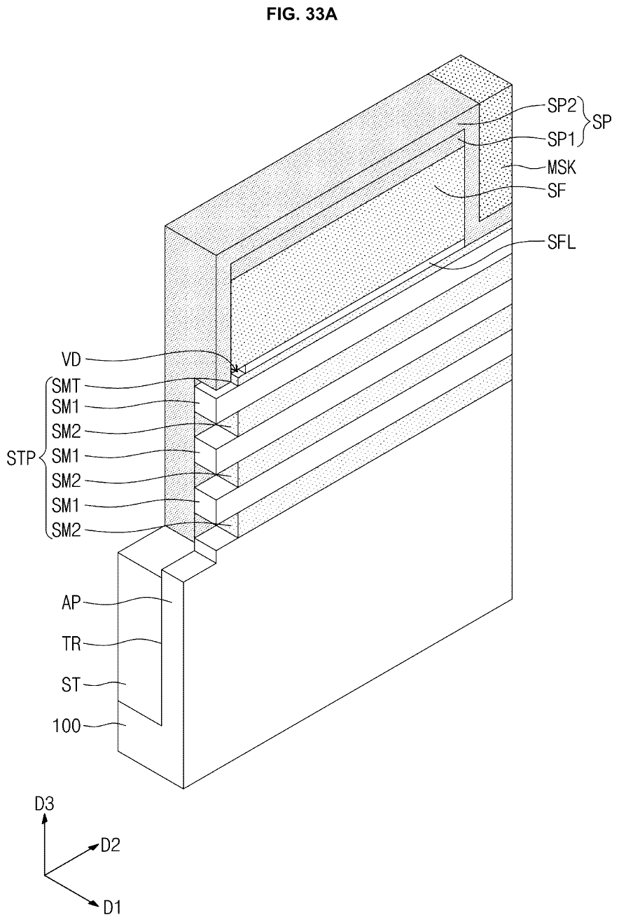

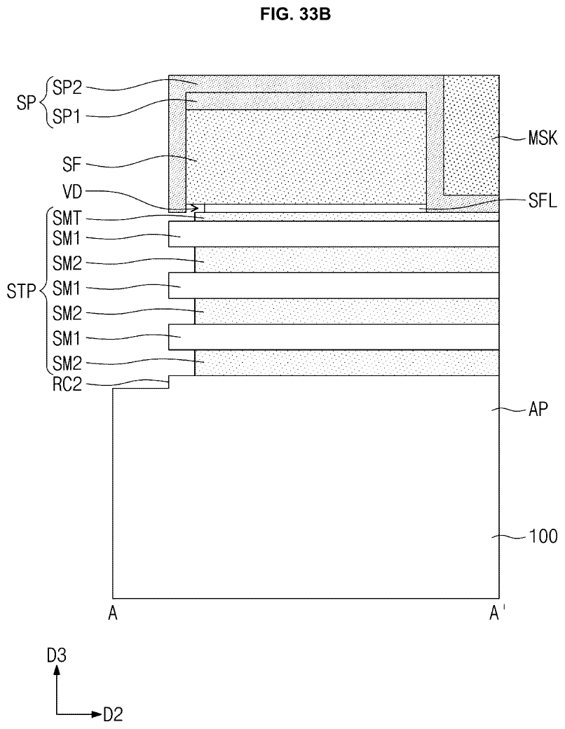

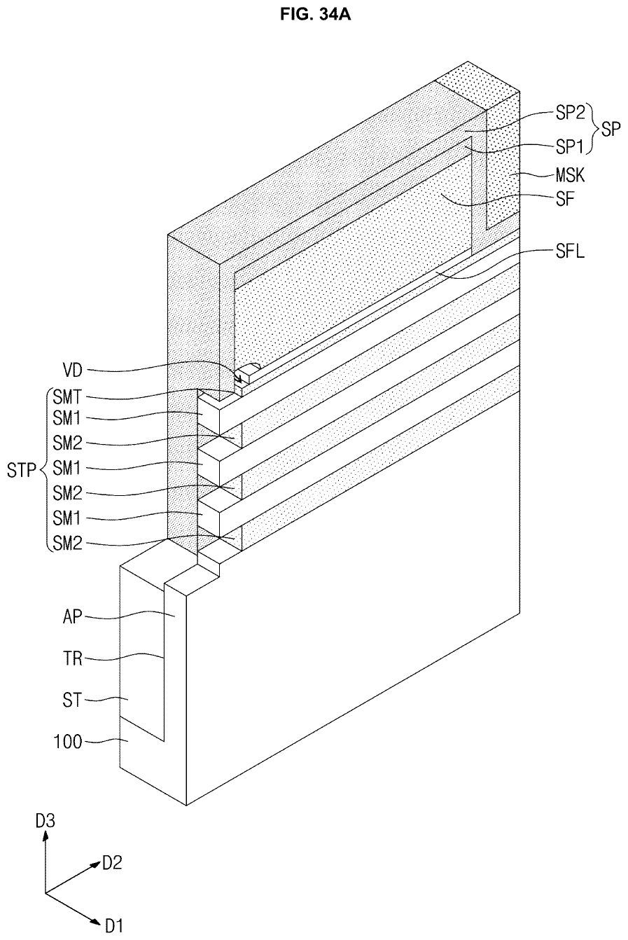

Referring to FIGS. 33A, 33B, and 29C, a portion of the exposed sub-sacrificial pattern SFL may be etched. The sub-sacrificial pattern SFL may be partially etched sequentially in an inward direction from its lower surface exposed to the outside, and the etching of the sub-sacrificial pattern SFL may be performed until a portion of the lower surface of the sacrificial pattern SF is exposed. As a result, a void VD may be formed, which is surrounded by an inner side surface of the gate spacer pattern SP, the lower surface of the sacrificial pattern SF, a side surface of the sub-sacrificial pattern SFL, and an upper surface of the uppermost semiconductor layer SMT.

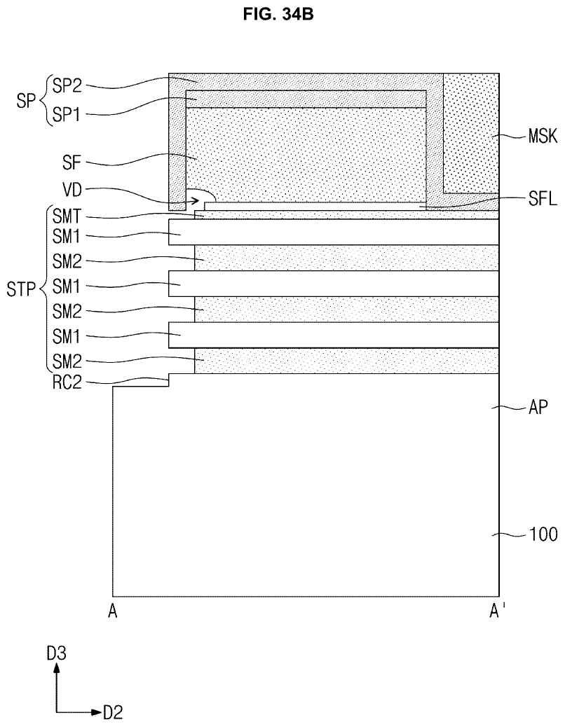

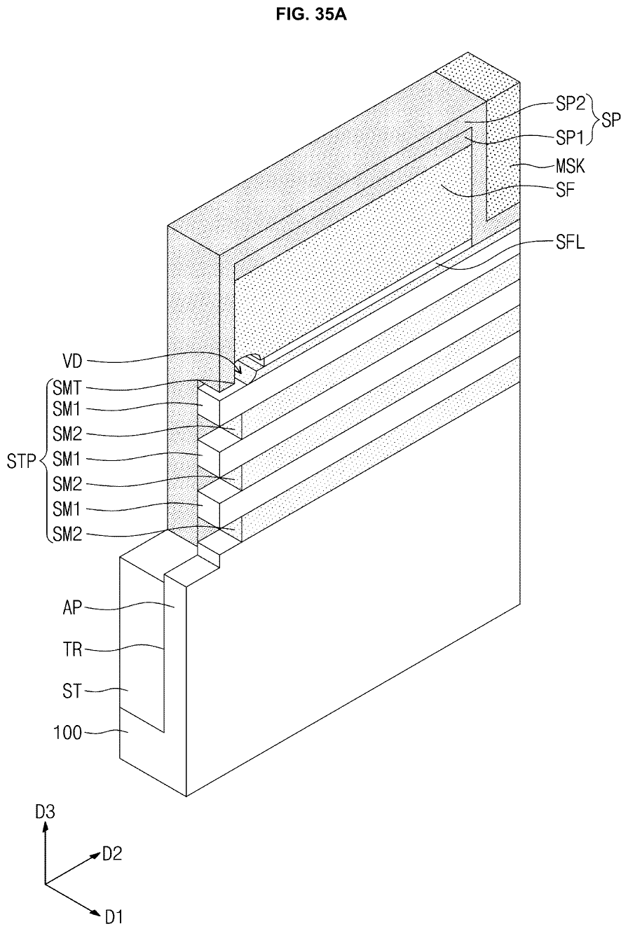

Referring to FIGS. 34A, 34B, and 29C, a portion of the exposed sacrificial pattern SF may be etched. The sacrificial pattern SF may include a material, for example, polysilicon, having etch selectivity with respect to materials constituting the sub-sacrificial pattern SFL and the stack pattern STP.

The sacrificial pattern SF may be partially etched sequentially in the inward direction from its lower surface exposed to the outside. Through the inward etching, the sacrificial pattern SF may also be recessed inward. As the sacrificial pattern SF is partially etched, the void VD that becomes larger than that in the previous process may be formed.

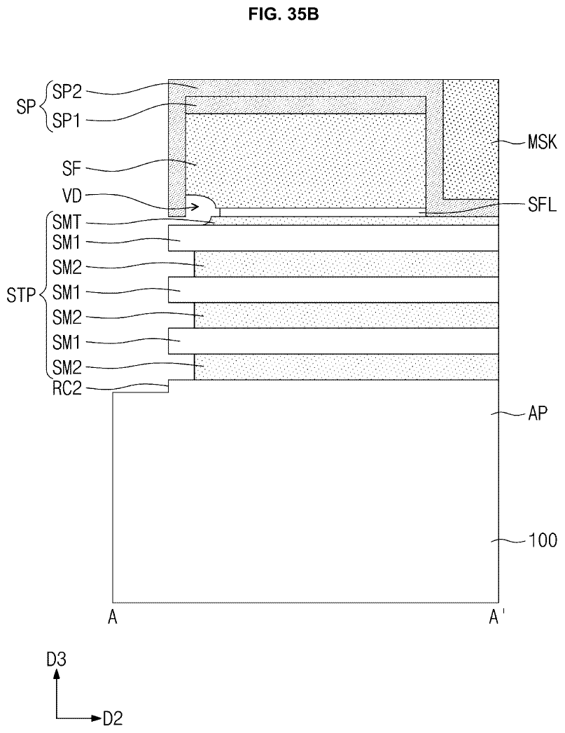

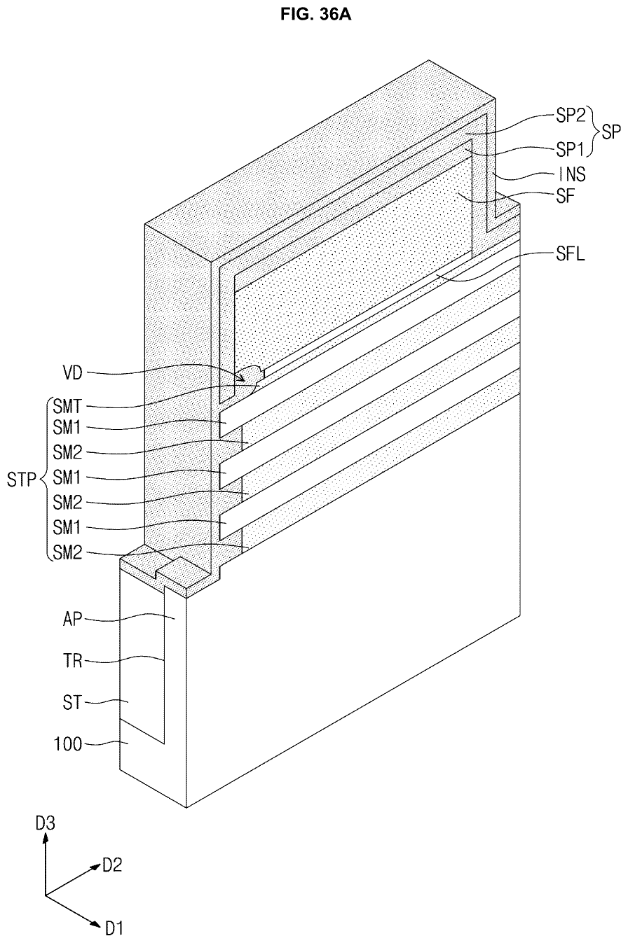

Referring to FIGS. 35A, 35B, and 29C, an additional etching process may be performed to expand the void VD. The additional etching process may be to etch the uppermost semiconductor layer SMT and the second semiconductor layers SM2.

As the uppermost semiconductor layer SMT and the second semiconductor layers SM2 are selectively etched, the side surfaces of the uppermost semiconductor layer SMT and the second semiconductor layers SM2 may be recessed inward along the horizontal direction more than the side surface of the sub-sacrificial pattern SFL.

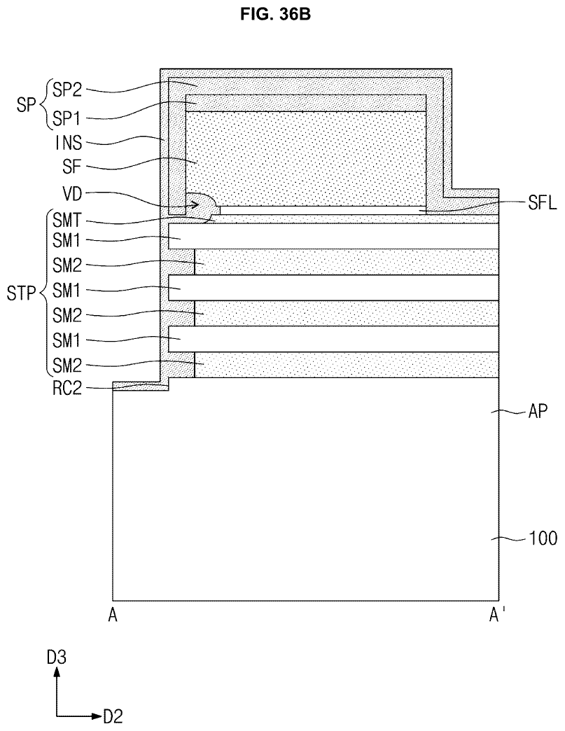

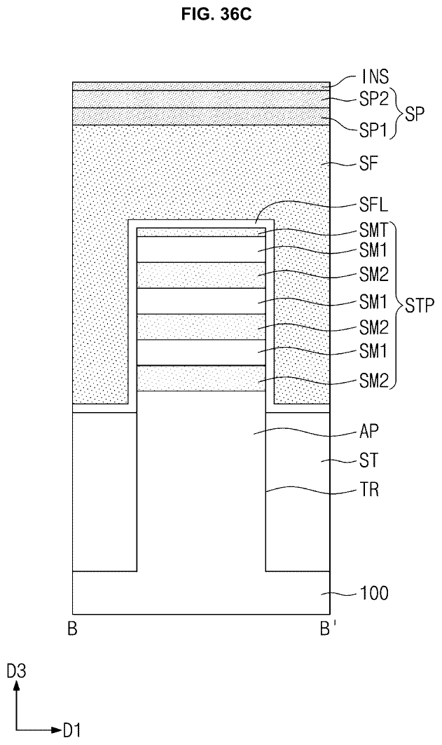

Referring to FIGS. 36A, 36B, and 36C, the protective mask MSK formed at one side of the sacrificial pattern SF may be removed, and an insulating layer INS may be conformally formed on the substrate 100. The insulating layer INS may fill the void VD and the recess formed in the second semiconductor layers SM2 in the horizontal direction, while simultaneously covering the surface of the substrate 100.

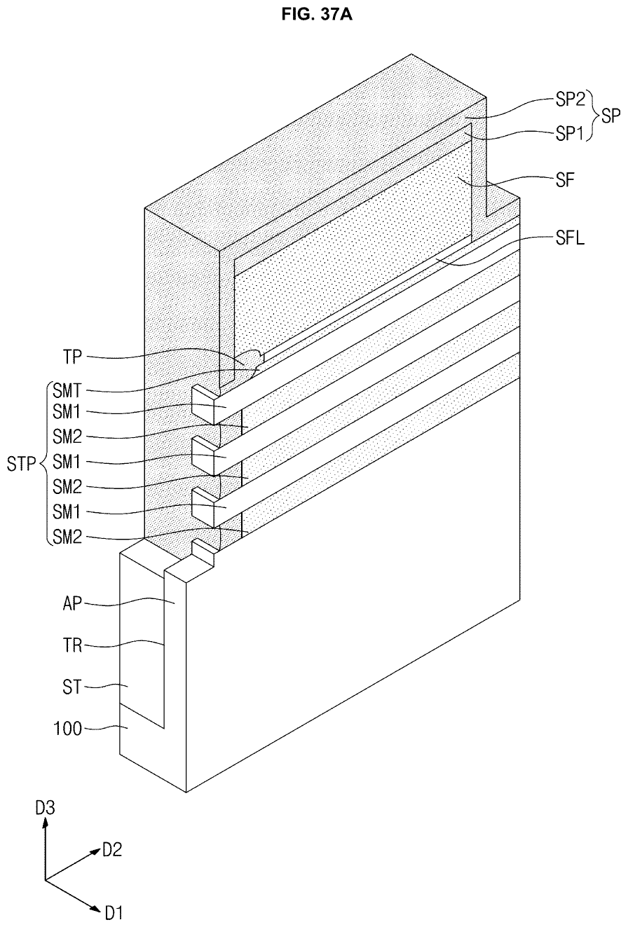

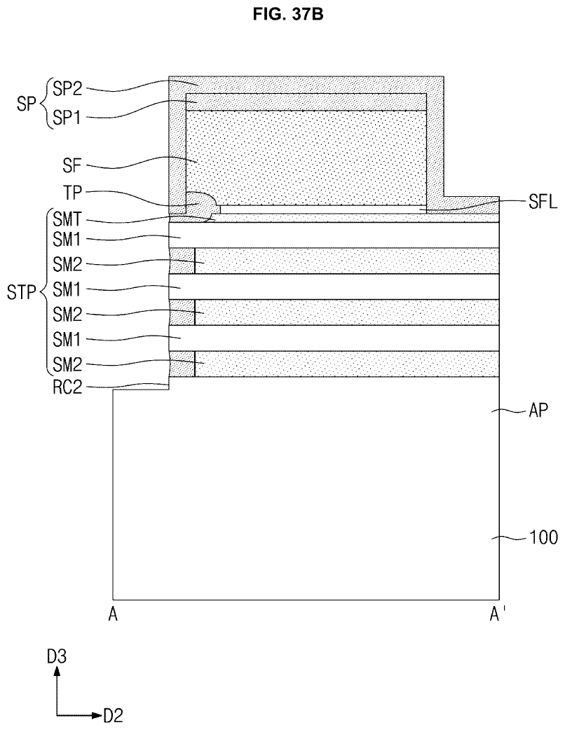

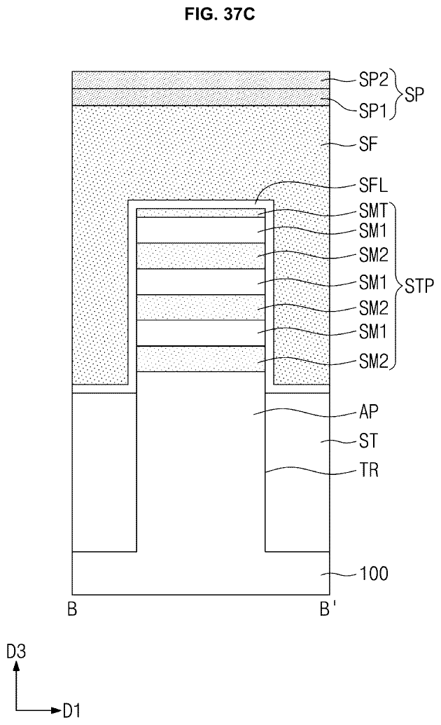

Referring to FIGS. 37A, 37B, and 37C, the insulating layer INS formed on the surface of the substrate 100 may be anisotropically patterned, and thus, portions of the insulating layer INS may be removed except for portions filling the void VD and the recesses. The portion of the insulating layer INS, which is filled in the void VD, may form a sloped insulation pattern TP, and the portion of the insulating layer INS, which is filled in the recesses may form the inner spacer IP.

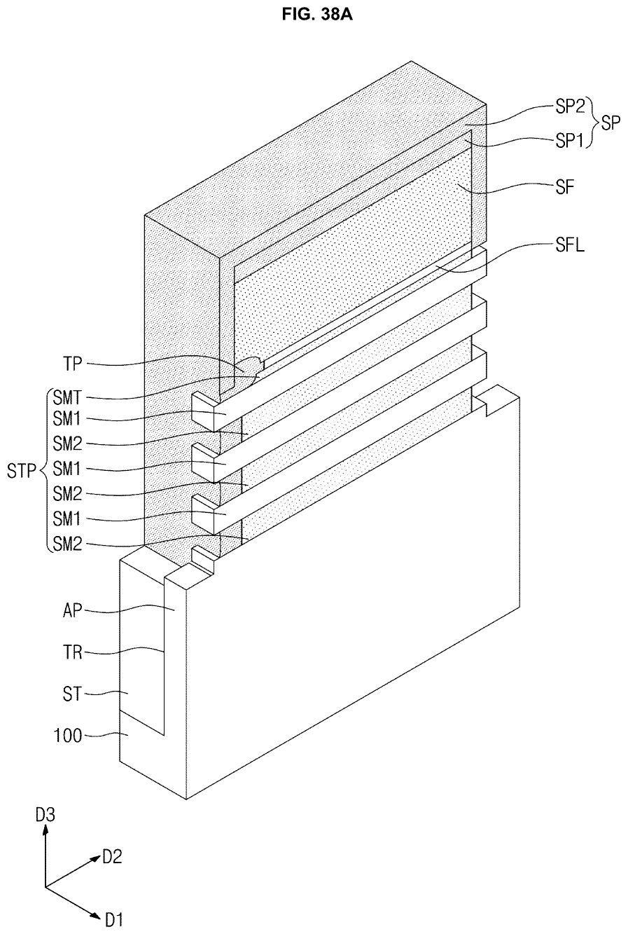

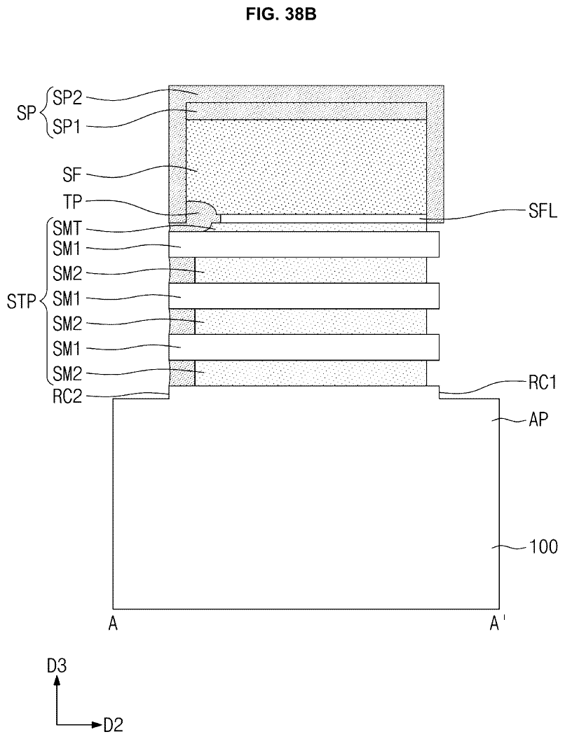

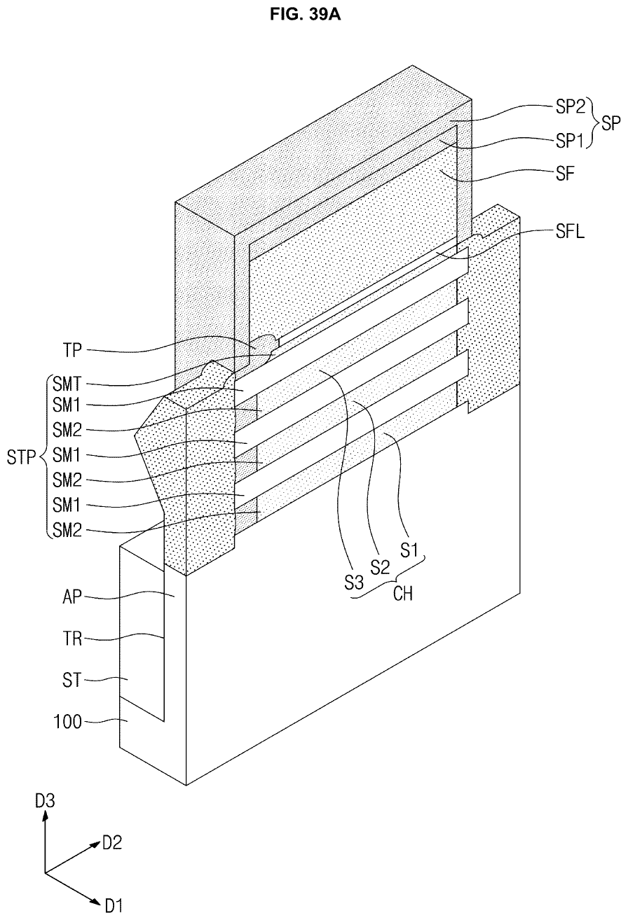

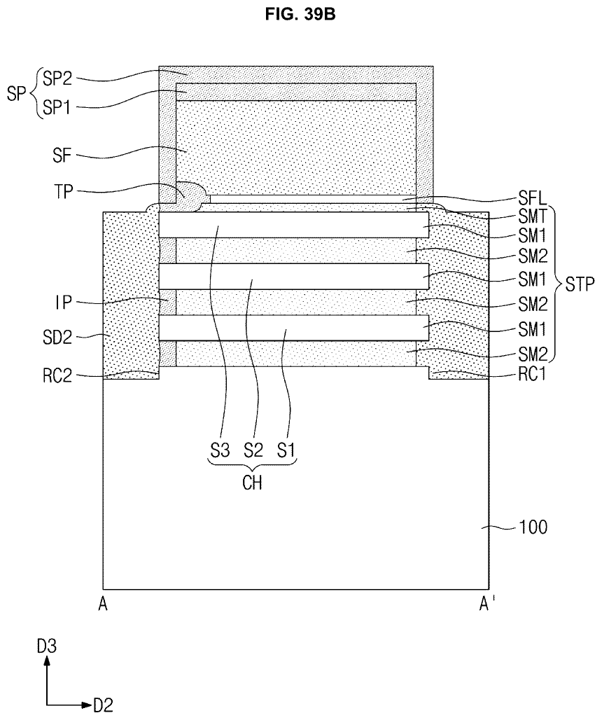

Referring to FIGS. 38A, 38B, and 37C, a portion of the gate spacer pattern SP and a portion of the stack pattern STP on the active pattern AP may be removed, and the first recess RC1 may be formed at one side of the stack pattern STP. The first recess RC1 may correspond to the area in which the first source/drain pattern SD1 is to be formed. In an embodiment, the first source/drain pattern SD1 may later be used as a source of the semiconductor device.

The remaining portion of the stack pattern STP exposed through the first recess RC1 may be selectively etched. For example, the uppermost semiconductor layer SMT and the second semiconductor layers SM2 may be selectively etched. As the uppermost semiconductor layer SMT and the second semiconductor layers SM2 are selectively etched, the side surfaces of the uppermost semiconductor layer SMT and the second semiconductor layers SM2 may be recessed inward along the horizontal direction more than the side surfaces of the first semiconductor layers SM1.

Referring to FIGS. 39A, 39B, and 37C, the first source/drain pattern SD1 may be formed in the first recess RC1, and the second source/drain pattern SD2 may be formed in the second recess RC2. The first and second source/drain patterns SD1 and SD2 may be formed at opposite sides of the stack pattern STP. Since the first and second source/drain patterns SD1 and SD2 are formed, the channel pattern CH may be formed between the first source/drain pattern SD1 and the second source/drain pattern SD2. The channel pattern CH may include first, second, and third semiconductor patterns S1, S2, and S3 that are sequentially stacked.

In the present embodiment, the inner spacer IP may not be provided between the first source/drain pattern SD1 and the second semiconductor layers SM2, and the inner spacers IP may be provided only between the second source/drain pattern SD2 and the second semiconductor layers SM2.

After the first source/drain pattern SD1 and the second source/drain pattern SD2 are formed, the processes corresponding to FIGS. 13A to 18B may be sequentially performed.

In manufacturing a semiconductor device according to one or more embodiments, some of the above-described components may be omitted. For example, the semiconductor device according to the present embodiment may include a stacked structure in which the first semiconductor layers SM1 are alternately stacked with the second semiconductor layers SM2, but the stack pattern STP may not include the uppermost semiconductor layer as in the above-described embodiment.

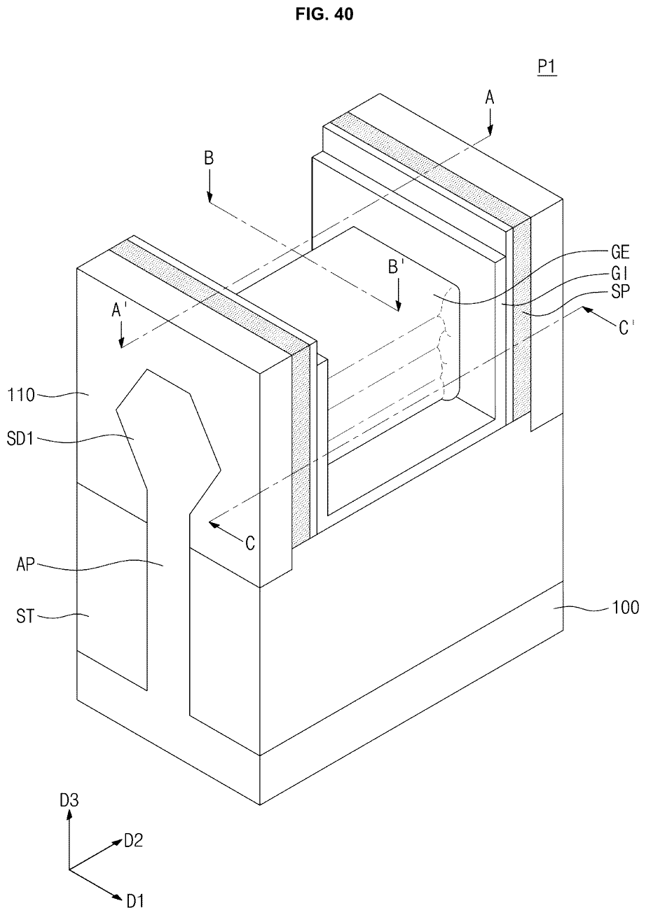

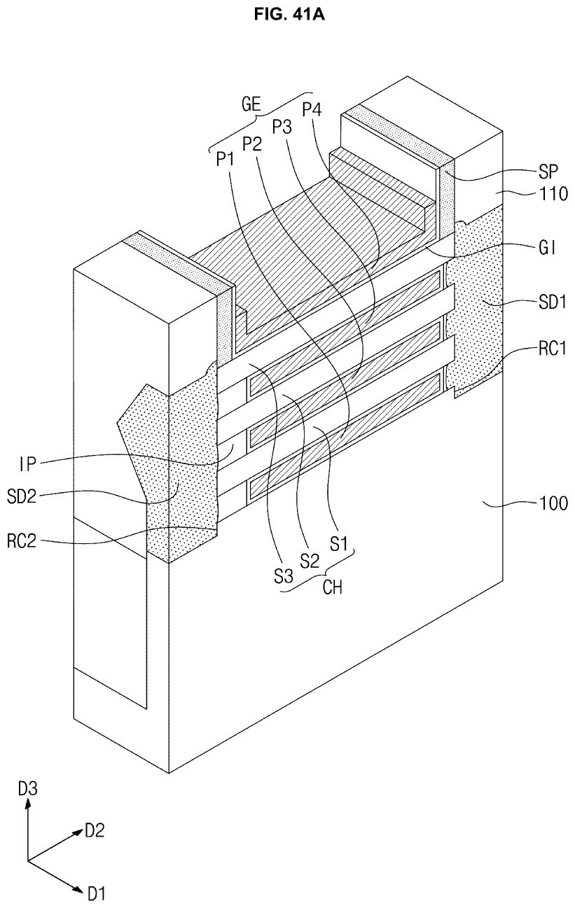

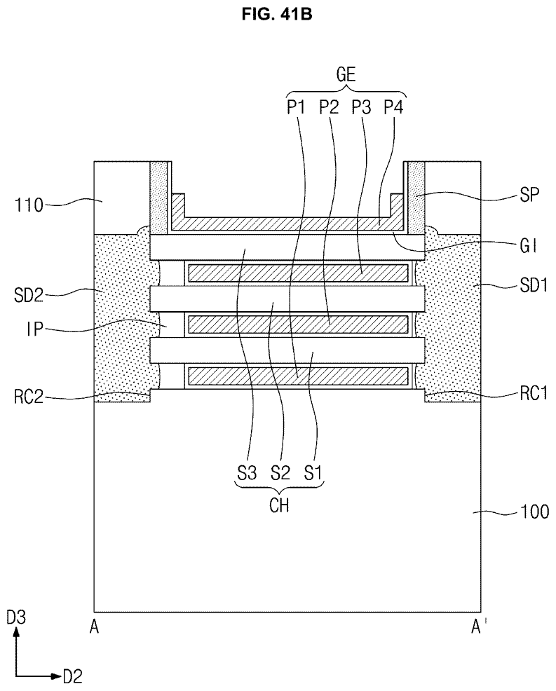

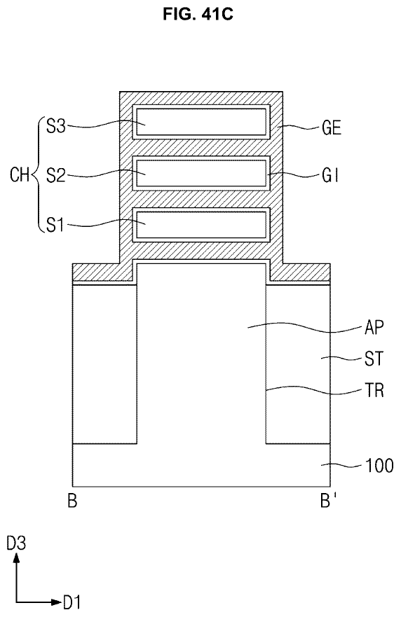

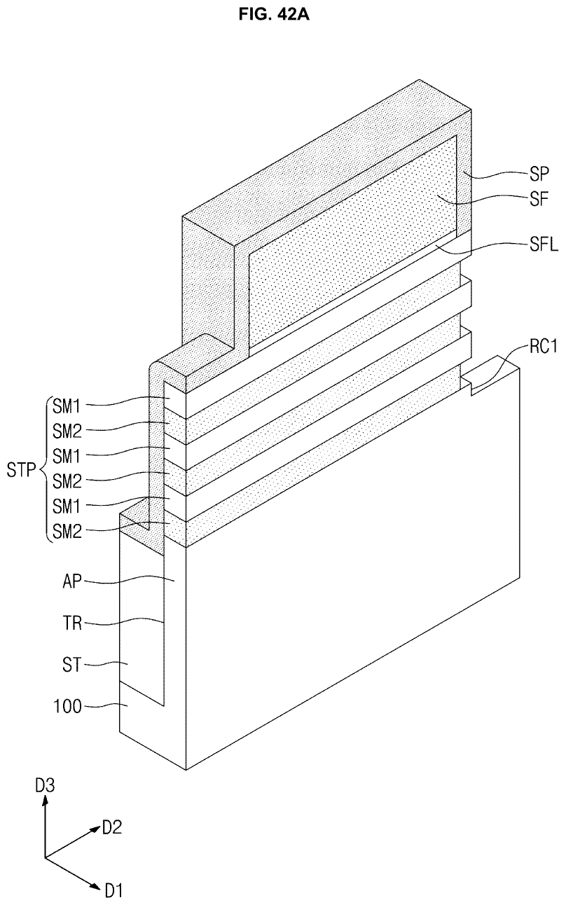

FIG. 40 is a perspective view illustrating a semiconductor device according to one or more embodiments. FIGS. 41A to 41C are views illustrating the semiconductor device according to one or more embodiments, FIG. 41A is a cross-sectional perspective view taken along a line A-A′ of FIG. 40, FIG. 41B is a cross-sectional view taken along the line A-A′ of FIG. 40, and FIG. 41C is a cross-sectional view taken along a line B-B′ of FIG. 40.

Referring to FIGS. 40 and 41A to 41C, unlike the previous embodiments, a sloped insulation pattern may be provided between a gate electrode GE and a channel pattern CH. For example, the sloped insulation pattern TP may be provided on an outer side surface of the channel pattern CH. The sloped insulation pattern TP may be provided on an outer side surface of each of first, second, and third semiconductor patterns S1, S2, and S3. In addition, the sloped insulation pattern TP may also be provided on outer side surfaces of inner spacers, and in this case, the sloped insulation pattern TP on the outer side surfaces may be integrally formed with the inner spacers IP without being separated. The sloped insulation pattern TP may not be provided on an uppermost portion of the channel pattern CH, i.e., on the third semiconductor pattern S3.

Although the sloped insulation pattern TP is not provided on the uppermost portion of the channel pattern CH, the sloped insulation pattern TP may still be used as a field plate since the sloped insulation pattern TP is provided on the outer side surface of the channel pattern CH, and thus, effects similar to those of an LDMOS device may be achieved.

A method of manufacturing the semiconductor device having the above-described structure is as follows.

As shown in FIGS. 3A, 3B, and 3C, a stack pattern STP may be formed on a substrate 100. To facilitate the formation of the channel pattern CH, the stack pattern STP may include different material layers that are alternately stacked one on another. In an embodiment, the stack pattern STP may include first semiconductor layers SM1 and second semiconductor layers SM2 alternately stacked with the first semiconductor layers SM1. In the present embodiment, a relatively thin uppermost semiconductor layer SMT is not provided on an uppermost first semiconductor layer SM1. A patterning process may be performed on the stack pattern STP and the substrate 100 to form a trench TR that defines an active area. The trench TR may be formed at both sides of the active pattern AP. A device isolation layer ST may fill the trench TR.

Then, as illustrated in FIGS. 4A, 4B, and 4C, a sacrificial pattern SF and a sub-sacrificial pattern SFL crossing the active pattern AP may be formed on the substrate 100. In detail, the sub-sacrificial pattern SFL may be formed on the uppermost first semiconductor layer SM1 of the stack pattern STP, and the sacrificial pattern SF may be formed on the sub-sacrificial pattern SFL. A gate spacer pattern SP may be formed on the sacrificial pattern SF. The gate spacer pattern SP may be conformally formed over the surface of the substrate 100.

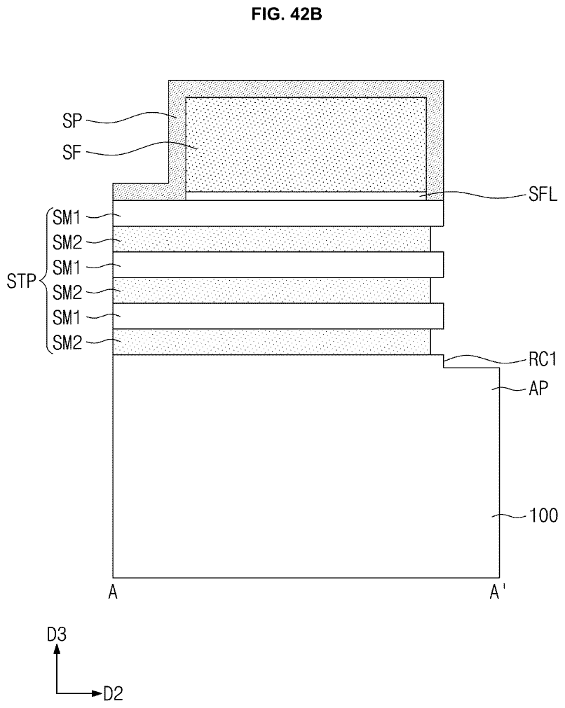

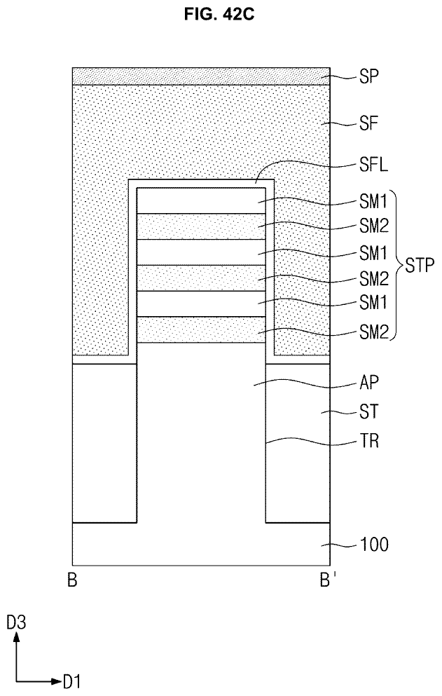

As illustrated in FIGS. 42A, 42B, and 42C, a portion of the gate spacer pattern SP and a portion of the stack pattern STP on the active pattern AP are removed, and thus, a first recess RC1 may be formed at one side of the stack pattern STP. The first recess RC1 may correspond to an area in which a first source/drain pattern SD1 is to be formed. According to embodiments, the first recess RC1 may be formed deeper than upper surfaces of the active pattern AP and/or the device isolation layer ST. A portion of the stack pattern STP exposed through the first recess RC1 may be selectively etched. For instance, the second semiconductor layers SM2 may be selectively etched without etching other components. As the second semiconductor layers SM2 are selectively etched, side surfaces of the second semiconductor layers SM2 may be inwardly recessed more than side surfaces of the first semiconductor layers SM1 in a horizontal direction.

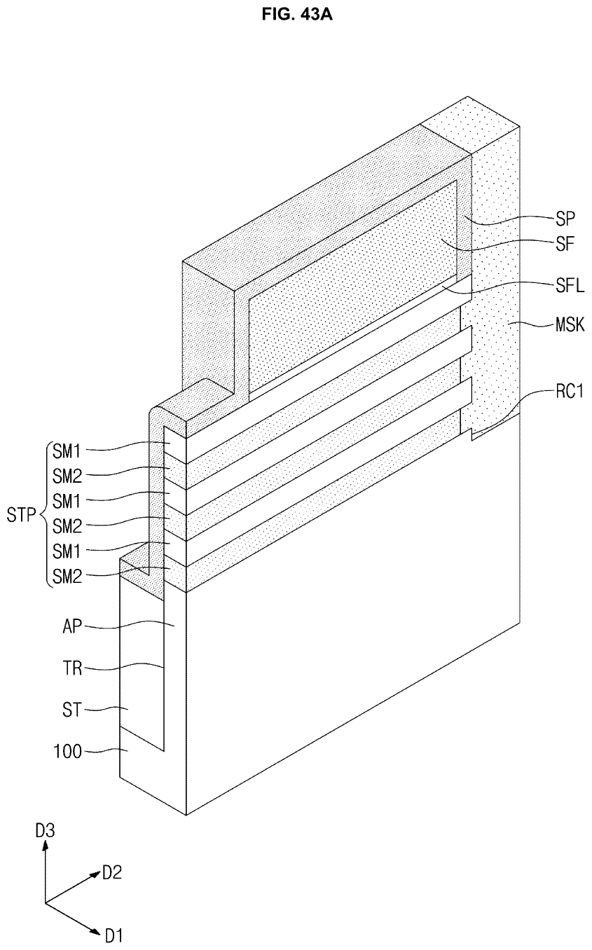

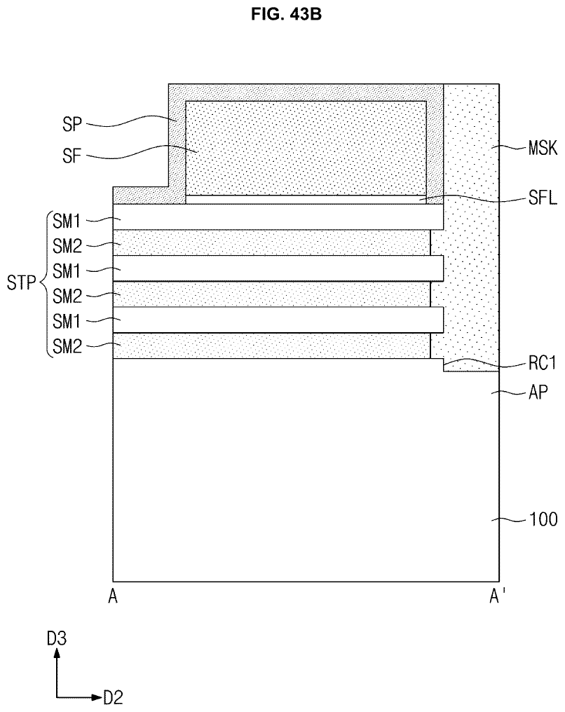

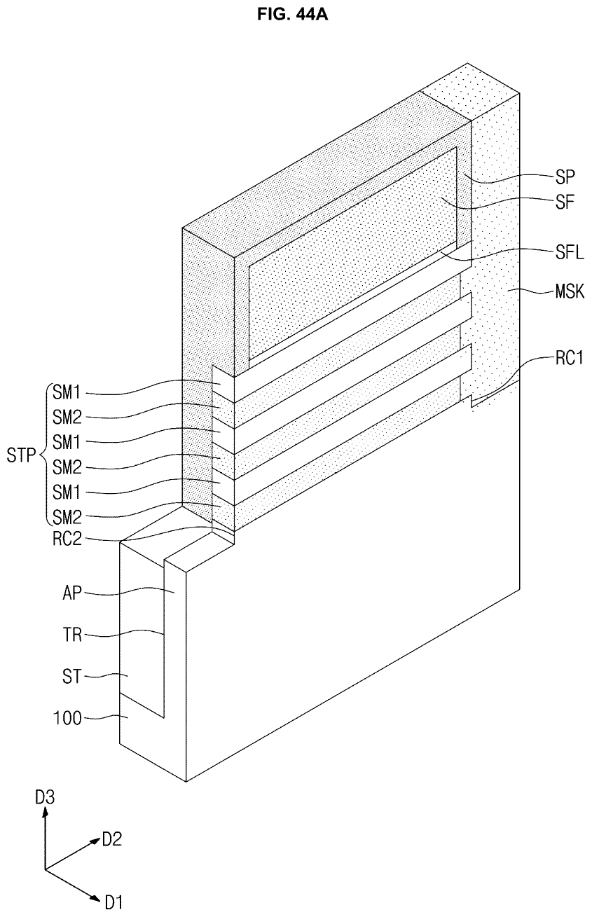

Referring to FIGS. 43A, 43B, and 42C, a protective mask MSK may be formed in the first recess RC1. In an embodiment, the protective mask MSK may be formed only in the first recess RC1 and may not be formed in other areas.

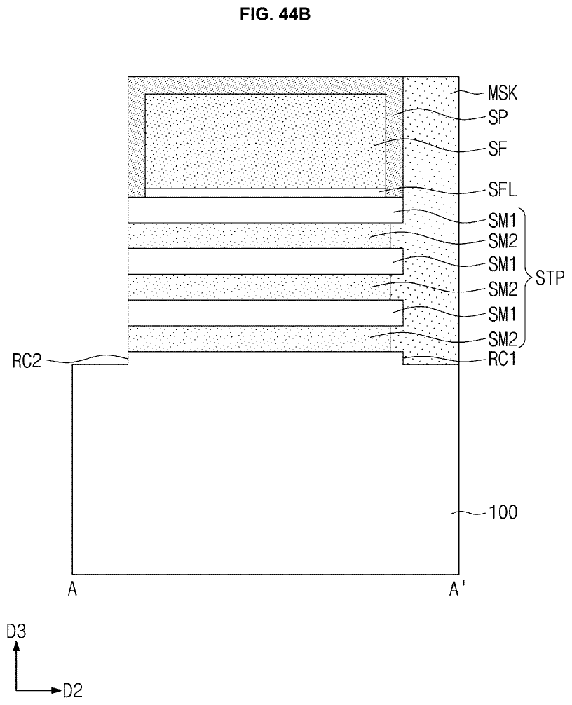

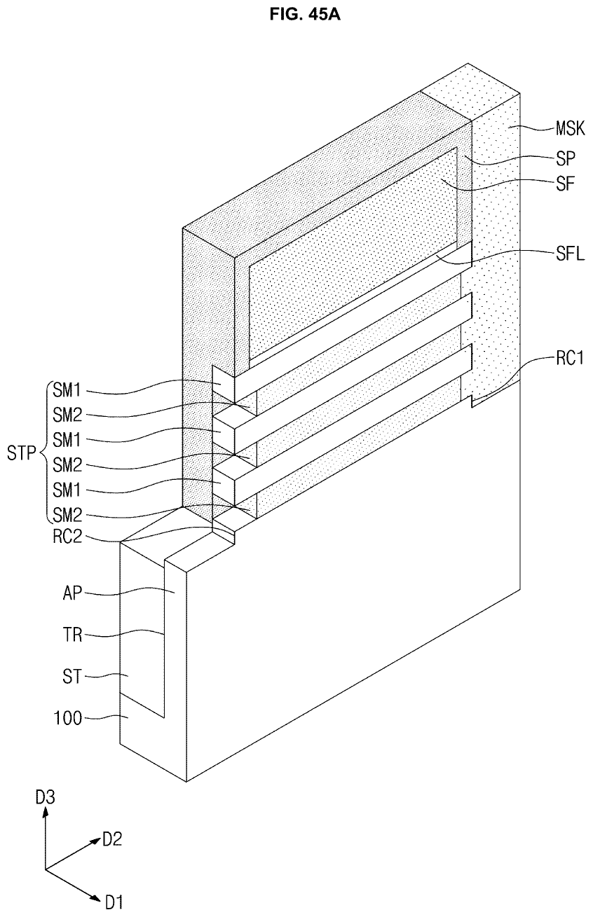

Referring to FIGS. 44A, 44B, and 42C, a portion of the gate spacer pattern SP and a portion of the stack pattern STP on the active pattern AP are removed, and thus, a second recess RC2 may be formed at the other side of the stack pattern STP. The first recess RC1 may be formed at the one side of the stack pattern STP extending in the second direction D2, and the second recess RC2 may be formed at the other side of the stack pattern STP.

A dopant implantation for forming a lightly doped drain (LDD) may be additionally performed on the surface of the substrate 100 in which the second recess RC2 is formed.

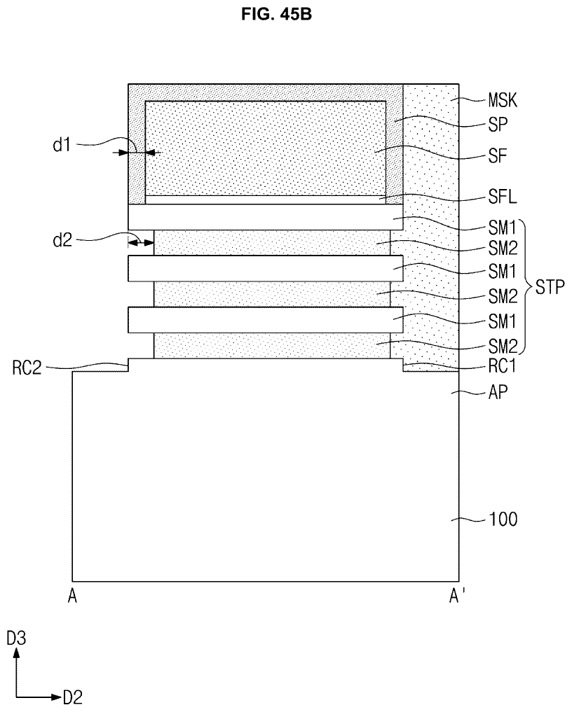

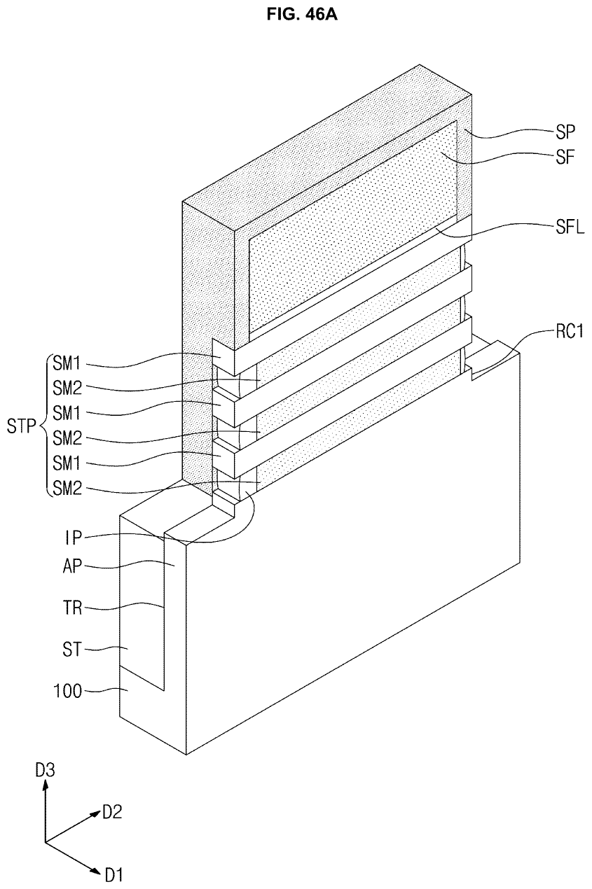

Referring to FIGS. 45A, 45B, and 42C, a portion of the stack pattern STP exposed through the second recess RC2 may be selectively etched. For example, the exposed side surfaces of the second semiconductor layers SM2 may be selectively etched. As the second semiconductor layers SM2 are selectively etched, the side surfaces of the second semiconductor layers SM2 may be recessed inward along the horizontal direction more than the side surfaces of the first semiconductor layers SM1.

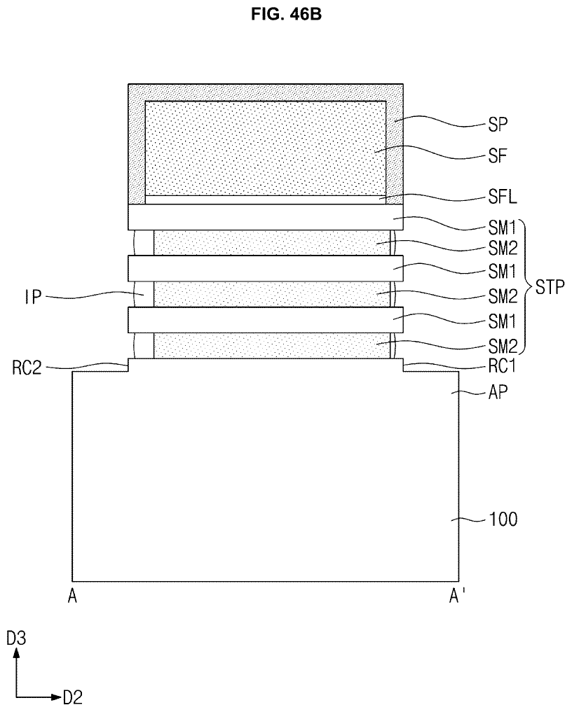

Referring to FIGS. 46A, 46B, and 42C, the protective mask MSK formed in the first recess RC1 may be removed, and a side surface of the stack pattern STP corresponding to the first recess RC1 may be exposed to the outside. For example, the side surfaces of the first semiconductor layers SM1, and the second semiconductor layers SM2 may be exposed to the outside.

Then, the processes illustrated in FIGS. 12A to 18C may be performed in substantially the same manner, and thus, the semiconductor device may be formed.

In the above-described embodiments, the semiconductor device is illustrated as a three-dimensional field effect transistor, such as a multi-bridge channel FET (MBCFET), but the disclosure should not be limited thereto or thereby. The semiconductor device according to the embodiment of the present disclosure may also be applied to a fin-type transistor.

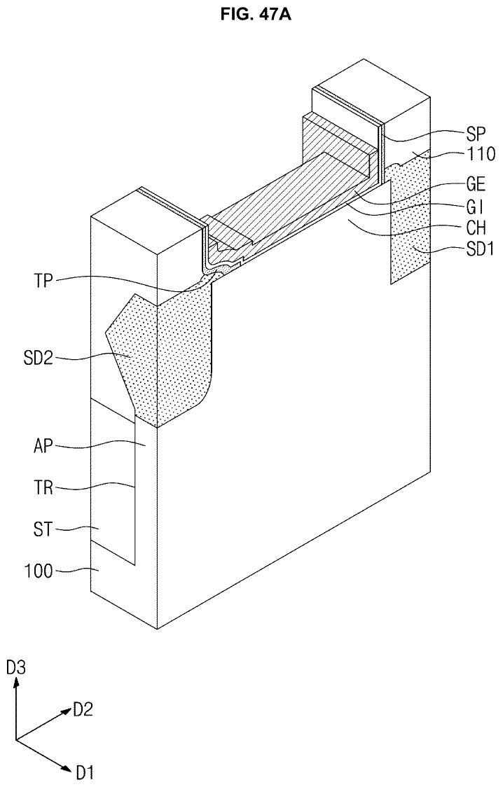

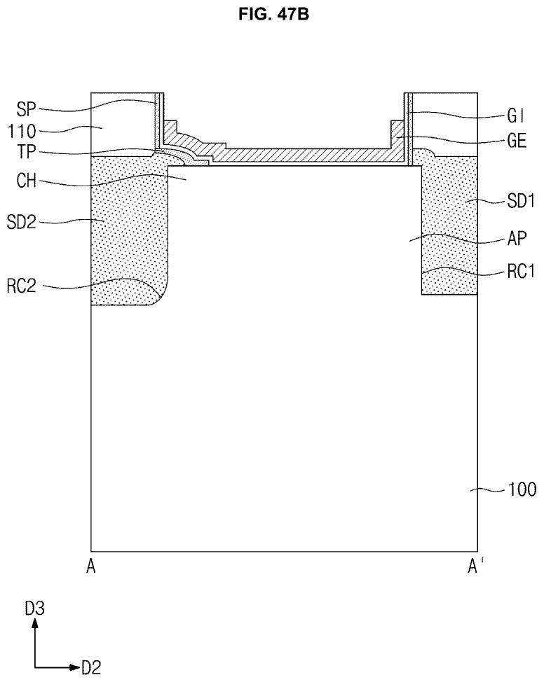

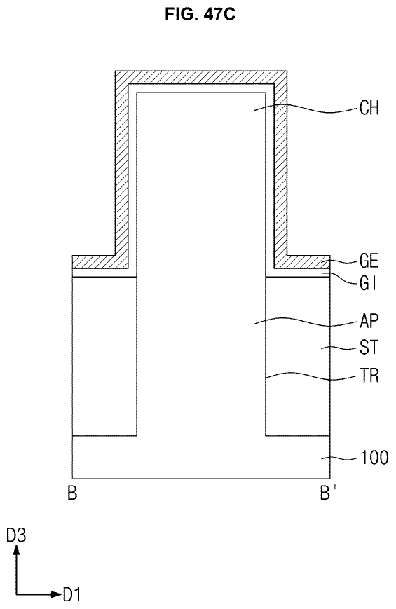

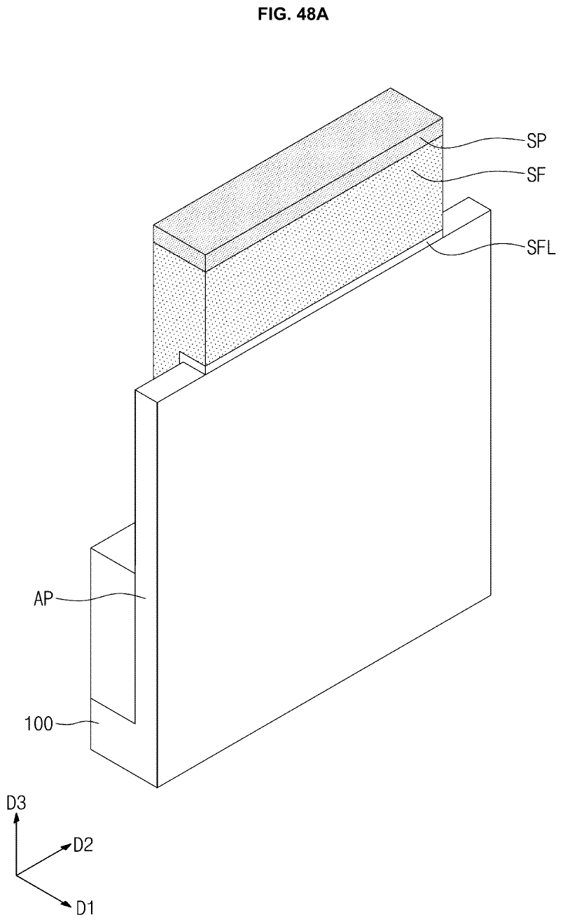

FIGS. 47A, 47B, and 47C are views illustrating a semiconductor device according to one or more embodiments, FIG. 47A is a cross-sectional perspective view taken along the line A-A′ of FIG. 1B, FIG. 47B is a cross-sectional view taken along the line A-A′ of FIG. 1B, and FIG. 47C is a cross-sectional view taken along the line B-B′ of FIG. 1B. Although the semiconductor device according to the embodiment of the present disclosure is not identical to that shown in FIG. 1B, cross-sectional views corresponding to the lines illustrated in FIG. 1B are provided for convenience of explanation.

Referring to FIGS. 47A to 47C, the semiconductor device may be provided on a substrate 100.

A trench TR formed in the substrate 100 may define an active pattern AP, and the trench TR may be filled with a device isolation layer ST.

A first recess RC1 and a second recess RC2 may be defined at an upper portion of the active pattern AP, and a first source/drain pattern SD1 and a second source/drain pattern SD2 may be provided in the first and second recesses RC1 and RC2, respectively. A channel pattern CH may be disposed between the first source/drain pattern SD1 and the second source/drain pattern SD2.

A gate electrode GE may extend across the active pattern AP in the first direction D1. The gate electrode GE may cover side surfaces and an upper surface of the channel pattern CH.

A pair of gate spacer patterns SP may be disposed at opposite side surfaces of each fourth portion of the gate electrode GE. The gate spacer patterns SP may extend along each gate electrode GE in the first direction D1.

A gate insulating layer GI may be disposed between each gate electrode GE and each channel pattern CH. The gate insulating layer GI may cover the upper surface and side surfaces of the channel pattern CH.

A sloped insulation pattern TP may be provided between the gate electrode GE and the channel pattern CH. In addition, the sloped insulation pattern TP may also be provided on an outer side surface of the channel pattern CH. slopedAt an uppermost portion of the channel pattern CH, the sloped insulation pattern TP may be in contact with the second source/drain pattern SD2 and may include a slope surface inclined with respect to an uppermost surface of the channel pattern CH. The sloped insulation pattern TP provided on the outer side surface of the channel pattern CH may include a slope surface that is inclined with respect to the outer side surface of the channel pattern CH. The gate insulating layer GI and the gate electrode GE may be sequentially stacked on the slope surface of the sloped insulation pattern TP.

An end portion of the gate electrode GE, which is at the side of the second source/drain pattern SD2, may vertically overlap the sloped insulation pattern TP. The sloped insulation pattern TP may function as an insulating layer that electrically isolates the gate electrode GE from the second source/drain pattern SD2 together with the gate insulating layer GI and may also function as a field plate of a laterally diffused metal oxide semiconductor (LDMOS) device.

A cover layer 110 may be provided on the substrate 100. The cover layer 110 may be provided on the device isolation layer ST and may cover a portion of the first source/drain pattern SD1 and a portion of the second source/drain pattern SD2.

Since the semiconductor device having the above-described structure includes the sloped insulation pattern TP, the semiconductor device may achieve an effect similar to that of the LDMOS.

A method of manufacturing the semiconductor device having the above-described structure is as follows.

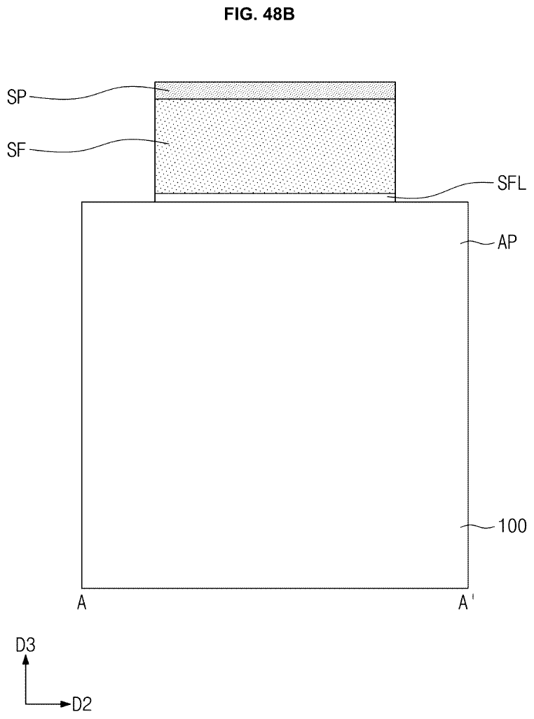

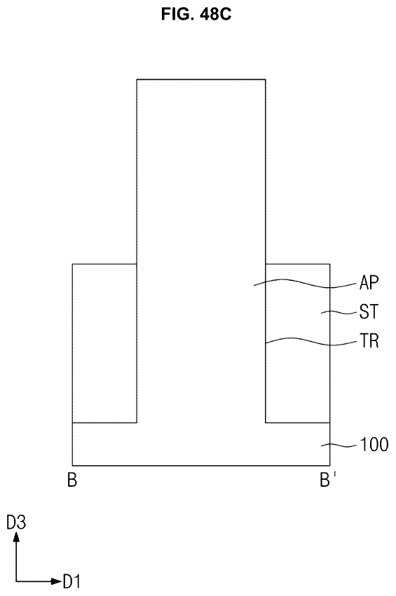

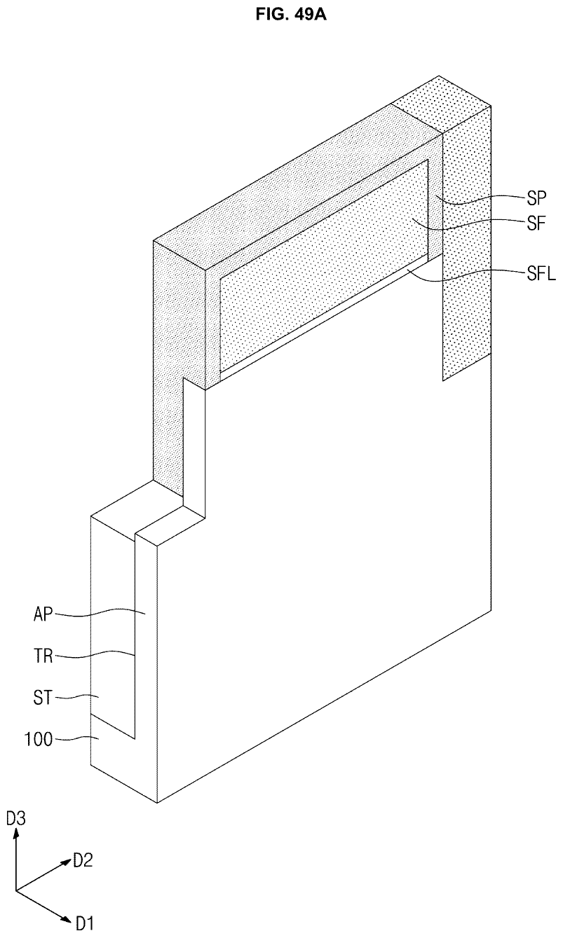

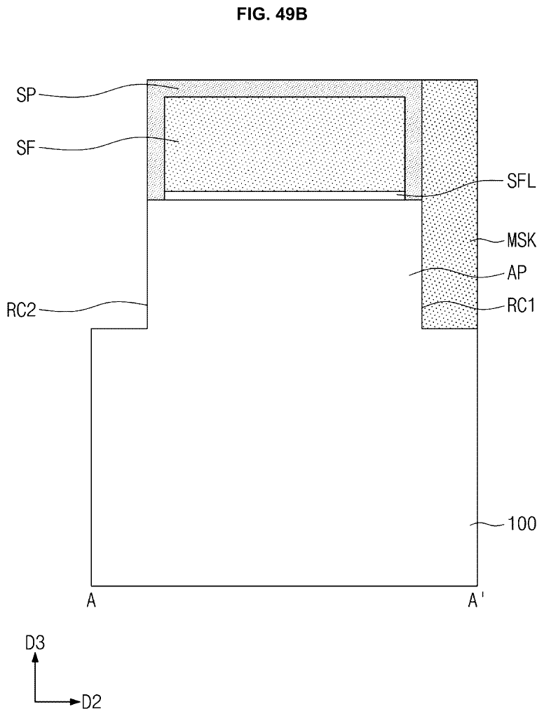

Referring to FIGS. 48A, 48B, and 48C, a patterning process may be performed on the substrate 100 to form the trench TR that defines an active area. The trench TR may be formed at opposite sides of the active pattern AP. The active pattern AP may have a bar shape extending in a direction parallel to the second direction D2. The device isolation layer ST may fill the trench TR.

A sacrificial pattern SF and a sub-sacrificial pattern SFL, which cross the active pattern AP, may be formed on the substrate 100. In detail, the sub-sacrificial pattern SFL may be formed on an uppermost semiconductor layer of a stack pattern, and the sacrificial pattern SF may be formed on the sub-sacrificial pattern SFL.

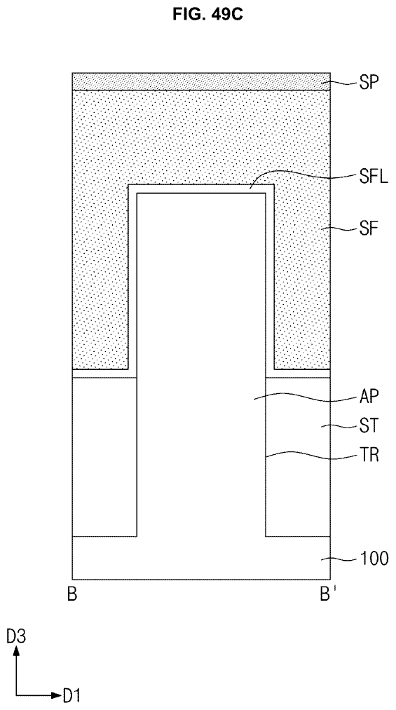

Referring to FIGS. 49A, 49B, and 49C, a gate spacer pattern SP may be formed on the sacrificial pattern SF. The gate spacer pattern SP may be conformally formed on the surface of the substrate 100.

The first recess RC1 and the second recess RC2 may be formed at the opposite sides of the active pattern AP by removing a portion of the gate spacer pattern SP and a portion of the active pattern AP. The first recess RC1 may be an area in which the first source/drain pattern SD1 is to be formed, and the second recess RC2 may be an area in which the second source/drain pattern SD2 is to be formed. Then, a protective mask MSK may be formed to fill the first recess RC1. An upper surface of the protective mask MSK may be substantially coplanar with an upper surface of the gate spacer pattern SP. A dopant implantation to form a lightly doped drain (LDD) may be performed on the surface of the substrate 100 in which the second recess RC2 is formed.

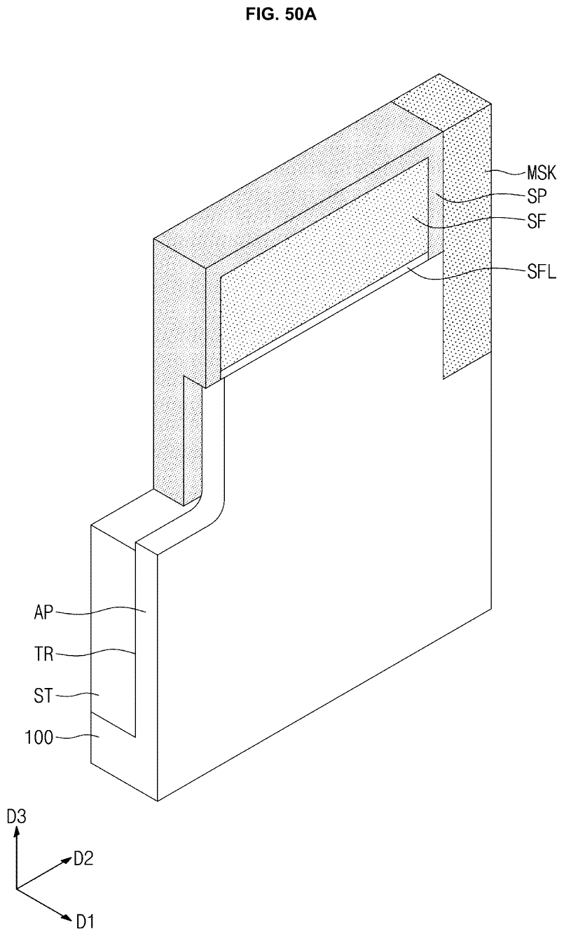

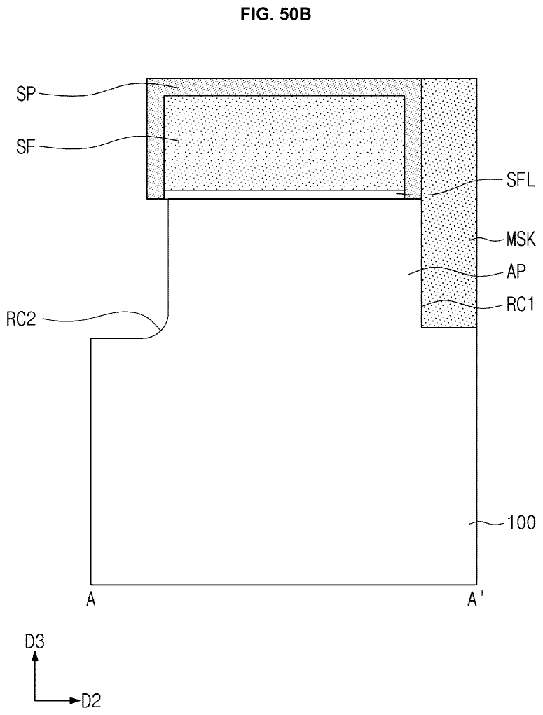

Referring to FIGS. 50A, 50B, and 49C, a portion of the active pattern AP exposed through the second recess RC2 may be selectively etched.

Since the active pattern AP is selectively etched, a side surface of the active pattern AP may be recessed inward more than a side surface of the gate spacer pattern SP. The side surface of the active pattern AP may be etched until a portion of a lower surface of the sub-sacrificial pattern SFL is exposed.

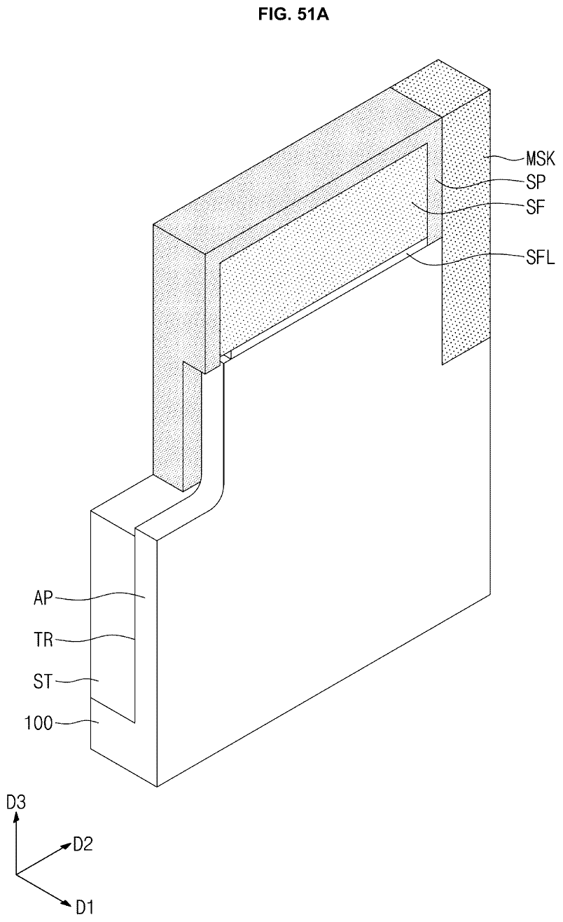

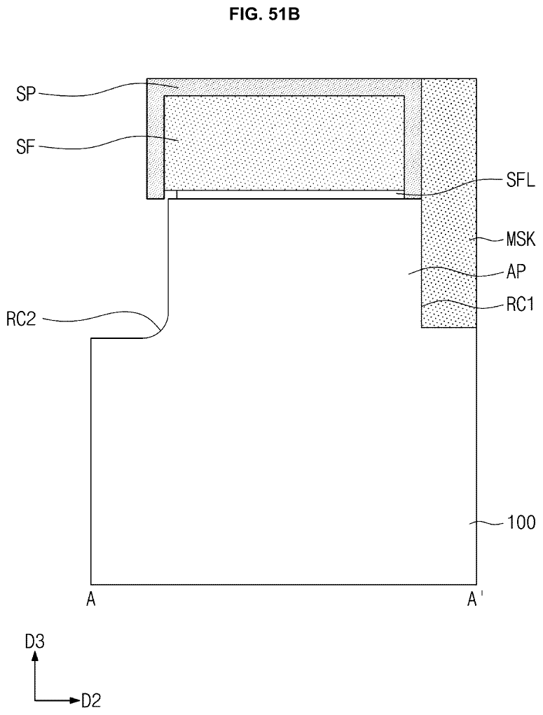

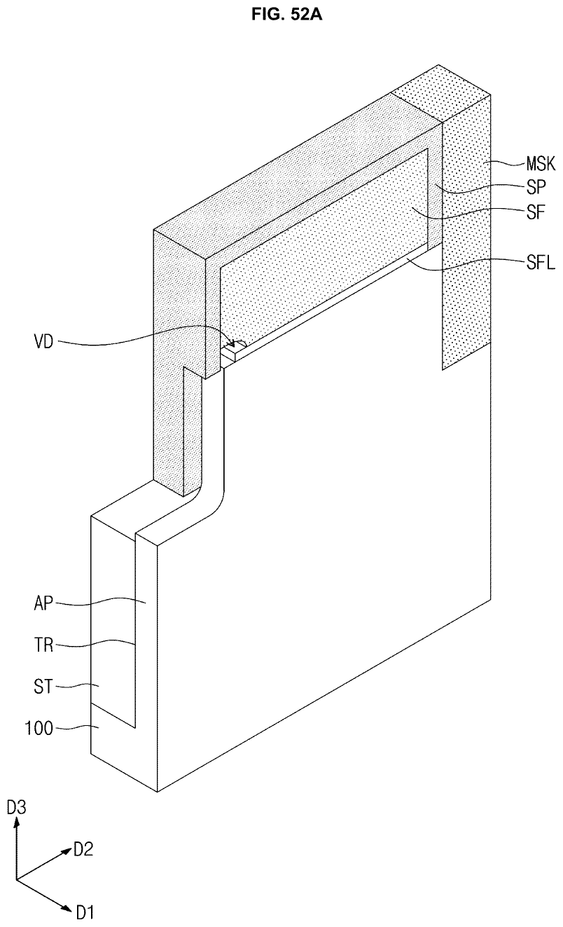

Referring to FIGS. 51A, 51B, and 49C, a portion of the exposed sub-sacrificial pattern SFL may be etched. The sub-sacrificial pattern SFL may be partially etched sequentially in an inward direction from its exposed lower surface, and the etching process may be performed until a portion of a lower surface of the sacrificial pattern SF is exposed. As a result, a void VD may be formed, which is surrounded by an inner side surface of the gate spacer pattern SP, the lower surface of the sacrificial pattern SF, a side surface of the sub-sacrificial pattern SFL, and an upper surface of the active pattern AP.

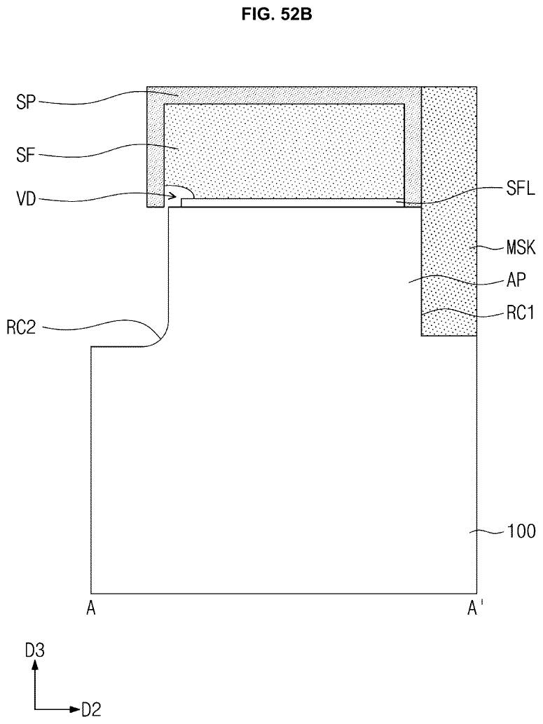

Referring to FIGS. 52A, 52B, and 49C, a portion of the exposed sacrificial pattern SF may be etched. The sacrificial pattern SF may be partially etched sequentially in the inward direction from its exposed lower surface. Due to the etching in the inward direction, the sacrificial pattern SF may also be recessed inward. As the sacrificial pattern SF is partially etched, the void VD, which is larger than that of the previous process may be formed.

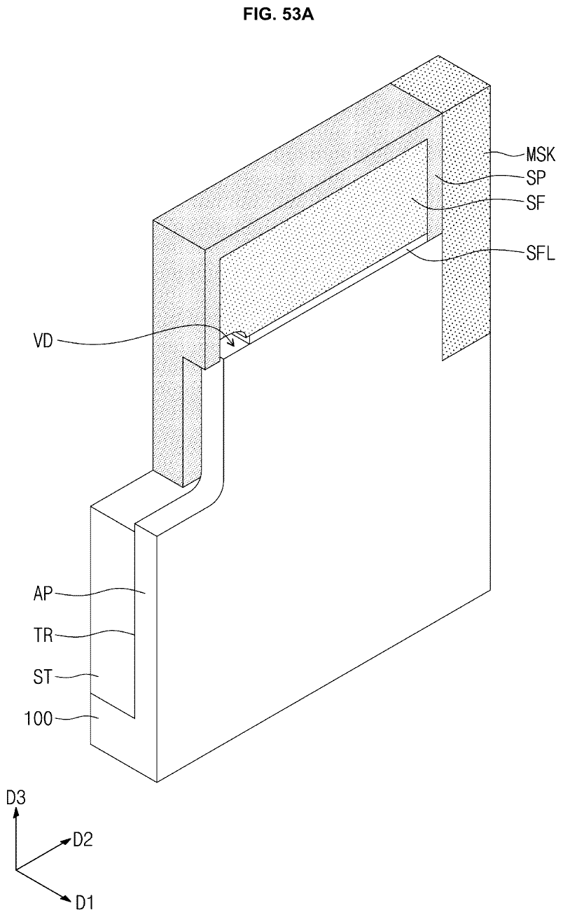

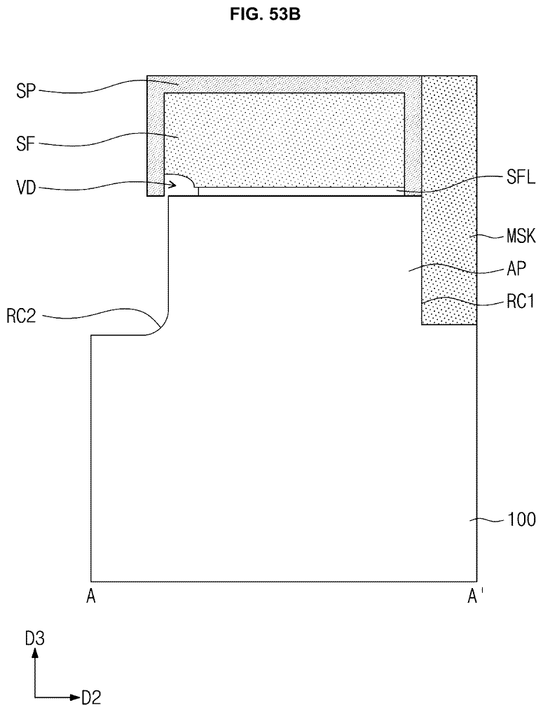

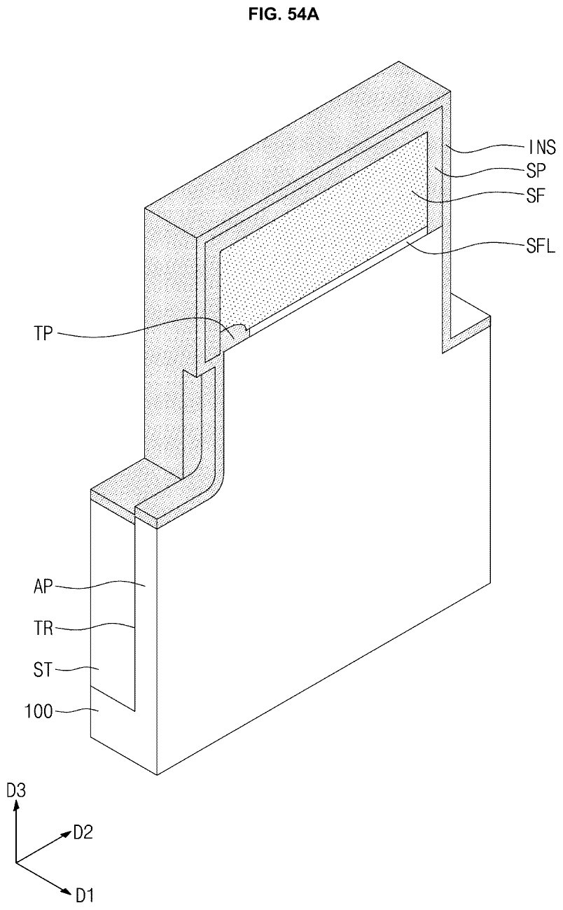

Referring to FIGS. 53A, 53B, and 49C, an additional etching process may be performed to expand the void VD. The additional etching process may be performed to etch a portion of the active pattern AP. Through the additional etching process, a recess formed inward along the horizontal direction more than the side surface of the sub-sacrificial pattern SFL may be formed.

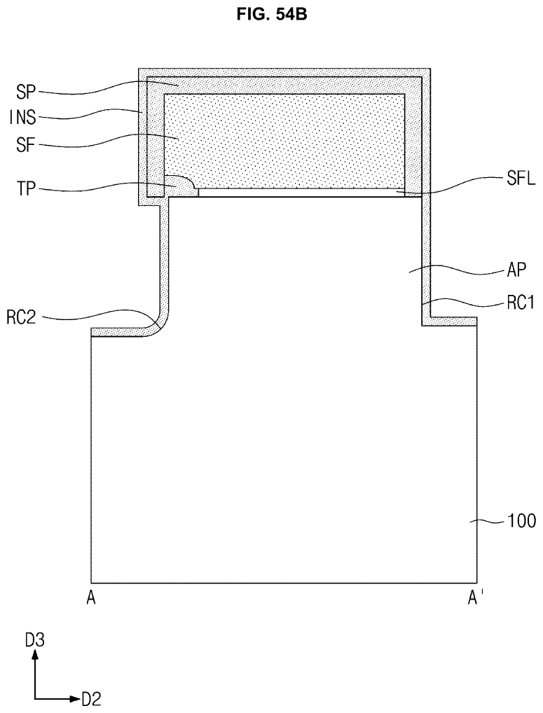

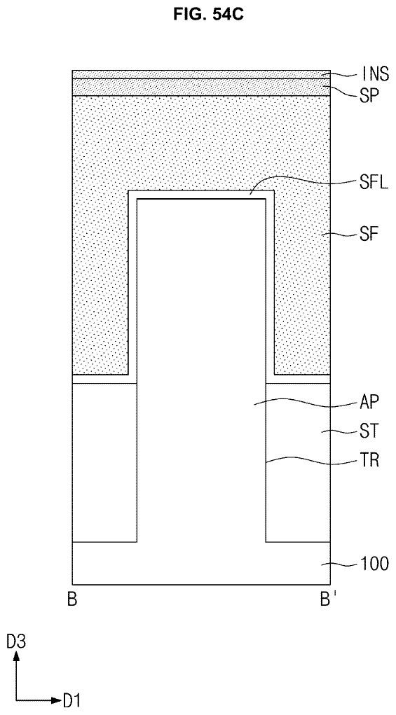

Referring to FIGS. 54A, 54B, and 54C, the protective mask MSK formed at one side of the sacrificial pattern SF may be removed, and an insulating layer may be conformally formed on the substrate 100. The insulating layer may fill the void VD and simultaneously cover the surface of the substrate 100.

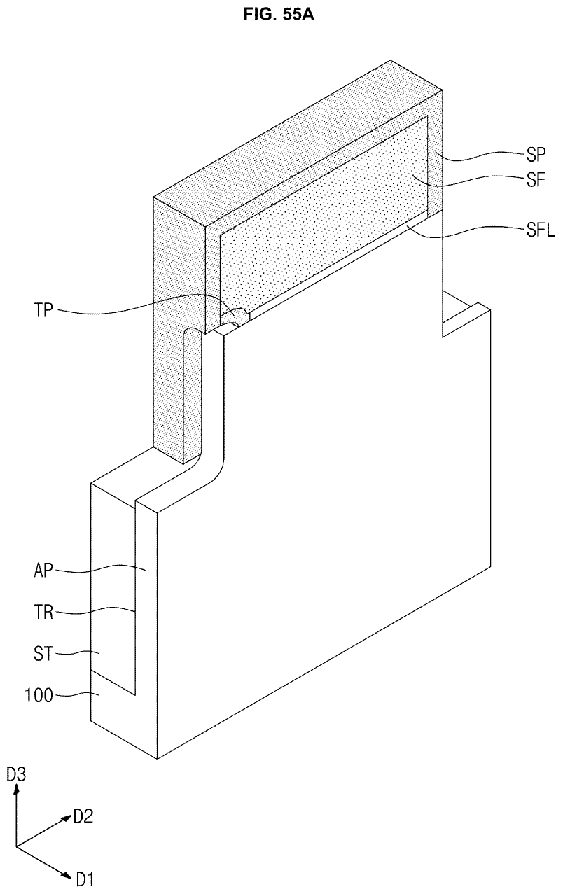

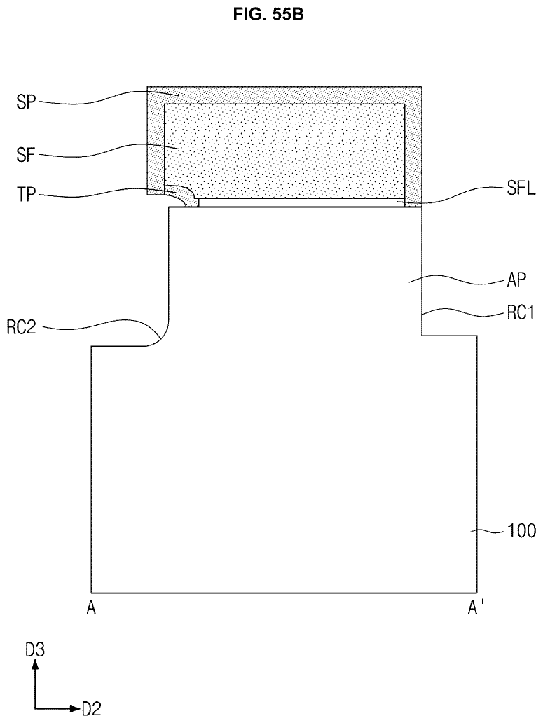

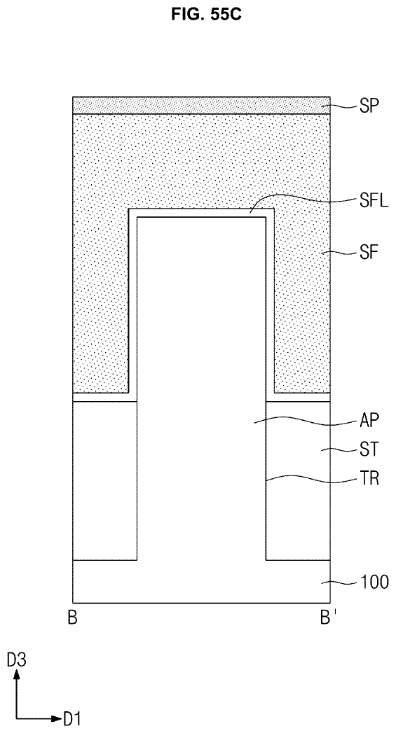

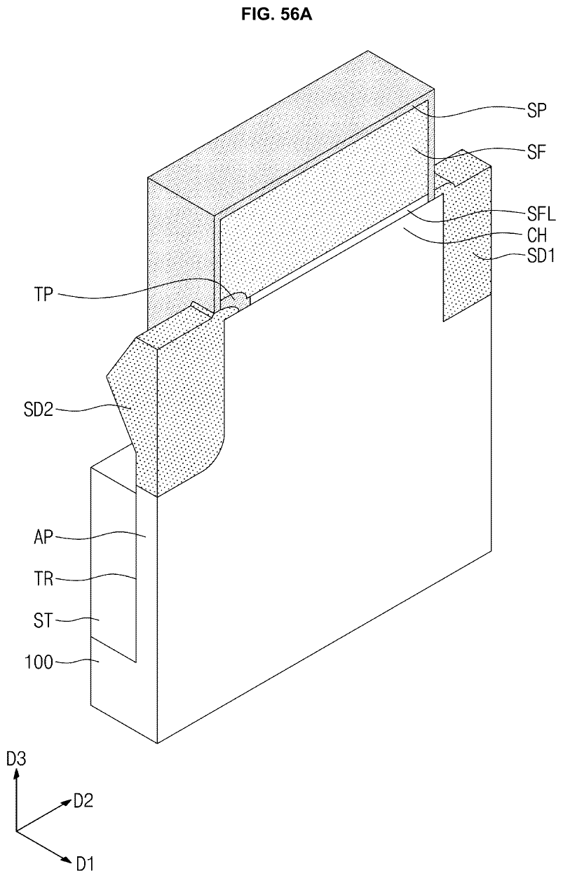

Referring to FIGS. 55A, 55B, and 55C, the insulating layer formed on the surface of the substrate 100 may be anisotropically patterned, and thus, a portion of the insulating layer except for a portion formed in the void VD including the recess may be removed. The insulating layer filled in the void VD including the recess may form the sloped insulation pattern TP.

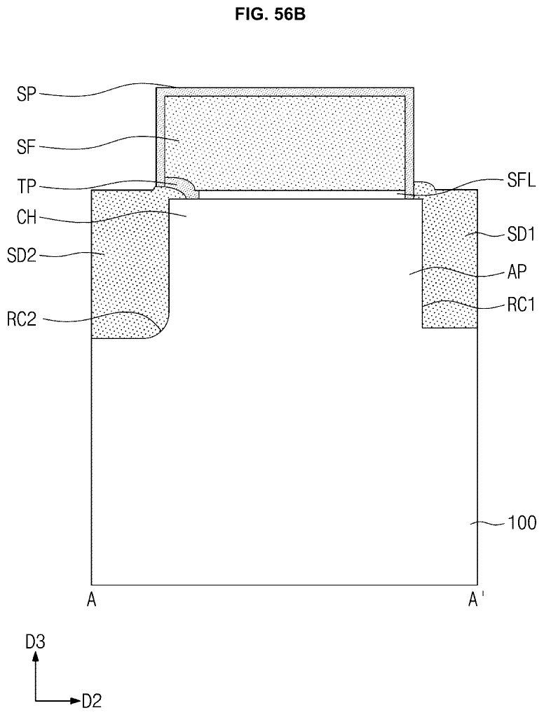

Referring to FIGS. 56A, 56B, and 55C, the first source/drain pattern SD1 may be formed in the first recess RC1, and the second source/drain pattern SD2 may be formed in the second recess RC2. The first and second source/drain patterns SD1 and SD2 may be formed at opposite sides of the stack pattern STP. Since the first and second source/drain patterns SD1 and SD2 are formed, the channel pattern CH may be formed between the first source/drain pattern SD1 and the second source/drain pattern SD2.

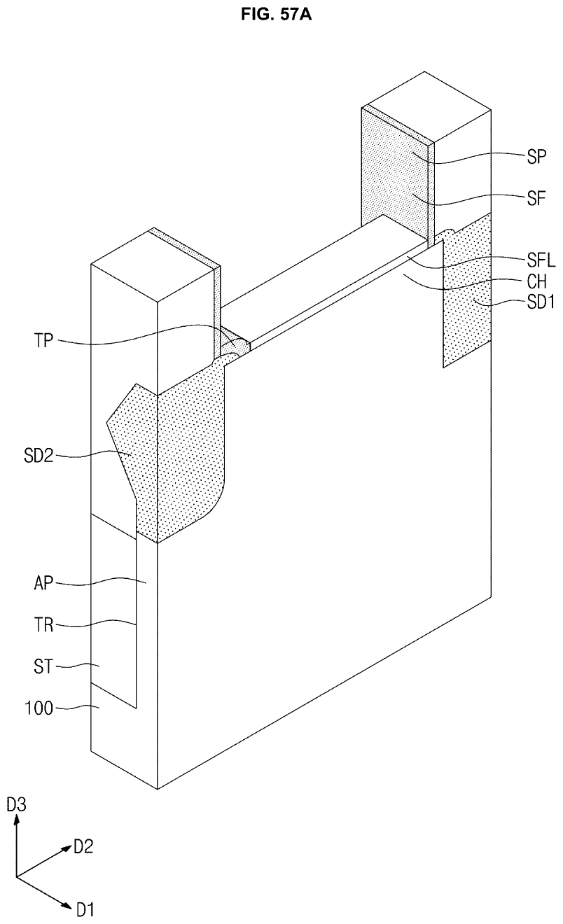

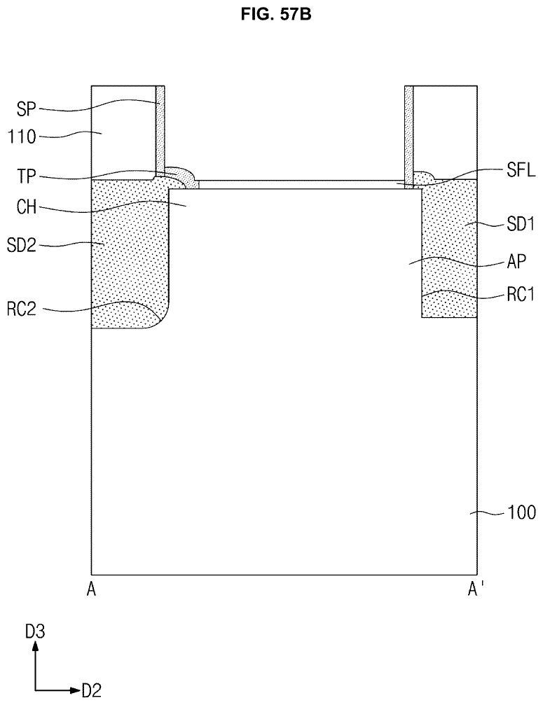

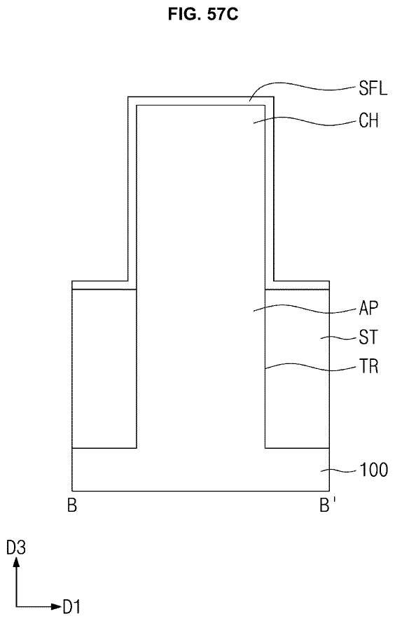

Referring to FIGS. 57A, 57B, and 57C, the cover layer 110 may be formed to cover the first source/drain pattern SD1, the second source/drain pattern SD2, and the gate spacer pattern SP. The cover layer 110 may be planarized until an upper surface of the sacrificial pattern SF is exposed. Then, the sacrificial pattern SF may be removed, and an upper surface of a lower sacrificial pattern SFL, an upper surface of the sloped insulation pattern TP, and the side surfaces of the gate spacer pattern SP may be exposed. The sloped insulation pattern TP may be provided on an upper surface of the active pattern AP but may be provided only on the other side adjacent to the second source/drain pattern SD2. The sloped insulation pattern TP may be formed to be thicker than the lower sacrificial pattern SFL. One side of the upper surface of the sloped insulation pattern TP, that is, a slope surface, may be in contact with the gate spacer pattern SP, and the other side of the upper surface of the sloped insulation pattern TP may be in contact with the lower sacrificial pattern SFL. When viewed in a cross-section, the sloped insulation pattern TP may have a sloped shape extending from the portion in contact with the gate spacer pattern SP to the portion in contact with the sacrificial pattern SF.

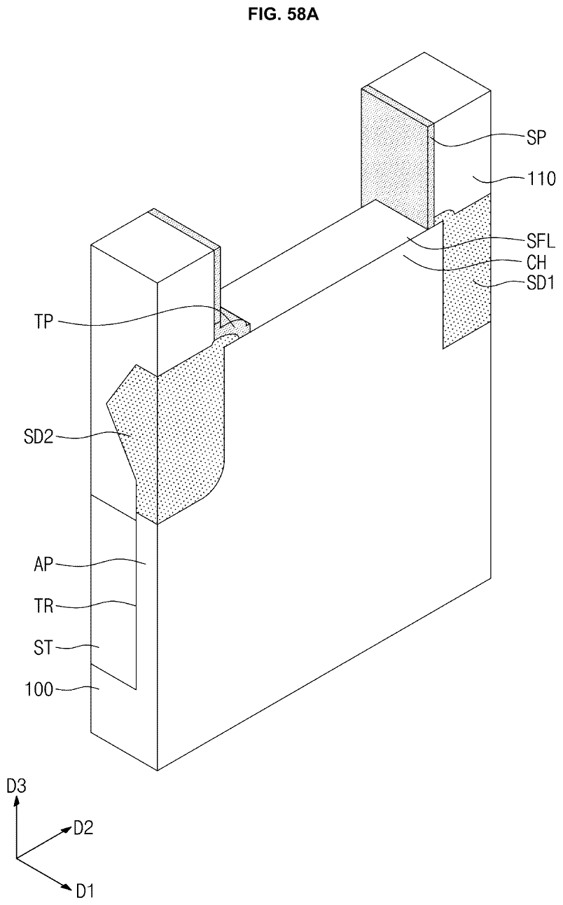

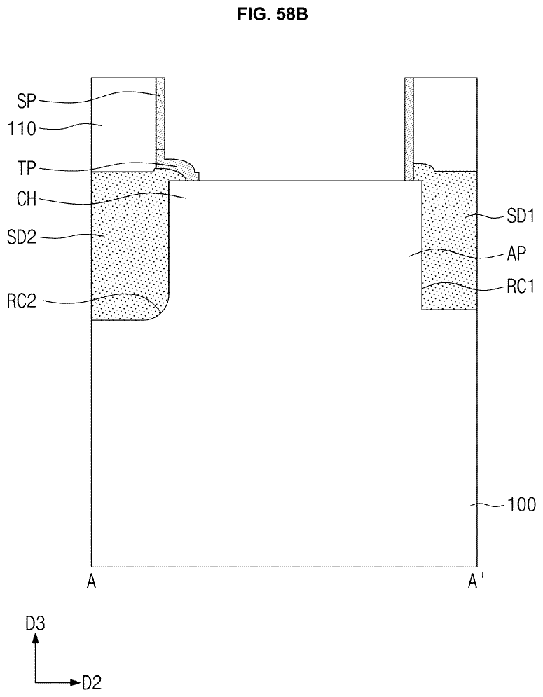

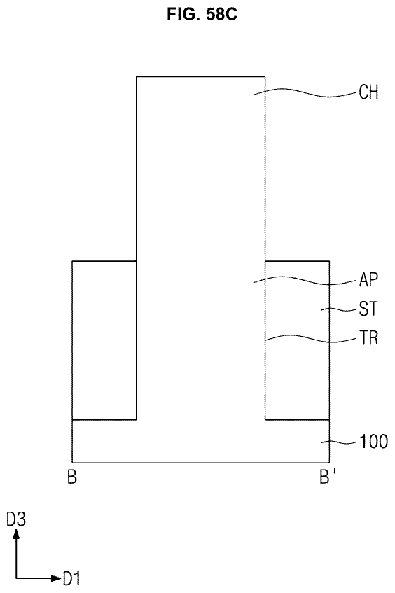

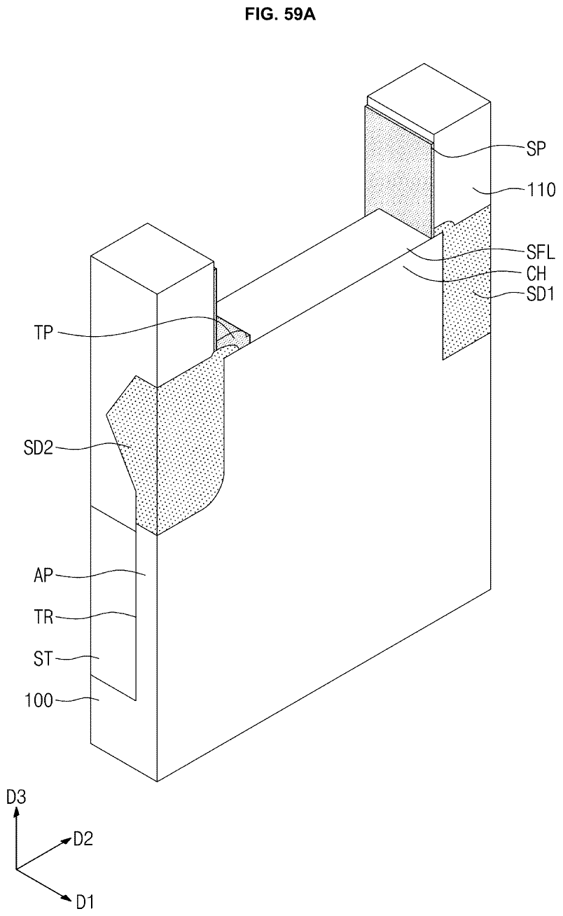

Referring to FIGS. 58A, 58B, and 58C, a portion of the exposed sloped insulation pattern TP and the lower sacrificial pattern SFL may be etched and removed. In this case, only the portion of the sloped insulation pattern TP may be removed, and the lower sacrificial pattern SFL may be entirely removed. As a result, the sloped insulation pattern TP may remain on the upper surface of the active pattern AP.

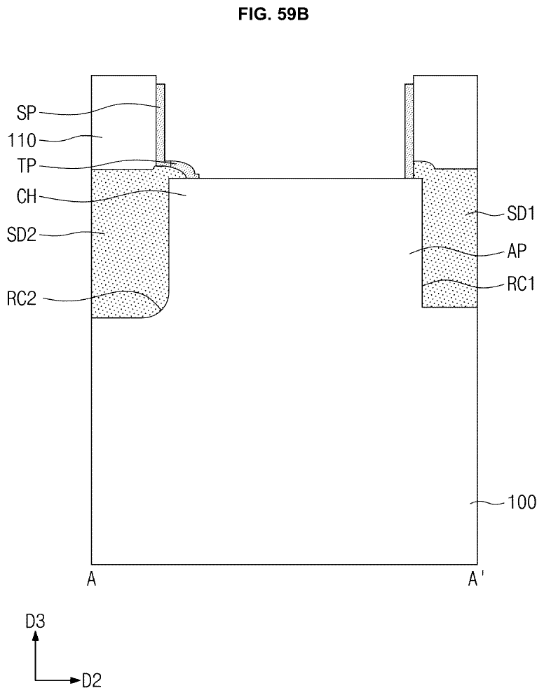

Referring to FIGS. 59A, 59B, and 58C, the portion of the sloped insulation pattern TP and the gate spacer pattern SP may be additionally etched.

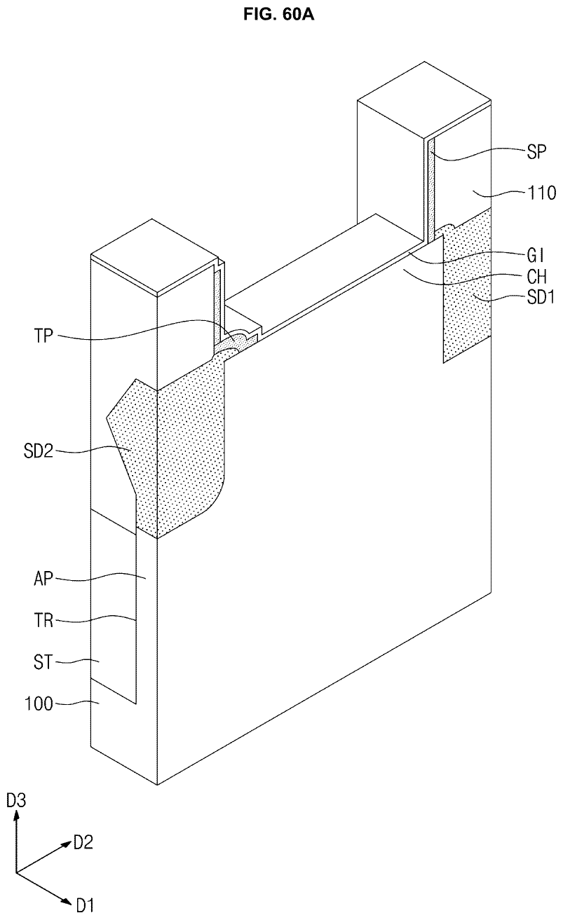

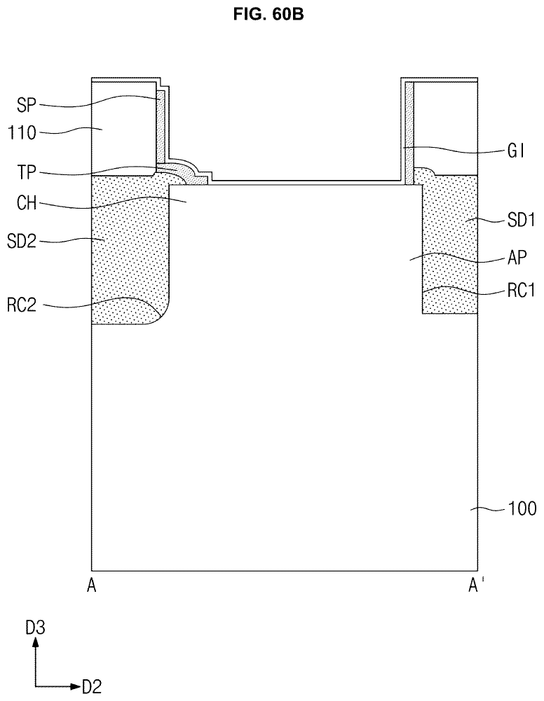

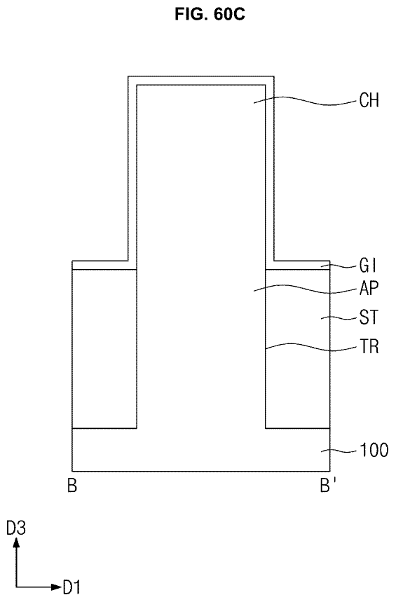

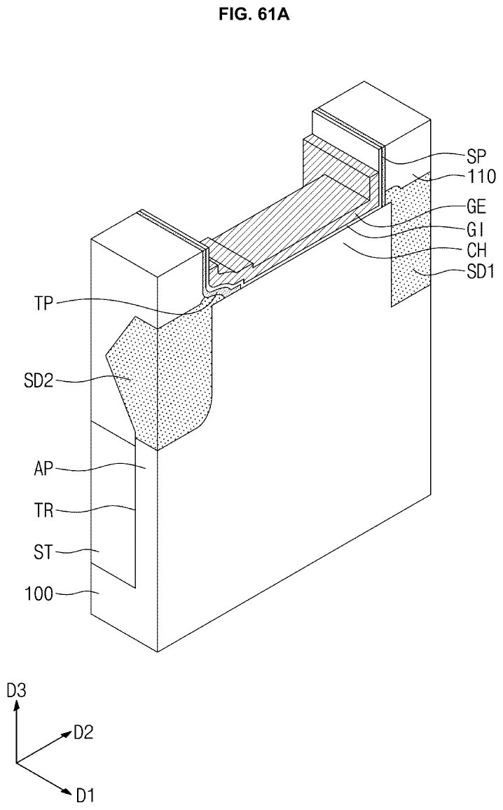

Referring to FIGS. 60A, 60B, and 60C, the gate insulating layer GI may be conformally formed in an inner region and an outer region, which are exposed to the outside on the active pattern AP.

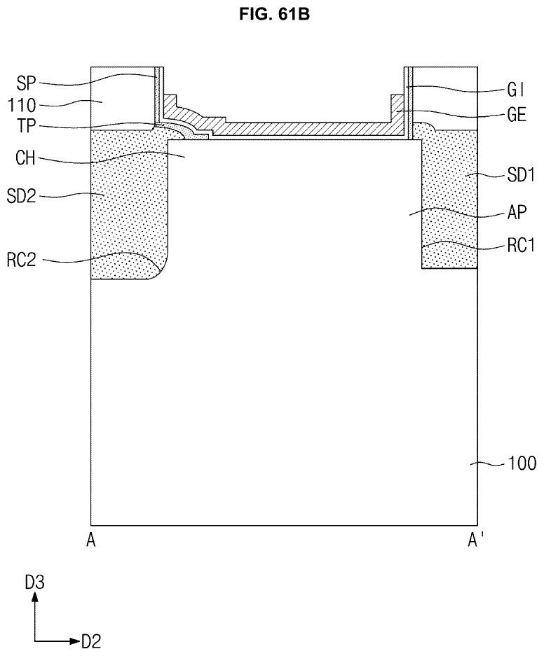

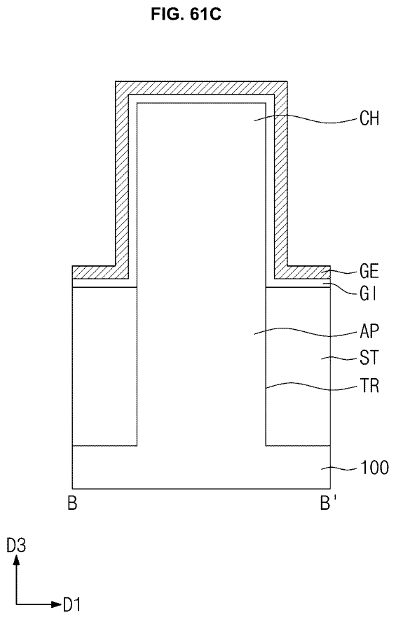

Referring to FIGS. 61A, 61B, and 61C, the gate electrode GE may be formed on the gate insulating layer GI.

According to an embodiment, a method of manufacturing a semiconductor device may include: alternately stacking first semiconductor layers and second semiconductor layers on a substrate to form a stack pattern; forming a sacrificial pattern on the stack pattern; forming a first recess in a vertical direction in one side of the stack pattern; forming a second recess in the vertical direction in the other side of the stack pattern; etching a portion of the sacrificial pattern adjacent to the second recess to form a void; filling the void to form a sloped insulation pattern; forming a first source/drain pattern and a second source/drain pattern in the first recess and the second recess, respectively; removing the sacrificial pattern to form an outer region; selectively etching the second semiconductor layers through the outer region to form an inner region; forming a gate insulating layer in the inner region; and forming a gate electrode on the gate insulating layer.

The method may further include: forming a sub-sacrificial pattern before the forming the sacrificial pattern; and etching a portion of the sub-sacrificial pattern.

The method may further include selectively etching a portion of the second semiconductor layers before the etching the portion of the sacrificial pattern to form a recess which is recessed inward more than a side surface of the first semiconductor layers.

The method may further include forming an inner spacer in the recess, and the forming the inner spacer in the recess may be performed through the same process as the forming the sloped insulation pattern.

The selectively etching the second semiconductor layers may be performed until a lower surface of the sacrificial pattern is exposed.

The selectively etching the portion of the second semiconductor layers may include a first etching process that selectively etches the portion of the second semiconductor layers exposed through the first recess and a second etching process that selectively etches the portion of the second semiconductor layers exposed through the second recess, and the first etching process and the second etching process are performed with different degrees of etching.

The stack pattern may further include an uppermost semiconductor layer formed on one of the first semiconductor layer.

The forming the void further may include etching a portion of the uppermost semiconductor layer.

The method may further include forming a gate spacer pattern on the sacrificial pattern, and the sloped insulation pattern may include the same material as the gate insulating layer and/or the gate spacer pattern.

The method may further include implanting a dopant at a low concentration into the second recess.

As described above, according to the semiconductor device of the disclosure, the improved breakdown voltage drain-to-source (BVDSS) like the LDMOS may be achieved by using the sloped insulation pattern as the field plate. The sloped insulation pattern according to the embodiments may have the effect of mitigating the electric field generated in the drain, and thus, the semiconductor device that operates even at a high voltage may be provided. Accordingly, the semiconductor device according to the embodiments may be used in various semiconductor apparatuses requiring high voltage tolerance, such as an RF power amplifier, a microwave power amplifier, and an audio power amplifier. In addition, the semiconductor device may be used in various power management integrated circuits (PMICs), such as a power supply, a DC-DC converter, a battery charger, a voltage scaling device, and a voltage regulator.

Although a limited number of embodiments of the disclosure have been described, it is understood that the disclosure should not be limited to these embodiments but various changes and modifications can be made by one ordinary skilled in the art within the spirit and scope of the disclosure as hereinafter claimed.

Therefore, the disclosed subject matter should not be limited to any single embodiment described herein, and the scope of the disclosure shall be determined according to the attached claims.

What is claimed is:

1. A semiconductor device comprising:
an active pattern on a substrate;
a first source/drain pattern and a second source/drain pattern on the active pattern;
a channel pattern between the first source/drain pattern and the second source/drain pattern;
a gate electrode on at least a portion of side surfaces of the channel pattern and an upper surface of the channel pattern;
a gate insulating layer between the channel pattern and the gate electrode; and
a sloped insulation pattern between the second source/drain pattern and the gate electrode and inclined with respect to the channel pattern.

2. The semiconductor device of claim 1, wherein the sloped insulation pattern comprises a slope surface inclined with respect to the upper surface of the channel pattern.

3. The semiconductor device of claim 2, wherein the channel pattern comprises a plurality of semiconductor patterns arranged vertically and spaced apart from each other, and
wherein the gate electrode comprises a plurality of portions between two semiconductor patterns adjacent to each other among the semiconductor patterns and on an uppermost semiconductor pattern among the semiconductor patterns.

4. The semiconductor device of claim 3, wherein the sloped insulation pattern is on the uppermost semiconductor pattern.

5. The semiconductor device of claim 4, wherein an end of the gate electrode, which is adjacent to the second source/drain pattern, vertically overlaps the sloped insulation pattern.

6. The semiconductor device of claim 3, further comprising inner spacers disposed between the gate electrode and at least one of the first source/drain pattern and the second source/drain pattern.

7. The semiconductor device of claim 6, wherein the inner spacers are between the gate electrode and the second source/drain pattern and between the gate electrode and the first source/drain pattern, and
wherein the inner spacers between the gate electrode and the second source/drain pattern have a width greater than a width of the inner spacers between the gate electrode and the first source/drain pattern.

8. The semiconductor device of claim 6, wherein the inner spacers are between the gate electrode and the second source/drain pattern, and are not between the gate electrode and the first source/drain pattern.

9. The semiconductor device of claim 6, wherein the sloped insulation pattern is on an outer side surface of the inner spacer between the gate electrode and the second source/drain pattern.

10. The semiconductor device of claim 6, wherein the sloped insulation pattern is on the uppermost semiconductor pattern and an outer side surface of the inner spacer adjacent to the second source/drain pattern.

11. The semiconductor device of claim 1, wherein the sloped insulation pattern comprises a same material as the gate insulating layer, and the sloped insulation pattern is formed integrally with the gate insulating layer without being separated from the gate insulating layer.

12. The semiconductor device of claim 11, wherein the sloped insulation pattern and the gate insulating layer comprise silicon oxide.

13. The semiconductor device of claim 1, further comprising a gate spacer at opposite sides of the gate electrode, the sloped insulation pattern comprises a same material as the gate spacer, and the sloped insulation pattern is formed integrally with the gate spacer without being separated from the gate spacer.

14. The semiconductor device of claim 13, wherein the sloped insulation pattern and the gate spacer comprise silicon nitride.

15. The semiconductor device of claim 1, further comprising a lightly doped drain (LDD) region into which a dopant is implanted at a low concentration, wherein the lightly doped drain (LDD) region is in the substrate and the channel pattern.

16. The semiconductor device of claim 15, wherein the first source/drain pattern and the second source/drain pattern comprise a P-type dopant at a high concentration, and the lightly doped drain (LDD) region comprises the P-type dopant at a low concentration.

17. A semiconductor device comprising:
an active area in a substrate;
a fin structure in the active area and comprising a channel pattern on the active area, a source region, and a drain region;
a gate electrode on at least a portion of a side surface and an upper surface of the channel pattern of the fin structure;
a gate insulating layer between the channel pattern and the gate electrode; and
a sloped insulation pattern between the drain and the gate electrode and comprising a slope surface inclined with respect to the channel pattern.

18. The semiconductor device of claim 17, wherein the sloped insulation pattern comprises a portion inclined with respect to the upper surface of the channel pattern and a portion inclined with respect to the side surfaces of the channel pattern.

19. A semiconductor device comprising:
a substrate;
an active pattern extending along a first direction on the substrate;
a first semiconductor pattern and a second semiconductor pattern vertically stacked on the active pattern and spaced apart from each other;
a gate electrode on the active pattern, extending in a second direction, and surrounding the first semiconductor pattern and the second semiconductor pattern;
a first source/drain pattern and a second source/drain pattern at least at opposite sides of the gate electrode; and
a sloped insulation pattern between the gate electrode and one of the first source/drain pattern and the second source/drain pattern and inclined with respect to an upper surface of the second semiconductor pattern.

20. The semiconductor device of claim 19, further comprising a gate spacer on the gate electrode,
wherein the gate electrode comprises a sloped gate portion inclined with respect to the upper surface of the second semiconductor pattern and the gate spacer.
